(19) United States
(12) Patent Application Publication
(10) Pub. No.: US 2008/0308727 A1
(43) Pub. Date: Dec. 18, 2008

(54) Sample Preparation for Micro-Analysis

(75) Inventors: Dimitri Boguslavsky, Haifa (IL); Colin Smith, Moshav Amikam (IL); Dan Viazovsky, Yokneam Ilit (IL); Danny Farhana, Givat Elah (IL); Dimitry Zacharin, Nesher (IL); Grigori Aronov, Hadera (IL)

Correspondence Address: MARTIN D. MOYNIHAN d/b/a PRTSI, INC., P.O. BOX 16446, ARLINGTON, VA, 22215, US

(73) Assignee: SELA SEMICONDUCTOR ENGINEERING LABORATORIES LTD., Yokneam (IL)

(21) Appl. No.: 11/883,478

(22) PCT Filed: Feb. 5, 2006
(86) PCT No.: PCT/IL06/00141

§ 371 Date: Aug. 1, 2007

Related U.S. Application Data
(60) Provisional application No. 60/649,080, filed on Feb. 3, 2005.

(51) Int. Cl. G01N 1/28; B32B 38/00; B32B 38/10; B32B 37/06; H01L 21/00; G01N 1/34; G01N 1/04; B28D 5/00

(52) U.S. Cl. 250/307; 156/379; 156/378; 156/153; 156/275.5; 438/14; 83/651; 125/39; 250/311

(57) ABSTRACT

System and method for preparing a sample for micro-analysis, comprising: (a) sample precursor holding unit, for supporting and holding a sample precursor; (b) transporting and positioning unit, for transporting and positioning the sample precursor holding unit; (c) optical imaging unit, for optically imaging, recognizing, and identifying, target features on the sample precursor, and for monitoring the sample preparation; (d) picking and placing unit, for picking and placing the sample precursor and system components from initial positions to other functionally dependent positions; (e) micro-groove generating unit, for generating at least one micro-groove in a surface of the sample precursor, wherein the micro-groove generating unit includes components for controlling formation of each micro-groove in the surface; and (f) cryogenic sectioning unit, for cryogenically sectioning the sample precursor to a pre-determined configuration and size, for forming the prepared sample. Optionally, includes a micro-mask adhering unit, and a macro-mask adhering method.

### FIELD AND BACKGROUND OF THE INVENTION

The present invention relates to sample preparation techniques and procedures, particularly those used in the fields of semiconductor manufacturing, micro-analytical testing, and materials science, which are employed prior to subjecting samples, particularly of semiconductor wafers, to micro-analysis. More particularly, the present invention relates to a system and corresponding method of preparing a sample for micro-analysis.

The present invention is a type of micro-analytical sample preparation technique which is based on ‘sectioning’ or ‘segmenting’ of at least a part of a material, such as that of a sample precursor, via reducing at least one dimension (length, width, or/and thickness, depth or height), of the size of the sample precursor, thereby producing a prepared sample ready for subjection to another process. Herein, the terms ‘sectioning’ and ‘segmenting’ are generally and equivalently referred to as ‘sectioning’, and generally refer to reducing at least one dimension (length, width, or/and thickness, depth or height), of the size of a material, such as that of a sample precursor, by using one or more types of a cutting, cleaving, slicing, or/and polishing, procedure and associated equipment.

Well known currently employed micro-analytical techniques are electron microscopy techniques, for example, scanning electron microscopy (SEM), transmission electron microscopy (TEM), scanning transmission electron microscopy (STEM), high resolution transmission electron microscopy (HR-TEM), and energy dispersion spectrometry (EDS); atomic force microscopy (AFM) techniques; and ion spectrometry techniques, for example, secondary ion mass-spectrometry (SIMS), and glow discharge spectrometry (GDS). Each of these types of micro-analytical techniques invariably requires preparing a sample using some kind of sectioning (segmenting) type of micro-analytical sample preparation technique. Herein, a sectioning (segmenting) type of micro-analytical sample preparation technique generally refers to a micro-analytical sample preparation technique which is based on sectioning or segmenting of at least a part of a sample precursor, via reducing at least one dimension (length, width, or/and thickness, depth or height), of the size of the sample precursor, by using one or more types of a cutting, cleaving, slicing, or/and polishing, procedure, thereby producing a prepared sample ready for subjection to another process, for example, a micro-analytical sample ‘final’ preparation technique.

Sectioning types of micro-analytical sample preparation techniques may be divided into three main categories: (1) thinning, (2) cross-sectioning, and (3) plan view sectioning, according to the particular type of micro-analytical technique ultimately applied for analyzing a sample. The ‘thinning’ category of sectioning types of micro-analytical sample preparation techniques are employed for preparing plan (planar) view or side view samples which are ultimately subjected to TEM types of micro-analysis. The ‘cross-sectioning’ category of sectioning types of micro-analytical sample preparation techniques are employed for preparing cross-section (side view) samples which are ultimately subjected to SEM or AFM types of micro-analysis. The ‘plan view sectioning’ category of sectioning types of micro-analytical sample preparation techniques are employed for preparing plan view samples which are ultimately subjected to SEM, AFM, or ion spectrometry, types of micro-analysis.

Most sectioning types of micro-analytical sample preparation techniques, particularly as relating to semiconductor manufacturing, are ordinarily employed ‘prior to’ applying micro-analytical sample ‘final’ preparation techniques, which, in turn, are used for preparing samples in a final form ready for subjection to micro-analysis, primarily for the purpose of inspecting or examining samples, especially for the presence of manufacturing defects or/and artifacts.

Following application of a sectioning type of micro-analytical sample preparation technique, a sample so prepared is ordinarily further subjected to a micro-analytical sample final preparation technique. Currently employed micro-analytical sample final preparation techniques are ion beam milling techniques, for example, focused ion beam (FIB) milling, and broad ion beam (BIB) milling; mechanical polishing; chemical etching techniques; plasma etching techniques; and various combination techniques thereof, for example, FIB milling followed by plasma etching, BIB milling followed by chemical etching, and FIB milling followed by BIB milling.

There exists a variety of different procedures which are ordinarily used for implementing the above stated main categories of thinning, cross-sectioning, and plan view sectioning, sectioning types of micro-analytical sample preparation techniques. Among such procedures most commonly employed are those based on processes of ion beam milling; mechanical polishing (grinding); cleaving; water cooled sawing (wet sawing); cryogenic sawing (dry sawing); a combination of cleaving and cryogenic sawing, or some other combination. These procedures are currently used for preparing samples of a wide variety of different types of materials, such as semiconductor materials (particularly, wafers, wafer segments, and wafer dies), ceramic materials, pure metallic materials, metal alloy materials, polymeric materials, and composite materials thereof, where a given material is mono-crystalline, poly-crystalline, or amorphous. Currently employed procedures used in sectioning types of micro-analytical sample preparation techniques are applicable for preparing general area or specific site (target) samples which are ultimately subjected to micro-analysis. Each of the just listed sectioning procedures is well known and taught about in the prior art. Selected highlights of each procedure are briefly provided herein as follows.

### Ion Beam Milling

Ion beam milling procedures, such as focused ion beam (FIB) milling, and broad ion beam (BIB) milling, used in sectioning types of micro-analytical sample preparation techniques, are based on highly accurately bombarding a sample by a concentrated ion beam, thereby removing material via interaction of the ion beam with the bombarded portion of the sample. An ion beam milling procedure can be applied as a specific sectioning procedure for performing any of the above stated three main categories of micro-analytical sample sectioning techniques, or as a specific sectioning procedure for performing a micro-analytical sample final preparation technique.

### Mechanical Polishing (Grinding)

Mechanical polishing (grinding) procedures, used in sectioning types of micro-analytical sample preparation techniques, are based on highly accurately polishing or grinding one or more surfaces of a sample to a tolerance of within the submicron range. Following application of a polishing (grinding) procedure, the polished or ground sample so prepared is either directly subjected to micro-analysis, or is further subjected to a final sample preparation technique, for example, ion beam milling, and then subjected to micro-analysis.

Wedge polishing (also known as tripod polishing), a particular polishing procedure used in sectioning types of micro-analytical sample preparation techniques, is based on polishing a sample until it becomes electron transparent in the region of interest, such that the polished sample can then be directly subjected to TEM micro-analysis. This procedure is further based on polishing specimen facets until a small angle is formed between them, resulting in the final sample being wedge shaped. The very tip (apex) of the sample is thus transparent to an electron beam of a TEM instrument.

An exemplary teaching of a polishing procedure used in a sectioning type of micro-analytical sample preparation technique is disclosed in U.S. Pat. No. 5,741,171, assigned to Sagitta Engineering Solutions Ltd., Ramat-Gan, Israel. Therein is disclosed a precision polishing system able to polish sample precursors to an accuracy within the submicron range, such that the polished sample can be directly subjected to micro-analysis. A sample is held in place by a gripper assembly which is attached to a polishing arm slideably connected to a fixed rail. The polishing arm is raised and lowered to polish the sample using a polishing wheel covered with a suitable abrasive. The polishing system includes real time operation of a video microscope for providing images which are processed for enabling real time control of the polishing procedure. The disclosed polishing system is particularly applicable to the semiconductor field for use in polishing silicon wafers during testing and quality control inspections.

Additional exemplary teachings of polishing, and related, procedures used in sectioning types of micro-analytical sample preparation techniques are disclosed in U.S. Pat. Nos. 6,607,429; 6,435,958; 6,116,998; 6,019,672; 4,858,479; 4,771,578; and 4,072,598, each assigned to Struers A/S (Denmark).

For example, in U.S. Pat. No. 4,771,578, there is disclosed an apparatus for the grinding or polishing of workpieces, particularly metallographic samples, wherein the grinding or polishing pressure is transmitted to the workpiece through a deformable transmission link which is strained by strain gauges of an activating member, which is then immobilized. The apparatus comprises means for sensing the elastic deformation of the transmission link and changes of that deformation during progress of the process, whereby a simultaneous measurement of the grinding or polishing pressure and the depth of the layer of material removed by the grinding or polishing is obtained. When such an apparatus is used for grinding (including honing) or polishing, an abrasion takes place, i.e., material is removed from the surface of the sample in contact with the grinding or polishing disc.

For example, in U.S. Pat. No. 4,072,598, there is disclosed an electrolytic polishing apparatus, in which a polishing sample is pressed against an opening in a cover of a container, in which electrolyte is caused to rotate by means of a stirring magnet, the container having a central bottom opening and being placed in an outer bowl. In such a polishing apparatus the magnetic stirrer serves to set the electrolyte in rapidly rotating movement, whereby it is possible to obtain a strong flow of the electrolyte along the surface of the polishing sample that the conditions necessary for the polishing effect (so-called polishing film) are not disturbed, while the gas bubbles liberated by the electrolysis are nevertheless removed. Metal is dissolved from the surface of the sample in such a manner that a uniform and shiny surface is obtained, in which the structure of the metal can be observed, for example, by a micro-analytical technique, without being distorted by the deformations which are unavoidable in the case of mechanical polishing or grinding.

Dimpling (polishing, grinding), another particular polishing procedure used in sectioning types of micro-analytical sample preparation techniques, is based on removal, via polishing or grinding, of spherically (dimple) shaped surface layers of a sample. Typically, a sample holder holding the sample is rotated while an orthogonally positioned and operative polishing or grinding device removes the spherically (dimple) shaped surface layers, for forming a sample suitable for general area micro-analysis. Following application of a dimpling procedure, the dimple polished or ground sample so prepared is further subjected to a final sample preparation technique, for example, ion beam milling, and then subjected to micro-analysis.

### Cleaving

Cleaving procedures, used in sectioning types of micro-analytical sample preparation techniques, are based on highly accurate cleaving or splitting a sample precursor, or a sample, along a cleavage (crystal) plane coinciding with a previously made indention or groove on a surface of the sample precursor, or sample, in the immediate vicinity of a region of interest (ROI) including one or more targets (or features thereof) on the sample precursor, or sample. A cleaving procedure typically includes a coarse cleaving step performed on a sample precursor, having a size larger than that of the sample, followed by a fine cleaving step performed on the coarse cleaved sample. Following application of a cleaving procedure, the cleaved sample so prepared can be further subjected to a final sample preparation technique, for example, ion beam milling, and then subjected to micro-analysis.

Exemplary teachings of cleaving procedures used in sectioning types of micro-analytical sample preparation techniques are disclosed in U.S. Pat. Nos. 5,740,953, and 6,223,961, each assigned to Sela Ltd. [Semiconductor Engineering Laboratories, (Israel)]; being the same assignee/applicant of the present invention.

In U.S. Pat. No. 5,740,953, to Smith et al., there is disclosed a method and apparatus for cleaving a semiconductor wafer for inspecting a target feature on a workface thereof by: producing, on a first lateral face of the semiconductor wafer, laterally of the workface on one side of the target feature, an indentation in alignment with the target feature; and inducing by impact, in a second lateral face of the semiconductor wafer, laterally of the workface on the opposite side of the target feature, a shock wave substantially in alignment with the target feature and the indentation on the first lateral face, to split the semiconductor wafer along a cleavage plane essentially coinciding with the target feature and the indentation. The disclosed cleaving technique is capable of cleaving wafers having a length of 40-100 mm, a width of 10-15 mm, and a thickness of a fraction of a millimeter (e.g., 0.5 mm) with an accuracy in the micron range (usually less than 3 microns, and on the average of 1-2 microns) of the target feature, suitable for wafer manufacturing quality control purposes. The cleaving operations can be performed in a matter of minutes (as compared to hours by a comparable manual method), and with less skilled personnel than required by the manual method. The disclosed invention is particularly useful for cleaving semiconductor wafers in order to inspect, particularly via SEM, a cross-section of the wafer at a specified location, designated by a target feature or features on a workface of the wafer.

It is noted that the invention disclosed in U.S. Pat. No. 5,740,953, was developed specifically for SEM sample preparation, but, also being applicable for TEM sample preparation. A notable limitation of the invention disclosed therein relates to the segment size of the input sample, or sample precursor, being limited to a minimum size of about 13 mm×40 mm (length×width), and to the size of the output sample so prepared. For overcoming this relatively significant practical limitation, as well as for improving cleaving accuracy, the present assignee/applicant (Sela Ltd.) developed an invention, disclosed in U.S. Pat. No. 6,223,961, to Boguslavsky et al., for cleaving smaller crystalline segments, such as semiconductor wafer segments or dice, which are not readily and accurately cleaved with prior art apparatus and techniques.

In U.S. Pat. No. 6,223,961, there is disclosed an apparatus for cleaving a crystalline segment, such as a semiconductor wafer segment or die, having a size equal to or smaller than about 13 mm×40 mm (length×width). The disclosed invention comprises a knife facing a first cleave plane formed on a first side of a crystalline segment, wherein the crystalline segment has a cleave line extending between and generally perpendicular to the opposing cleave planes; an impact pin facing a second cleave plane formed on a second side of the crystalline segment opposite to the first side, wherein the impact pin and the knife are aligned on opposite sides of the cleave line; and an actuator connected to the knife and the impact pin, for causing relative movement of the knife and the impact pin towards each other, such that the knife abuts against the first cleave plane and the impact pin abuts against the second cleave plane, and the knife cleaves the crystalline segment generally along the cleave line.

### Water Cooled Sawing (Wet Sawing)

Water cooled sawing (wet sawing) procedures used in sectioning types of micro-analytical sample preparation techniques, are based on using a diamond blade saw operative with a cooling device or mechanism having water as a cooling medium, for ‘wet’ cooling the saw blade and a sample precursor during the sawing process, for highly accurately sawing the sample precursor to a pre-determined shaped or formed sample. Following application of a water cooled sawing procedure, the saw cut sample so prepared is further subjected to a final sample preparation technique, for example, ion beam milling, and then subjected to micro-analysis.

A potentially significant limitation associated with water cooled sawing (wet sawing) types of sectioning procedures relates to the potentially undesirable presence of contaminants or artifacts in the water used for cooling the saw blade and the sample precursor during the sawing process, potentially resulting in samples containing the water originating contaminants or artifacts. In addition, water (regardless of its purity level) is known for causing swelling of a sample, translating to distortion of sample features. Such occurrences would most likely lead to erroneous results obtained during the eventual micro-analysis of the sample.

### Cryogenic Sawing (Dry Sawing)

Cryogenic sawing (dry sawing) procedures used in sectioning types of micro-analytical sample preparation techniques, are based on using a diamond blade saw operative with a cooling device or mechanism having an evaporative (dry) cooling medium (for example, dual-phase liquid and gaseous nitrogen), for ‘dry’ cooling the saw blade and a sample precursor during the sawing process, for highly accurately sawing the sample precursor to a pre-determined shaped or formed sample. It is noted that the cryogenic sawing (dry sawing) procedure, absent of water, overcomes the previously described potentially significant limitation, relating to water contaminants, associated with the water cooled sawing (wet sawing) procedure. Following application of a cryogenic sawing procedure, the saw cut sample so prepared is further subjected to a final sample preparation technique, for example, ion beam milling, and then subjected to micro-analysis.

An exemplary teaching of a cryogenic sawing (dry sawing) procedure used in a sectioning type of micro-analytical sample preparation technique is disclosed in present assignee/applicant PCT International Patent Application Publication No. WO 02/054042, summarized immediately following in the context of an exemplary teaching of a combination of cleaving and sawing procedures used in a sectioning type of micro-analytical sample preparation technique.

### Combination of Cleaving and Sawing

A combination of cleaving and sawing procedures used in sectioning types of micro-analytical sample preparation techniques, is based on sequentially performing the above described cleaving and sawing (preferably, cryogenic (dry) sawing) procedures, for highly accurately first cleaving a sample precursor, and then sawing the sample precursor to a pre-determined shaped or formed sample. Following application of a combination of cleaving and sawing procedures, the sectioned sample so prepared is further subjected to a final sample preparation technique, for example, ion beam milling, and then subjected to micro-analysis.

As previously noted above, the cleaving procedures used in the sectioning types of micro-analytical sample preparation techniques disclosed in U.S. Pat. Nos. 5,740,953, and 6,223,961, are ordinarily employed for ultimately subjecting the final prepared sample to SEM types of micro-analysis. For the main objective of extending those cleaving procedures to TEM types of micro-analysis, the present assignee/applicant developed a combination cleaving and sawing (preferably, cryogenic (dry) sawing) procedure, as a type of micro-analytical sample preparation technique. The technical strategy was based on the premise that the first face of a TEM sample precursor would be cut by cleaving, and that additional faces of the cleaved sample precursor would be cut by sawing, such that the sectioned sample would then be subjected to a final sample preparation technique, such as FIB milling or/and BIB milling, and be made ready for subsequent TEM micro-analysis. A significant advantage resulting from that strategy is that a polishing or grinding procedure is not required for producing a final sectioned sample, for example, of about 0.1 micron thick, suitable for TEM micro-analysis.

An exemplary teaching of such a combination of cleaving and cryogenic sawing procedures, which can be used in a sectioning type of micro-analytical sample preparation technique, is disclosed in present assignee/applicant PCT Int'l. Pat. Appl. Publ. No. WO 02/054042. Therein is disclosed a procedure for preparing a sample, especially of a semiconductor wafer segment or die, for subjection to a micro-analytical technique, particularly TEM, for the purpose of inspecting or examining the sample for the presence of manufacturing defects or/and artifacts.

The disclosed sectioning type of micro-analytical sample preparation technique includes initially manipulating and cutting a sample precursor (a wafer), for example, using the cleaving procedure disclosed in present assignee/applicant U.S. Pat. No. 5,740,953, in a manner such that a target (or feature thereof) is preferably near the edge, or, alternatively, near the center, of the sample precursor. Then, the cleaved sample precursor is subjected to a series of highly accurate saw cuts, so as to produce a thinner sample, which is then subjected to a final thinning or trimming procedure, preferably, FIB milling. The disclosed saw cutting procedure can be performed by using a water cooled sawing (wet sawing) type of procedure. Alternatively, and preferably, the saw cutting procedure is performed by using a cryogenic sawing (dry sawing) type of procedure, wherein the blade saw apparatus is operative with a cooling device including a needle and nozzle for spraying dual-phase liquid and gaseous nitrogen as an evaporative cooling medium, for ‘dry’ cooling the saw blade and the sample precursor during the sawing process.

In a preferred embodiment of the disclosed invention, the step of making a series of saw cuts includes making a first saw cut in the range of 10-50 microns from the edge, a width of the first saw cut being in the range of 20-100 microns and in the range of 20-100 microns deep, making a second saw cut in the range of 50-100 microns from the edge, a width of the second saw cut being in the range of 100-500 microns and in the range of 100-500 microns deep, and making a third saw cut in the vicinity of the second saw cut which cuts clean the sample from the remainder of the sample precursor. The cut sample is then subjected to a final thinning or trimming procedure, preferably, FIB milling, for producing a bar shaped or formed final sample in which the target is located, suitable for subsequent micro-analysis, particularly via TEM.

Each above summarized and exemplified prior art micro-analytical sample preparation sectioning procedure has particular advantages and disadvantages or limitations, especially as relating to the particular type (physicochemical properties, characteristics, and behavior, and dimensions) of the initial sample precursor used and of the sectioned sample subsequently prepared, and as relating to the particular preparatory requirements of the micro-analytical technique which is ultimately used for analyzing a given sample.

Regarding the type of sample precursor which is used for preparing a sectioned sample, three significant limitations exist in current practice. First, a given prior art micro-analytical sample preparation sectioning procedure which is particularly suitable for sectioning (cutting, cleaving, slicing, or/and polishing) in specific directions along crystal boundaries or edges in a mono-crystalline type of sample precursor material, is ordinarily not suitable for sectioning a poly-crystalline or amorphous type of sample precursor material. Second, prior art sample preparation sectioning procedures are ordinarily not sufficiently suitable for processing sample precursors having adjacent layers which poorly adhere to each other. Third, prior art sample preparation sectioning procedures are ordinarily not sufficiently suitable for ‘in-line’ initial handling and processing of relatively large sample precursors, for example, a whole semiconductor wafer having a diameter of about 300 mm.

Regarding the type of the sectioned sample subsequently prepared, two significant limitations currently exist in practice. First, a given prior art micro-analytical sample preparation sectioning procedure is ordinarily suitable for preparing a sectioned sample which can be subsequently further prepared by only a single type of final preparation technique, such as focused ion beam (FIB) milling, or broad ion beam (BIB) milling, but not both. This limitation reduces subsequent processing options one has regarding final preparation of a sectioned sample. Second, prior art micro-analytical sample preparation sectioning procedures which are used for preparing samples that are subsequently subjected to ion beam milling types of final preparation techniques, currently produce sectioned samples having relatively large size dimensions that require proportionately large amounts of ion beam milling time. As the time required for performing an ion beam milling procedure increases, there is an increase in the potential for introduction of contamination and artifacts to the sample, as a result of re-deposition during the ion beam milling process. Such introduction of contamination and artifacts to a sample tends to interfere with the mass spectrometry, and analysis thereof, required during a typical micro-analytical technique.

Regarding the particular preparatory requirements of the micro-analytical technique which is ultimately used for analyzing a given sample, a significant limitation relates to the lack of generality of applicability of a given prior art micro-analytical sample preparation sectioning procedure. There exist prior art micro-analytical sample preparation sectioning procedures, including, for example, the cleaving and sawing procedures disclosed by the present assignee/applicant and summarized hereinabove, which are applicable for ultimately preparing samples suitable for different types of micro-analytical techniques, such as SEM, TEM, STEM, EDS, AFM, SIMS, or GDS. However, typically, a given micro-analytical sample preparation sectioning procedure is preferably employed for the ultimate purpose of only one type of micro-analytical technique, that is, SEM, or TEM, or STEM, or EDS, or AFM, or SIMS, or GDS, respectively, and tends not to be equally generally applicable to more than one type of micro-analytical technique. A result of this limitation is that a different micro-analytical sample preparation sectioning procedure, involving different methodology and associated equipment, needs to be employed for ultimate preparation of each specific type of micro-analytical sample. Moreover, a given micro-analytical sample preparation sectioning procedure may be fully applicable for ultimately preparing one type of an SEM or TEM sample, for example, a side view (cross section) SEM or TEM sample, but, may be inapplicable for ultimately preparing another type of an SEM or TEM sample, for example, a plan view SEM or TEM sample. Thus, the same limitation again arises in practice.

Another specific limitation which particularly characterizes prior art dimpling (polishing, grinding) procedures used in sectioning types of micro-analytical sample preparation techniques, is that such procedures are not applicable for preparing specific site (target) samples.

Another specific limitation which is particularly prevalent during application of prior art sawing procedures used in sectioning types of micro-analytical sample preparation techniques, including, for example, the cryogenic sawing (dry sawing) procedure disclosed by the present assignee/applicant and summarized hereinabove, is based on the practically unavoidable formation of undesirable micro-sized cracks or/and artifacts in the sample during the sawing process.

Based to a large extent on the above described limitations and disadvantages associated with prior art micro-analytical sample preparation sectioning procedures, currently, at least in the fields of semiconductor manufacturing, micro-analytical testing, and materials science, there is an on-going need for having improved and new micro-analytical sample preparation sectioning procedures, in particular, which are absent of the above indicated limitations and disadvantages.

There is thus a need for, and it would be highly advantageous to have a system and corresponding method of preparing a sample for micro-analysis. There is a need for such an invention, particularly as relating to semiconductor manufacturing, micro-analytical testing, and materials science, which is implementable prior to applying a micro-analytical sample final preparation technique, which, in turn, is used for preparing a sample in a final form ready for subjection to micro-analysis, such as by an electron microscopy technique, an atomic force microscopy technique, or/and an ion spectrometry technique, primarily for the purpose of inspecting or examining samples, especially for the presence of manufacturing defects or/and artifacts.

Additionally, there is a need for such an invention which is applicable for preparing micro-analytical samples of different types of materials, such as semiconductor materials (particularly, wafers, wafer segments, and wafer dies), ceramic materials, pure metallic materials, metal alloy materials, and composite materials thereof, where a given material is mono-crystalline, poly-crystalline, or amorphous. Additionally, there is a need for such an invention which is applicable for preparing general area or specific site (target) samples that are suitable for being subjected to any of a variety of different types of sample final preparation techniques, and that are suitable for ultimately being subjected to any of a variety of different types of micro-analytical techniques.

### SUMMARY OF THE INVENTION

The present invention relates to a system and corresponding method of preparing a sample for micro-analysis. The present invention, particularly as relating to semiconductor manufacturing, micro-analytical testing, and materials science, is implementable prior to applying a micro-analytical sample final preparation technique, which, in turn, is used for preparing a sample in a final form ready for subjection to micro-analysis, such as by an electron microscopy technique, an atomic force microscopy technique, or/and an ion spectrometry technique, primarily for the purpose of inspecting or examining samples, especially for the presence of manufacturing defects or/and artifacts.

The present invention is a type of micro-analytical sample preparation technique which is based on sectioning or segmenting of at least a part of a material, such as that of a sample precursor, via reducing at least one dimension (length, width, or/and thickness, depth or height), of the size of the sample precursor, thereby producing a prepared sample ready for subjection to another process.

The present invention is applicable for performing various different procedures involved during the implementation of (1) thinning, (2) cross-sectioning, or/and (3) plan view sectioning, main categories of sectioning types of micro-analytical sample preparation techniques, according to the particular type of micro-analytical technique ultimately applied for analyzing a sample. The present invention is applicable for preparing micro-analytical samples of different types of materials, such as semiconductor materials (particularly, wafers, wafer segments, and wafer dies), ceramic materials, pure metallic materials, metal alloy materials, and composite materials thereof, where a given material is mono-crystalline, poly-crystalline, or amorphous. The present invention is applicable for preparing general area or specific site (target) samples that are suitable for being subjected to any of a variety of different types of sample final preparation techniques, and that are suitable for ultimately being subjected to any of a variety of different types of micro-analytical techniques.

Thus, according to the present invention, there is provided a system of preparing a sample for micro-analysis, comprising: (a) a sample precursor holding unit, for supporting and holding a sample precursor; (b) a transporting and positioning unit, for transporting and positioning at least a part of the sample precursor holding unit; (c) an optical imaging unit, for optically imaging, recognizing, and identifying, target features located on the sample precursor, and for monitoring steps of the sample preparation; (d) a picking and placing unit, for picking and placing the sample precursor and selected components of the system from initial positions to other functionally dependent positions; (e) a micro-groove generating unit, for generating at least one micro-groove in a surface of the sample precursor, wherein the micro-groove generating unit includes components for controlling depth and quality of each micro-groove in the surface; and (f) a cryogenic sectioning unit, for cryogenically sectioning the sample precursor to a pre-determined configuration and size, for forming the prepared sample.

According to further characteristics in preferred embodiments of the invention described below, the sample preparation system further includes an electronics and process control utilities, operatively (structurally or/and functionally) connected to each above stated main component (a)-(f) of the sample preparation system, for providing electronics to, and enabling process control of, each respective above stated sample preparation system main component (a)-(f).

According to further characteristics in preferred embodiments of the invention described below, the sample preparation system optionally, further includes at least one additional main component selected from the group consisting of: (g) an adhering interface assembly, for enabling interfacing of (b) the transporting and positioning unit with (d) the picking and placing unit, for adhering a first component to a second component within the sample preparation system; (h) a pneumatics control unit, for controlling pneumatics of selected main components [(a) the sample precursor holding unit, (b) the transporting and positioning unit, (d) the picking and placing unit, and (f) the cryogenic sectioning unit] of the sample preparation system; (i) a sample precursor size (surface area dimensions) reducing unit, for reducing size (surface area dimensions) of the sample precursor to a pre-determined sample precursor size; (j) a scribing and cleaving unit, for generating a scribe line on a surface of the sample precursor, and cleaving the sample precursor along the scribe line; (k) a micro-mask adhering unit, for adhering a micro-mask onto a surface of the sample precursor; and (l) an anti-vibration unit, for preventing or minimizing occurrence of vibrations during operation of the system.

According to further characteristics in preferred embodiments of the invention described below, when the sample preparation system includes at least one of the above stated (optional) additional main components (g)-(l), then, the electronics and process control utilities is also operatively (structurally or/and functionally) connected to each additionally included sample preparation system main component, for providing electronics to, and enabling process control of, each additionally included main component, in a manner operatively (structurally or/and functionally) integrated with previously stated sample preparation system main components (a)-(f). Accordingly, the present invention provides various alternative exemplary preferred embodiments of a sample preparation system, for preparing a sample for micro-analysis.

According to another aspect of the present invention, there is provided a device for generating at least one micro-groove in a surface of a material, comprising: (a) a micro-groove generating element assembly, including a micro-groove generating element and a micro-groove generating element holder assembly; (b) a vertical displacement assembly, for vertically displacing and penetrating the micro-groove generating element into the surface of the material; and (c) a force applying assembly, for applying a controllable force to the micro-groove generating element, via operation of the vertical displacement assembly.

According to another aspect of the present invention, there is provided a device for cryogenically sectioning a material, comprising: (a) a fine sectioning blade, for sectioning the material at positions located along the material which are adjacent to target features of the material; (b) a coarse sectioning blade, for reducing, via sectioning, the material at positions along the material which are not adjacent to the target features; (c) a sectioning blade drive shaft, for driving both the fine sectioning blade and the coarse sectioning blade; (d) a sectioning blade drive shaft motor, for rotating the blade drive shaft; and (e) a cryogenic fluid supply and control assembly, for supplying and controlling use of a cryogenic fluid as a coolant or cooling agent for cooling at least one of the fine sectioning blade and the coarse sectioning blade, and the material during the cryogenic sectioning process, wherein the cryogenic fluid supply and control assembly includes: (i) a cryogenic fluid; (ii) a cryogenic fluid reservoir; (iii) a cryogenic fluid supply valving and distributing sub-assembly, including a pressure control mechanism for maintaining pressure of the cryogenic fluid reservoir at a constant value regardless of changes or variability in volume of the cryogenic fluid present in the cryogenic fluid reservoir; and (iv) a cryogenic fluid outlet nozzle sub-assembly.

According to another aspect of the present invention, there is provided a device for adhering a micro-mask onto a surface of a material, comprising: (a) a micro-size masking element, having a geometrical configuration, shape or form, selected from the group consisting of cylindrical, rectangular, and trapezoidal, and wherein diameter of the cylindrical configuration is in a range of from about 6 microns to about 25 microns, and wherein section or profile of the rectangular configuration is in a range of from about 6 microns to about 25 microns; (b) a micro-size masking element holder assembly; (c) an electrical contact assembly; (d) a housing assembly; (e) a y-axis displacement sub-assembly; (f) a z-axis displacement sub-assembly; and (g) a light beam interruption sensor assembly.

According to another aspect of the present invention, there is provided a method of preparing a sample for micro-analysis, comprising: (a) loading a sample precursor onto a sample precursor holding unit; (b) transporting and positioning the sample precursor holding unit by a transporting and positioning unit; (c) optically imaging, recognizing, and identifying, target features located on the sample precursor, and monitoring steps of the sample preparation, by an optical imaging unit; (d) picking and placing the sample precursor and selected components of the system from initial positions to other functionally dependent positions, by a picking and placing unit; (e) generating at least one micro-groove in a surface of the sample precursor, by a micro-groove generating unit, wherein depth and quality of each micro-groove in the surface is controlled by components included in the micro-groove generating unit; and (f) cryogenically sectioning the sample precursor to a pre-determined configuration and size, for forming the prepared sample, by a cryogenic sectioning unit.

According to further characteristics in preferred embodiments of the invention described below, the method of preparing a sample for micro-analysis further includes the step of providing electronics to, and enabling process control of, each main component of each above stated sample preparation method main step (a)-step (f), by an electronics and process control utilities which is operatively connected to each respective above stated main component.

According to further characteristics in preferred embodiments of the invention described below, the method of preparing a sample for micro-analysis, optionally, further includes at least one additional main step (and components thereof) selected from the group consisting of: (g) adhering a first component to a second component within the sample preparation system, by an adhering interface assembly which enables interfacing of the transporting and positioning unit with the picking and placing unit; (h) controlling pneumatics of selected main components (a sample precursor holding unit, a transporting and positioning unit, a picking and placing unit, and a cryogenic sectioning unit) of the sample preparation system, by a pneumatics control unit; (i) reducing size (surface area dimensions) of the sample precursor to a pre-determined sample precursor size, by a sample precursor micro-size (surface area dimensions) reducing unit; (j) generating a scribe line on a surface of the sample precursor, and cleaving the sample precursor along the scribe line, by a scribing and cleaving unit; (k) marking a target area or region of interest (ROI) on a surface of the sample precursor, by a marking device; (l) adhering a macro-mask onto a surface of the sample precursor, by selected sample preparation system main components; (m) adhering a micro-mask onto a surface of the sample precursor, by a micro-mask adhering unit; and (n) preventing or minimizing occurrence of vibrations during operation of the sample preparation system, by an anti-vibration unit.

According to further characteristics in preferred embodiments of the invention described below, when the sample preparation method includes at least one of the above stated (optional) additional main steps (g)-(n), then, the electronics and process control utilities provides electronics, and enables process control, for performing each additional main step, in a manner operatively (structurally and functionally) integrated with previously stated sample preparation method main steps (a)-(f).

According to another aspect of the present invention, there is provided a method of generating at least one micro-groove in a surface of a material, comprising: (a) providing a micro-groove generating element assembly including a micro-groove generating element and a micro-groove generating element holder assembly; (b) controlling angle of approach towards, and penetration into, the surface of the material, by the micro-groove generating element, by an aligning assembly; (c) transmitting movement to the aligning assembly, such that vertical displacement of the micro-groove generating element is converted to a rotational displacement, by a vertical displacement assembly; and (d) applying a controllable force to the micro-groove generating element, by a force applying assembly.

According to another aspect of the present invention, there is provided a method of cryogenically sectioning a material, comprising: (a) sectioning the material at positions located along the material which are adjacent to target features of the material, by a fine sectioning blade; (b) reducing, via sectioning, the material at positions along the material which are not adjacent to the target features, by a coarse sectioning blade; (c) driving both the fine sectioning blade and the coarse sectioning blade, by a sectioning blade drive shaft; (d) rotating the blade drive shaft, by a sectioning blade drive shaft motor; and (e) supplying and controlling use of a cryogenic fluid as a coolant or cooling agent for cooling at least one of the fine sectioning blade and the coarse sectioning blade, and the material during the cryogenic sectioning process, by a cryogenic fluid supply and control assembly, wherein the cryogenic fluid supply and control assembly includes: (i) a cryogenic fluid; (ii) a cryogenic fluid reservoir; (iii) a cryogenic fluid supply valving and distributing sub-assembly, including a pressure control mechanism for maintaining pressure of the cryogenic fluid reservoir at a constant value regardless of changes or variability in volume of the cryogenic fluid present in the cryogenic fluid reservoir; and (iv) a cryogenic fluid outlet nozzle sub-assembly.

According to another aspect of the present invention, there is provided a method of adhering a macro-mask onto a surface of a material, comprising: (a) generating at least one micro-groove in a surface of the material, by using a micro-groove generating unit; and (b) adhering the macro-mask at a pre-determined location and according to a pre-determined configuration (orientation) onto a surface of the material, by using an adhering interface assembly, in such a way that each generated micro-groove is extended in reference to the macro-mask, for serving as a mark, thereby being visible by an optical imaging device during subsequent subjection to a sectioning procedure.

According to another aspect of the present invention, there is provided a method of adhering a micro-mask onto a surface of a material, comprising: (a) applying an adhesive onto a dedicated area on a surface of the material, by a picking and placing unit; (b) positioning the dedicated area with the adhesive applied under a micro-size masking element, by using a transporting and positioning unit; (c) controllably dipping of the micro-size masking element into the adhesive, by using a z-axis displacement sub-assembly of the transporting and positioning unit; (d) focusing the micro-size masking element, by using the z-axis displacement sub-assembly; (e) vertically moving the micro-size masking element out of focus of the optical imaging unit, by using the z-axis displacement sub-assembly; (f) positioning a target feature of the material, to be coincident with position formerly occupied by the micro-size masking element prior to being taken out of focus, by using the transporting and positioning unit; (g) vertically moving the micro-size masking element down until contact is made with the surface of the material, by using the z-axis displacement sub-assembly; (h) applying an electrical current to the micro-size masking element, for heating and curing the micro-size masking element; and (i) increasing the applied electrical current to edges of the micro-size masking element, for trimming the edges of the micro-size masking element.

The present invention is implemented by performing procedures, steps, and sub-steps, in a manner selected from the group consisting of manually, semi-automatically, fully automatically, and a combination thereof, involving use and operation of system units, system sub-units, devices, assemblies, sub-assemblies, mechanisms, structures, components, and elements, and, peripheral equipment, utilities, accessories, and materials, in a manner selected from the group consisting of manually, semi-automatically, fully automatically, and a combination thereof. Moreover, according to actual procedures, steps, sub-steps, system units, system sub-units, devices, assemblies, sub-assemblies, mechanisms, structures, components, and elements, and, peripheral equipment, utilities, accessories, and materials, used for implementing a particular embodiment of the disclosed invention, the procedures, steps, and sub-steps, are performed by using hardware, software, or/and an integrated combination thereof, and the system units, sub-units, devices, assemblies, sub-assemblies, mechanisms, structures, components, and elements, and, peripheral equipment, utilities, accessories, and materials, operate by using hardware, software, or/and an integrated combination thereof.

In particular, software used for implementing the present invention includes operatively connected and functioning written or printed data, in the form of software programs, software routines, software sub-routines, software symbolic languages, software code, software instructions or protocols, software algorithms, or/and a combination thereof. In particular, hardware used for implementing the present invention includes operatively connected and functioning electrical, electronic or/and electromechanical system units, sub-units, devices, assemblies, sub-assemblies, mechanisms, structures, components, and elements, and, peripheral equipment, utilities, accessories, and materials, which may include one or more computer chips, integrated circuits, electronic circuits, electronic sub-circuits, hard-wired electrical circuits, or/and combinations thereof, involving digital or/and analog operations. Accordingly, the present invention is implemented by using an integrated combination of the just described software and hardware.

### BRIEF DESCRIPTION OF THE DRAWINGS

The present invention is herein described, by way of example only, with reference to the accompanying drawings. With specific reference now to the drawings in detail, it is stressed that the particulars shown are by way of example and for purposes of illustrative description of the preferred embodiments of the present invention only, and are presented in the cause of providing what is believed to be the most useful and readily understood description of the principles and conceptual aspects of the present invention. In this regard, no attempt is made to show structural details of the present invention in more detail than is necessary for a fundamental understanding of the invention, the description taken with the drawings making apparent to those skilled in the art how the several forms of the invention may be embodied in practice. In the drawings:

FIG. 1 is a block diagram illustrating an exemplary preferred embodiment of the system, sample preparation system 10, for preparing a sample for micro-analysis, including main components: (a) a sample precursor holding unit 100, (b) a transporting and positioning unit 200, (c) an optical imaging unit 300, (d) a picking and placing unit 400, (e) a micro-groove generating unit 500, and (f) a cryogenic sectioning unit 600, along with an electronics and process control utilities 1300, and various possible specific exemplary preferred embodiments thereof, by further including at least one additional main component selected from the group consisting of: (g) an adhering interface assembly 700, (h) a pneumatics control unit 800, (i) a sample precursor micro-size (surface area dimensions) reducing unit 900, (j) a scribing and cleaving unit 1000, (k) a micro-mask adhering unit 1100, and (l) an anti-vibration unit 1200, in accordance with the present invention;

FIG. 2 is a schematic diagram illustrating a perspective view of the exemplary preferred embodiment of the sample preparation system 10, and main components 100-1200 thereof, shown in FIG. 1, for preparing a sample for micro-analysis, in accordance with the present invention;

FIG. 3 is a schematic diagram illustrating a partly exploded perspective close-up view of the sample precursor holding unit 100, and components thereof, as part of the sample preparation system 10 illustrated in FIGS. 1 and 2, in accordance with the present invention;

FIG. 4 is a schematic diagram illustrating a partly exploded perspective close-up view of selected units (the sample precursor holding unit 100, the transporting and positioning unit 200, the optical imaging unit 300, the picking and placing unit 400, the micro-groove generating unit 500, the cryogenic sectioning unit 600, the adhering interface assembly 700, the sample precursor micro-size (surface area dimensions) reducing unit 900, the scribing and cleaving unit 1000, and the micro-mask adhering unit 1100), and components thereof, as part of the sample preparation system 10 illustrated in FIGS. 1 and 2, in accordance with the present invention;

FIGS. 5A-5C are schematic diagrams illustrating additional perspective close-up front (FIG. 5A), underside (FIG. 5B), and partly exploded (FIG. 5C), views of the micro-groove generating unit 500, and components thereof, as part of the sample preparation system 10 illustrated in FIGS. 1 and 2, in accordance with the present invention;

FIGS. 5D-5F are schematic diagrams illustrating additional perspective close-up front (FIG. 5A), side (FIG. 5B), and partly section underside (FIG. 5C), views of the micro-groove generating unit 500′, and components thereof, as an alternative embodiment of the micro-groove generating unit 500, and components thereof, as part of the sample preparation system 10 illustrated in FIGS. 1 and 2, in accordance with the present invention;

FIGS. 6A-6D are schematic diagrams illustrating additional perspective close-up views of the cryogenic sectioning unit 600, and components thereof, as part of the sample preparation system 10 illustrated in FIGS. 1 and 2, along with directional movements thereof [(FIGS. 6A-6B): vertical movement, and (FIGS. 6C-6D): horizontal movement, during sectioning of the sample precursor 20], in accordance with the present invention;

FIGS. 7A-7B are schematic diagrams illustrating additional perspective close-up views of the adhering interface assembly 700, and components thereof, as part of the sample preparation system 10 illustrated in FIGS. 1 and 2, in relation to the sample precursor holding unit 100, the transporting and positioning unit 200, and the picking and placing unit 400, with (FIG. 7A) and (FIG. 7B) depicting final stages of adhering the sample precursor 20 to an exemplary side view type of sample precursor support structure 110, in accordance with the present invention;

FIG. 8 is a schematic diagram illustrating an additional perspective close-up view of the pneumatics control unit 800, the anti-vibration unit 1200, and the electronics and process control utilities 1300, and components thereof, as part of the sample preparation system 10 illustrated in FIGS. 1 and 2, in accordance with the present invention;

FIGS. 9A-9B are schematic diagrams illustrating additional perspective close-up views of the scribing and cleaving unit 1000, and components thereof, as part of the sample preparation system 10 illustrated in FIGS. 1 and 2, in accordance with the present invention;

FIG. 9C is a schematic diagram illustrating a perspective close-up section view of the scribing and cleaving unit 1000 illustrated in FIG. 9A, and components thereof, as part of the sample preparation system 10 illustrated in FIGS. 1 and 2, in accordance with the present invention;

FIGS. 10A-10B are schematic diagrams illustrating perspective close-up views of the micro-mask adhering unit 1100, and components thereof, as part of the sample preparation system 10 illustrated in FIGS. 1 and 2, in accordance with the present invention;

FIG. 10C is a schematic diagram illustrating a perspective close-up section view of the mask adhering unit 1100 illustrated in FIG. 10A, and components thereof, as part of the sample preparation system 10 illustrated in FIGS. 1 and 2, in accordance with the present invention;

FIGS. 11A-11B are schematic diagrams illustrating a perspective close-up view of a planar view sample preparation process involving performance of Step (d), using picking and placing unit 400, for picking and placing a material (for example, a processed (cut and mounted) form of sample precursor 20 adhered to a portion 121 of sample precursor support structure 120), from an initial position to another functionally dependent position, in accordance with the present invention;

FIGS. 12A-12B are schematic diagrams illustrating perspective views (FIG. 12B being a close-up of FIG. 12A) of Step (e), generating at least one micro-groove (for example, pair of micro-grooves 590) in a surface of a material (for example, sample precursor 20, having a designated target area or region of interest (ROI) T), by micro-groove generating unit 500 or 500′, in accordance with the present invention;

FIGS. 13A-13B are schematic diagrams illustrating perspective close-up views of (optional) Step (j), generating a scribe line (for example, scribe line 1050) on a surface of a material (for example, sample precursor 20 having a designated target area or region of interest (ROI) T), by scribing assembly 1002, (FIG. 13A), and cleaving the material (sample precursor 20) along the scribe line (scribe line 1050), by cleaving assembly 1004, (FIG. 13B), of scribing and cleaving unit 1000, in accordance with the present invention;

FIGS. 14A-14D are schematic diagrams illustrating perspective close-up views of three specific alternative preferred embodiments of the present invention, for performing (optional) Step (k), of marking a target area or region of interest (ROI) (for example, target area or region of interest (ROI) T) on a surface of sample precursor 20, by a marking device, where, in the first embodiment, the marking device corresponds to optical imaging unit 300 (FIGS. 14A and 14B); in the second embodiment, the marking device corresponds to micro-groove generating unit 500 or 500′ (FIGS. 14A and 14C); and in the third embodiment, the marking device corresponds to scribing assembly 1002 of scribing and cleaving unit 1000 (FIGS. 14A and 14D), in accordance with the present invention;

FIGS. 15A, and 15B-15C, are schematic diagrams illustrating perspective close-up views of the two main particular embodiments, respectively, of performing (optional) Step (m), for adhering a micro-mask, for example, micro-masking element 1110 (having a cylindrical shaped micron-sized wire (FIG. 15A), or a rectangular shaped profile (FIGS. 15B-15C)), onto a surface of sample precursor 20; in first particular embodiment (FIG. 15A), sample precursor 20 has been previously cryogenically sectioned according to cryogenic sectioning procedure of Step (i), and is adhered to a side view type of sample precursor support structure 110, and in second particular embodiment (FIGS. 15B-15C), sample precursor 20 has not been subjected to a cryogenic sectioning procedure, and includes a target area or region of interest (ROI) T, in accordance with the present invention;

FIGS. 16A-16M are schematic diagrams illustrating an exemplary specific preferred embodiment of a typical sequence of selected steps which are performed during a TEM side view (cross section) type of sample preparation procedure, by implementing the sample preparation system, and the corresponding sample preparation method, for preparing a sample for micro-analysis, in accordance with the present invention;

FIGS. 17A-17R are schematic diagrams illustrating an exemplary specific preferred embodiment of a typical sequence of selected steps which are performed during a TEM plan (planar) view type of sample preparation procedure, by implementing the sample preparation system, and the corresponding sample preparation method, for preparing a sample for micro-analysis, in accordance with the present invention;

FIGS. 18A-18K are schematic diagrams illustrating an exemplary specific preferred embodiment of a typical sequence of selected steps which are performed during an SEM side view (cross section) type of sample preparation procedure, by implementing the sample preparation system, and corresponding sample preparation method, for preparing a sample for micro-analysis, in accordance with the present invention; and

FIGS. 19A-19P are schematic diagrams illustrating an exemplary specific preferred embodiment of a typical sequence of selected steps which are performed during a TEM side view (cross section) type of sample preparation procedure, wherein the final prepared sample is supported by a prepared sample support element, by implementing the sample preparation system, and corresponding sample preparation method, for preparing a sample for micro-analysis, in accordance with the present invention.

### DESCRIPTION OF THE PREFERRED EMBODIMENTS

The present invention relates to a system and corresponding method of preparing a sample for micro-analysis. The present invention, particularly as relating to semiconductor manufacturing, micro-analytical testing, and materials science, is implementable prior to applying a micro-analytical sample final preparation technique, which, in turn, is used for preparing a sample in a final form ready for subjection to micro-analysis, such as by an electron microscopy technique, an atomic force microscopy technique, or/and an ion spectrometry technique, primarily for the purpose of inspecting or examining samples, especially for the presence of manufacturing defects or/and artifacts.

The present invention is a type of micro-analytical sample preparation technique which is based on sectioning or segmenting of at least a part of a material, such as a sample precursor, via reducing at least one dimension (length, width, or/and thickness, depth or height), of the size of the sample precursor, thereby producing a prepared sample ready for subjection to another process. Each of the terms ‘sectioning’ and ‘segmenting’, herein, equivalently referred to as ‘sectioning’, generally refers to reducing at least one dimension (length, width, or/and thickness, depth or height), of the size of a material, such as that of a sample precursor, by using one or more types of a cutting, cleaving, slicing, or/and polishing, procedure.

The present invention is applicable for performing various different procedures involved during the implementation of (1) thinning, (2) cross-sectioning, or/and (3) plan view sectioning, main categories of sectioning types of micro-analytical sample preparation techniques, according to the particular type of micro-analytical technique ultimately applied for analyzing a sample. The present invention is applicable for preparing micro-analytical samples of different types of materials, such as semiconductor materials (particularly, wafers, wafer segments, and wafer dies), ceramic materials, pure metallic materials, metal alloy materials, and composite materials thereof, where a given material is mono-crystalline, poly-crystalline, or amorphous. The present invention is applicable for preparing general area or specific site (target) samples that are suitable for being subjected to any of a variety of different types of sample final preparation techniques, and that are suitable for ultimately being subjected to any of a variety of different types of micro-analytical techniques.

The system for preparing a sample for micro-analysis, of the present invention, includes the following main components, and functionalities thereof: (a) a sample precursor holding unit, for holding a sample precursor; (b) a transporting and positioning unit, for transporting and positioning at least a part of the sample precursor holding unit; (c) an optical imaging unit, for optically imaging, recognizing, and identifying, target features located on the sample precursor, and for monitoring steps of the sample preparation; (d) a picking and placing unit, for picking and placing the sample precursor and selected components of the sample preparation system from initial positions to other functionally dependent positions; (e) a micro-groove generating unit, for generating at least one micro-groove in a surface of the sample precursor, wherein the micro-groove generating unit includes components for controlling depth and quality of each micro-groove in the surface; and (f) a cryogenic sectioning unit, for cryogenically sectioning the sample precursor to a pre-determined configuration and size, for forming the prepared sample.

The sample preparation system further includes an electronics and process control utilities, operatively (structurally or/and functionally) connected to each above stated main component (a)-(f) of the sample preparation system, for providing electronics to, and enabling process control of, each respective above stated sample preparation system main component (a)-(f).

The sample preparation system, of the present invention, optionally, further includes at least one additional main component selected from the group consisting of: (g) an adhering interface assembly, for enabling interfacing of (b) the transporting and positioning unit with (d) the picking and placing unit, for adhering a first component to a second component within the sample preparation system; (h) a pneumatics control unit, for controlling pneumatics of selected main components [(a) the sample precursor holding unit, (b) the transporting and positioning unit, (d) the picking and placing unit, and (f) the cryogenic sectioning unit] of the sample preparation system; (i) a sample precursor micro-size (surface area dimensions) reducing unit, for reducing size (surface area dimensions) of the sample precursor to a pre-determined sample precursor size; (j) a scribing and cleaving unit, for generating a scribe line on a surface of the sample precursor, and cleaving the sample precursor along the scribe line; (k) a micro-mask adhering unit, for adhering a micro-mask onto a surface of the sample precursor; and (l) an anti-vibration unit, for preventing or minimizing occurrence of vibrations during operation of the system.

When the sample preparation system includes at least one of the above stated (optional) additional main components (g)-(l), then, the electronics and process control utilities is also operatively (structurally or/and functionally) connected to each additionally included sample preparation system main component, for providing electronics to, and enabling process control of, each additionally included main component, in a manner operatively (structurally or/and functionally) integrated with previously stated sample preparation system main components (a)-(f). Accordingly, the present invention provides various alternative exemplary preferred embodiments of a sample preparation system, for preparing a sample for micro-analysis.

The method of preparing a sample for micro-analysis, of the present invention, includes the following main steps, and components thereof: (a) loading a sample precursor onto a sample precursor holding unit; (b) transporting and positioning at least a part of the sample precursor unit, by a transporting and positioning unit; (c) optically imaging, recognizing, and identifying, target features located on the sample precursor, and monitoring steps of the sample preparation, by an optical imaging unit; (d) picking and placing the sample precursor and selected components of the sample preparation system from initial positions to other functionally dependent positions, by a picking and placing unit; (e) generating at least one micro-groove in a surface of the sample precursor, by a micro-groove generating unit, wherein depth and quality of each micro-groove in the surface is controlled by components included in the micro-groove generating unit; and (f) cryogenically sectioning the sample precursor to a pre-determined configuration and size, for forming a prepared sample, by a cryogenic sectioning unit.

Preferably, the method of preparing a sample for micro-analysis further includes the step of providing electronics to, and enabling process control of, each main component of each above stated sample preparation method main step (a)-(f), by an electronics and process control utilities which is operatively connected to each above stated main component.

The method of preparing a sample for micro-analysis, of the present invention, optionally, further includes at least one additional main step (and components thereof) selected from the group consisting of: (g) adhering a first component to a second component within the sample preparation system, by an adhering interface assembly which enables interfacing of the transporting and positioning unit with the picking and placing unit; (h) controlling pneumatics of selected main components (a sample precursor holding unit, a transporting and positioning unit, a picking and placing unit, and a cryogenic sectioning unit) of the sample preparation system, by a pneumatics control unit; (i) reducing size (surface area dimensions) of the sample precursor to a predetermined sample precursor size, by a sample precursor micro-size (surface area dimensions) reducing unit; (j) generating a scribe line on a surface of the sample precursor, and cleaving the sample precursor along the scribe line, by a scribing and cleaving unit; (k) marking a target area or region of interest (ROI) on a surface of the sample precursor, by a marking device; (l) adhering a macro-mask onto a surface of the sample precursor, by selected sample preparation system main components; (m) adhering a micro-mask onto a surface of the sample precursor, by a micro-mask adhering unit; and (n) preventing or minimizing occurrence of vibrations during operation of the sample preparation system, by an anti-vibration unit.

Preferably, the method of preparing a sample for micro-analysis further includes the step of providing electronics to, and enabling process control of, each main component of each above stated at least one additional sample preparation method main step (g)-(n), by the electronics and process control utilities which is operatively connected to each main component of each respective above stated at least one additional main step (g)-(n), in a manner operatively integrated with each previously stated sample preparation method main step (a)-(f). Accordingly, the present invention provides various alternative exemplary preferred embodiments of a method of preparing a sample for micro-analysis.

The system, and corresponding method, for preparing a sample for micro-analysis, of the present invention, include several aspects of novelty and inventiveness over prior art techniques of micro-analytical sample preparation. Main aspects of novelty and inventiveness of the present invention are as follows.

A main aspect of novelty and inventiveness of the present invention is provision of an overall sample preparation system for preparing a sample for micro-analysis. The overall sample preparation system of the present invention includes several integrated units or devices each of which is also separable and integratable with other sample preparation systems.

Another main aspect of the present invention is provision of two alternative preferred embodiments of a micro-groove generating unit or device for generating at least one micro-groove in a surface of a sample precursor, as an exemplary material, wherein the micro-groove generating unit includes components for controlling depth (penetration), incremental resolution of depth (penetration), and quality, of each micro-groove in the surface. The micro-groove generating unit corresponds to an integrated unit or device of the overall system for preparing a sample for micro-analysis, of the present invention, and is also separable and integratable with other sample preparation systems.

Another main aspect of the present invention is provision of a cryogenic sectioning unit or device for cryogenically sectioning a sample precursor, as an exemplary material, to a pre-determined configuration and size, for forming a sectioned sample precursor. The cryogenic sectioning unit corresponds to another integrated unit or device of the overall system for preparing a sample for micro-analysis, of the present invention, and is also separable and integratable with other sample preparation systems.

Another main aspect of the present invention is provision of a micro-mask adhering unit or device for adhering a micro-mask onto a surface of sample precursor, as an exemplary material. The micro-mask adhering unit corresponds to another integrated unit or device of the overall system for preparing a sample for micro-analysis, of the present invention, and is also separable and integratable with other sample preparation systems.

Another main aspect of novelty and inventiveness of the present invention is provision of an overall sample preparation method of preparing a sample for micro-analysis. The overall sample preparation method of the present invention includes several integrated steps or procedures each of which is also separable and integratable with other sample preparation methods.

Another main aspect of the present invention is provision of a step or procedure of generating at least one micro-groove in a surface of a sample precursor, as an exemplary material, by a micro-groove generating unit, wherein depth (penetration), incremental resolution of depth (penetration), and quality, of each micro-groove in the surface are controlled by components included in the micro-groove generating unit. The micro-groove generating step or procedure corresponds to an integrated step or procedure of the overall method of preparing a sample for micro-analysis, of the present invention, and is also separable and integratable with other sample preparation methods.

Another main aspect of the present invention is provision of a step or procedure of cryogenically sectioning a sample precursor, as an exemplary material, to a pre-determined configuration and size, for forming a sectioned sample precursor, by a cryogenic sectioning unit. The cryogenic sectioning step or procedure corresponds to another integrated step or procedure of the overall method of preparing a sample for micro-analysis, of the present invention, and is also separable and integratable with other sample preparation methods.

Another main aspect of the present invention is provision of a step or procedure of adhering a macro-mask onto a surface of a sample precursor, as an exemplary material, by selected system units of the sample preparation system. The macro-mask adhering step or procedure corresponds to another integrated step or procedure of the overall method of preparing a sample for micro-analysis, of the present invention, and is also separable and integratable with other sample preparation methods.

Another main aspect of the present invention is provision of a step or procedure of adhering a micro-mask onto a surface of a sample precursor, as an exemplary material, by a micro-mask adhering unit. The micro-mask adhering step or procedure corresponds to another integrated step or procedure of the overall method of preparing a sample for micro-analysis, of the present invention, and is also separable and integratable with other sample preparation methods.

Regarding the micro-groove generating unit or device, and corresponding step or procedure, for generating at least one micro-groove in a surface of a sample precursor, as an exemplary material, the micro-groove generating unit includes specially designed, constructed, and operated, components, which enable highly accurate control of depth (penetration), incremental resolution of depth (penetration), and quality, during the formation and generation of each micro-groove in the surface of the material.

More specifically, wherein a first critical parameter for characterizing operation of the micro-groove generating unit of the sample preparation system of the present invention, relates to the depth penetration) of the micro-groove generating element into the surface of the material. For example, the depth (penetration) of the micro-groove generating element into the surface of the material is, preferably, in a range of from about 10 nanometers to about 10,000 nanometers, more preferably, in a range of from about 100 nanometers to about 2,000 nanometers, and most preferably, in a range of from about 300 nanometers to about 1,500 nanometers.

A second critical parameter for characterizing operation of the micro-groove generating unit of the sample preparation system of the present invention, relates to the incremental resolution of depth (penetration) of the micro-groove generating element into the surface of the material, where the incremental resolution of depth (penetration) of the micro-groove generating element into the surface of a material refers to the smallest incremental step of depth (penetration) that is attainable by a micro-groove depth (penetration) control sub-assembly, and a micro-groove depth (penetration) control sub-assembly. For example, the incremental resolution of depth (penetration) of the micro-groove generating element into the surface of the material is, preferably, in a range of from about 3 nanometers to about 7 nanometers.

A third critical parameter for characterizing operation of the micro-groove generating unit of the sample preparation system of the present invention, relates to the quality of each micro-groove generated in the surface of the material, where the quality of each micro-groove generated in the surface of the material refers to a set of features which indicate the integrity of the generated micro-groove. Such features are, for example, absence of micro-sized cracks along the walls of the generated micro-groove, topographical uniformity in terms of smoothness, straightness, and consistency, along the walls of the generated micro-groove.

There are several characteristics of the micro-groove generating unit of the sample preparation system of the present invention, which lead to achieving the primary function of detaching a pre-determined number of layers of the material adjacent to features in a target area or region of interest (ROI) on the surface of the material, in order to avoid undesirable generation of artifacts which may be induced during cryogenically sectioning of the material.

Such characteristics are: (1) the type of material of the micro-groove generating element, (2) the configuration, shape, or form, of the micro-groove generating element, (3) the sharpness or radius of the tip of the micro-groove generating element, (4) the angle of approach of the micro-groove generating element towards the surface of the material, and (5) the manner by which the force is applied towards the surface of the material, by the micro-groove generating element.

Regarding the cryogenic sectioning unit or device, and corresponding step or procedure, for cryogenically sectioning a sample precursor, as an exemplary material, to a pre-determined configuration and size, for forming a sectioned sample precursor, the cryogenic sectioning unit includes a cryogenic fluid reservoir which is operatively connected to a cryogenic fluid supply valving and distributing sub-assembly that includes a pressure control mechanism. The pressure control mechanism functions for maintaining the pressure of a cryogenic fluid reservoir at a constant value, regardless of changes or variability in the volume of the cryogenic fluid (for example, dual-phase liquid and gaseous nitrogen) present in the cryogenic fluid reservoir. Operation of the pressure control mechanism ensures that the cryogenic fluid is controllably supplied through the cryogenic fluid supply valving and distributing sub-assembly, and through a cryogenic fluid outlet nozzle(s) sub-assembly, as well as onto the sectioning blade (a fine sectioning blade or a coarse sectioning blade), as well as onto the material, during the cryogenic sectioning process.

Operative connection of the pressure control mechanism to the cryogenic fluid reservoir, and use thereof, for improving the controllability and reproducibility of cryogenically sectioning a material, represents a significant improvement over the cryogenic sectioning type of micro-analytical sample sectioning procedure which is disclosed in present assignee/applicant PCT Int'l. Pat. Appl. Publ. No. WO 02/054042.

Regarding the micro-mask adhering unit, and corresponding step or procedure, for adhering a micro-mask onto a surface of sample precursor, as an exemplary material, the micro-mask adhering unit includes a micro-size masking element which is composed of an electrically and thermally conductive material having a variable geometrical configuration, shape or form. The micro-size masking element enables the sample prepared according to the present invention to be subjected to ion beam milling types of micro-analytical sample final preparation techniques, in general, and broad ion beam milling types of micro-analytical sample final preparation techniques, in particular. Accordingly, the micro-size masking element is of such material and geometrical configuration, shape or form, such that preferably, the ion milling (material removal) rate of the micro-size masking element is compatible with the ion milling rate of a material on which the micro-size masking element is placed, during a final thinning process performed in a subsequent sample final preparation procedure.

Exemplary materials which compose the micro-size masking element are carbon materials, ceramic materials, metallic (pure metal or metal alloy) materials, and combination materials thereof. Exemplary geometrical configuration, shape or form, of such a material is cylindrical, rectangular, and trapezoidal. Exemplary diameter of a cylindrical configured material is in a range of from about 6 microns to about 25 microns. Exemplary section or profile of a rectangular configured material is in a range of from about 6 microns to about 25 microns. The micro-mask adhering unit, and corresponding method thereof, of the present invention, are implemented whereby a micro-size masking element is applied onto a surface of a sample prepared according to a TEM type of sectioning procedure, using a micro-size masking element in a manner significantly different from prior art micro-mask adhering techniques.

There are two main particular embodiments of the present invention wherein the micro-mask adhering unit is used, in accordance with an optional procedure, for adhering a micro-mask onto a surface of a material, for example, being a sample precursor. In a first particular embodiment, the micro-mask adhering unit is used for adhering a micro-mask onto a surface of a previously cryogenically sectioned sample precursor, at a pre-determined position and with a positioning accuracy in a range of between about 50 nanometers and about 150 nanometers, typically, being about 100 nanometers, having been cryogenically sectioned according to the cryogenic sectioning method of the present invention. Alternatively, in a second particular embodiment, the micro-mask adhering unit is used for adhering a micro-mask onto a surface of a material, for example, being a sample precursor, at a pre-determined position and with a positioning accuracy in a range of between about 50 nanometers and about 150 nanometers, typically, being about 100 nanometers, wherein the sample precursor has not been subjected to a cryogenic sectioning procedure.

Regarding the step or procedure of adhering a macro-mask onto a surface of a sample precursor, as an exemplary material, implementation thereof readily facilitates subjection of a prepared sample to subsequent micro-analytical sample final preparation techniques, such as those involving ion beam milling. Such sample final preparation techniques are relevant for at least four different main categories of different exemplary specific preferred embodiments of implementing the present invention, being: (A) TEM side view (cross section), (B) TEM plan (planar) view, (C) SEM side view (cross section), and (D) Back-side Exposing.

Accordingly, the present invention overcomes the various significant limitations and disadvantages which are associated with current practice of prior art sectioning types of micro-analytical sample preparation techniques, previously described in the Background, hereinabove, as relating to the particular type (physicochemical properties, characteristics, and behavior, and dimensions) of the initial sample precursor used and of the sectioned sample subsequently prepared, and as relating to the particular preparatory requirements of the micro-analytical technique which is ultimately used for analyzing a given sample.

Specifically, regarding the type of sample precursor which is used for preparing a sectioned (cut, sliced) sample, the present invention is particularly suitable for sectioning (cutting, slicing) in any specific direction in a mono-crystalline, poly-crystalline, or amorphous, type of sample precursor material, regardless of crystal boundaries or edges. The present invention is suitable for processing sample precursors having adjacent layers which poorly adhere to each other. The present invention is suitable for ‘in-line’ initial handling and processing of relatively large sample precursors, for example, a whole semiconductor wafer having a diameter of about 300 mm.

Specifically, regarding the type of the sectioned sample subsequently prepared, the present invention is suitable for preparing a sectioned sample which can be subsequently further sectioned (cut, cleaved, sliced, or/and polished) by essentially any type of sample final preparation technique, such as focused ion beam (FIB) milling, or broad ion beam (BIB) milling, or both. For preparation of a sectioned sample that is subsequently subjected to an ion beam milling type of sample final preparation technique, the present invention can produce a sectioned sample having relatively small size dimensions that require proportionately small amounts of ion beam milling time. This translates to decreasing the potential for introduction of contamination and artifacts to the sample, as a result of re-deposition during the ion beam milling process, thereby decreasing the potential that such contamination and artifacts may interfere with the mass spectrometry, and analysis thereof, required during a typical micro-analytical technique.

Specifically, regarding the particular preparatory requirements of the micro-analytical technique which is ultimately used for analyzing a given sample, the present invention is generally applicable for ultimate preparation of an SEM sample, or a TEM sample, or an STEM sample, or an EDS sample, or an AFM sample, or an SIMS sample, or a GDS sample. The present invention is therefore, generally applicable for the ultimate purpose of essentially any type of micro-analytical technique, for example, SEM, or TEM, or STEM, or EDS, or AFM, or SIMS, or GDS, respectively, without requiring an unnecessary number of various different systems, equipment, and methodologies.

Moreover, the present invention is fully applicable for ultimately preparing different types of sectioned samples, according to each main category, that is, (1) thinning, (2) cross-sectioning, and (3) plan view sectioning, of sectioning types of micro-analytical sample preparation techniques.

Furthermore, the present invention is implemented in a manner which significantly minimizes the formation of undesirable micro-sized cracks or/and artifacts in the sample during the sectioning (cutting, slicing) sawing process.

It is to be understood that the present invention is not limited in its application to the details of type, composition, construction, arrangement, order, and number, of the system units, system sub-units, devices, assemblies, sub-assemblies, mechanisms, structures, components, elements, and configurations, and, peripheral equipment, utilities, accessories, and materials, of the system, or to the details of the order or sequence, number, of procedures, steps, and sub-steps, of operation of the system, or of the method, set forth in the following illustrative description, and accompanying drawings, and examples, unless otherwise specifically stated herein. For example, the following description refers to a sample precursor as being an exemplary material which is prepared for ultimately being subjected to a micro-analytical technique, in order to illustrate implementation of the present invention. The present invention is capable of other embodiments and of being practiced or carried out in various ways. Although system units, system sub-units, devices, assemblies, sub-assemblies, mechanisms, structures, components, elements, and configurations, and, peripheral equipment, utilities, accessories, and materials, and, procedures, steps, sub-steps, which are equivalent or similar to those illustratively described herein can be used for practicing or testing the present invention, suitable system units, system sub-units, devices, assemblies, sub-assemblies, mechanisms, structures, components, elements, and configurations, and, peripheral equipment, utilities, accessories, and materials, and procedures, steps, sub-steps, are illustratively described and exemplified herein.

It is also to be understood that all technical and scientific words, terms, or/and phrases, used herein throughout the present disclosure have either the identical or similar meaning as commonly understood by one of ordinary skill in the art to which this invention belongs, unless otherwise specifically defined or stated herein. Phraseology, terminology, and, notation, employed herein throughout the present disclosure are for the purpose of description and should not be regarded as limiting.

It is to be fully understood that, unless specifically stated otherwise, the phrase ‘operatively connected’ is generally used herein, and equivalently refers to the corresponding synonymous phrases ‘operatively joined’, and ‘operatively attached’, where the operative connection, operative joint, or operative attachment, is according to a physical, or/and electrical, or/and electronic, or/and mechanical, or/and electromechanical, manner or nature, involving various types and kinds of hardware or/and software equipment and components. Additionally, it is to be fully understood that, unless specifically stated otherwise, the terms ‘connectable’, ‘connected’, and ‘connecting’, are generally used herein, and also may refer to the corresponding synonymous terms ‘joinable’, ‘joined’, and ‘joining’, as well as ‘attachable’, ‘attached’, and ‘attaching’.

Moreover, all technical and scientific words, terms, or/and phrases, introduced, defined, described, or/and exemplified, in the above Background section, are equally or similarly applicable in the illustrative description of the preferred embodiments, examples, and appended claims, of the present invention. Additionally, as used herein, the term ‘about’ refers to ±10% of the associated value.

System units, system sub-units, devices, assemblies, sub-assemblies, mechanisms, structures, components, elements, and configurations, and, peripheral equipment, utilities, accessories, and materials, procedures, steps, sub-steps, as well as operation, and implementation, of exemplary preferred embodiments, alternative preferred embodiments, specific configurations, and, additional and optional aspects, characteristics, or features, thereof, for preparing a sample for micro-analysis, according to the present invention, are better understood with reference to the following illustrative description and accompanying drawings. Throughout the following illustrative description and accompanying drawings, same reference numbers refer to same system units, system sub-units, devices, assemblies, sub-assemblies, mechanisms, structures, components, elements, and configurations, and, peripheral equipment, utilities, accessories, and materials. In the accompanying drawings a reference XYZ coordinate axis system is shown for indicating x, y, and z, directions relative to the components drawn therein.

In the following illustrative description of the present invention, included are main or principal system units, system sub-units, devices, assemblies, sub-assemblies, mechanisms, structures, components, elements, and configurations, and, peripheral equipment, utilities, accessories, and materials, and functions thereof, and, main or principal procedures, steps, and sub-steps, needed for sufficiently understanding proper ‘enabling’ utilization and implementation of the disclosed invention. Accordingly, description of various possible preliminary, intermediate, minor, or/and optional, system units, system sub-units, devices, assemblies, sub-assemblies, mechanisms, structures, components, elements, and configurations, and, peripheral equipment, utilities, accessories, and materials, or/and functions thereof, or/and, procedures, steps, or/and sub-steps, which are readily known by one of ordinary skill in the art, which are available in the prior art or/and technical literature relating to the present invention, are at most only briefly indicated herein.

### Overall Sample Preparation System

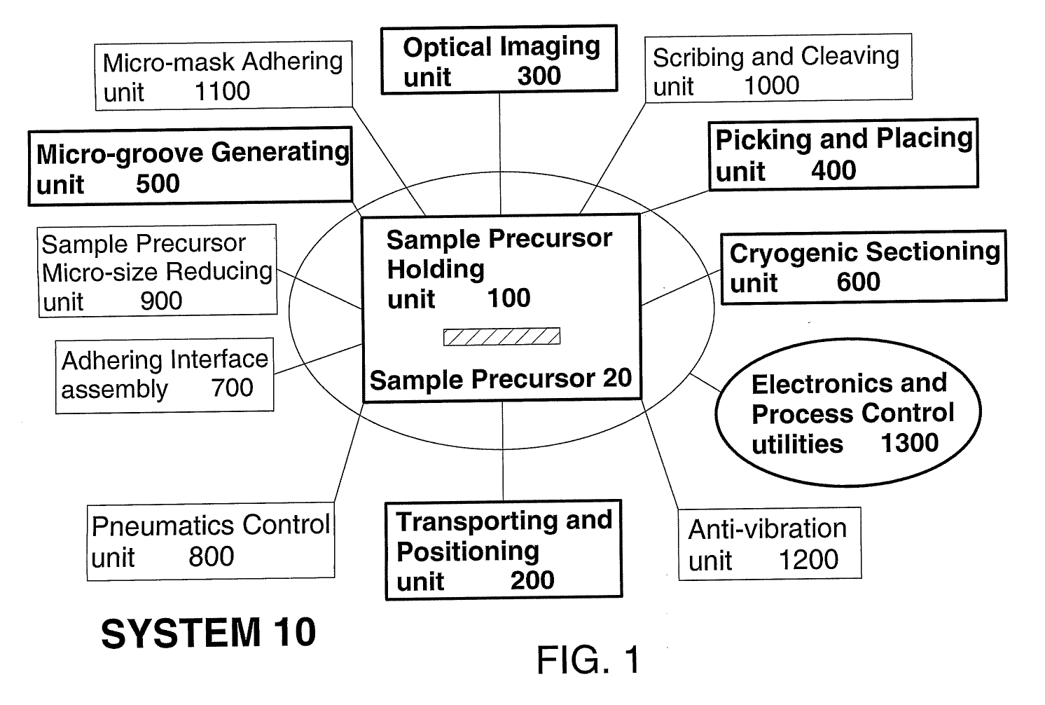

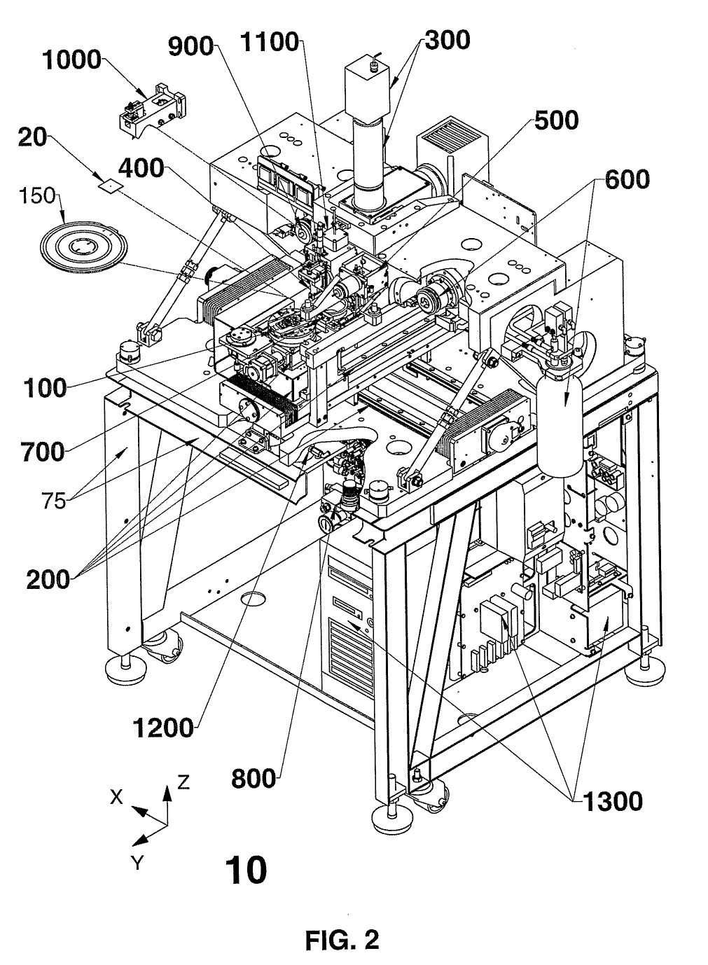

Thus, according to a main aspect of the present invention, there is provision of a system for preparing a sample for micro-analysis. Referring now to the drawings, FIG. 1 is a block diagram illustrating an exemplary preferred embodiment of the system, herein, generally referred to as sample preparation system 10, and main components thereof, for preparing a sample for micro-analysis. FIG. 2 is a schematic diagram illustrating a perspective view of the exemplary preferred embodiment of the system, sample preparation system 10, and main components thereof, shown in FIG. 1, for preparing a sample for micro-analysis.

As shown in FIGS. 1 and 2, sample preparation system 10, for preparing a sample for micro-analysis, of the present invention, includes the following main components: (a) a sample precursor holding unit 100, (b) a transporting and positioning unit 200, (c) an optical imaging unit 300, (d) a picking and placing unit 400, (e) a micro-groove generating unit 500, and (f) a cryogenic sectioning unit 600. As shown in FIGS. 1 and 2, sample preparation system 10 further includes an electronics and process control utilities 1300, operatively (structurally or/and functionally) connected to each of sample precursor holding unit 100, transporting and positioning unit 200, optical imaging unit 300, picking and placing unit 400, micro-groove generating unit 500, and cryogenic sectioning unit 600, for providing electronics to, and enabling process control of, each respective main component 100, 200, 300, 400, 500, and 600, of sample preparation system 10.

In FIG. 1, sample precursor 20, and the main components, that is, sample precursor holding unit 100, transporting and positioning unit 200, optical imaging unit 300, picking and placing unit 400, micro-groove generating unit 500, and cryogenic sectioning unit 600, along with electronics and process control utilities 1300, of sample preparation system 10, are shown highlighted by bold frames (rectangle or ellipse), letters, and reference numbers. Additionally, in FIG. 1, operative (structural or/and functional) connection of electronics and process control utilities 1300 to each sample preparation system main component—sample precursor holding unit 100, transporting and positioning unit 200, optical imaging unit 300, picking and placing unit 400, micro-groove generating unit 500, and cryogenic sectioning unit 600, is indicated by the larger (centrally located) ellipse intersecting operative connection lines extending from each sample preparation system main component to sample precursor holding unit 100.

Sample preparation system 10, optionally, further includes at least one additional main component selected from the group consisting of: (g) an adhering interface assembly 700, (h) a pneumatics control unit 800, (i) a sample precursor micro-size (surface area dimensions) reducing unit 900, (j) a scribing and cleaving unit 1000, (k) a micro-mask adhering unit 1100, and (l) an anti-vibration unit 1200.

When sample preparation system 10 includes at least one of the above stated (optional) additional main components 700, or/and 800, or/and 900, or/and 1000, or/and 1100, or/and 1200, then, electronics and process control utilities 1300 is also operatively (structurally or/and functionally) connected to each respective additionally included sample preparation system main component, for providing electronics to, and enabling process control of, each respective additionally included main component, in a manner operatively (structurally or/and functionally) integrated with previously stated sample preparation system main components 100, 200, 300, 400, 500, and 600. In FIG. 1, operative (structural or/and functional) connection of electronics and process control utilities 1300 to each optional at least one additional sample preparation system main component—adhering interface assembly 700, pneumatics control unit 800, sample precursor micro-size (surface area dimensions) reducing unit 900, scribing and cleaving unit 1000, micro-mask adhering unit 1100, and anti-vibration unit 1200, is indicated by the larger (centrally located) ellipse intersecting operative connection lines extending from each optional at least one additional sample preparation system main component to sample precursor holding unit 100.

Accordingly, the present invention provides various alternative exemplary preferred embodiments of a sample preparation system, that is, sample preparation system 10, for preparing a sample for micro-analysis.

In a non-limiting manner, as shown in FIG. 2, several units or components thereof, of sample preparation system 10, are directly mounted onto, and operatively connected to, a fixed or mobile (movable) table, stand, or fraine, type of system support assembly 75. System support assembly 75 includes appropriately constructed support elements, legs, brackets, and mobile (movable) elements, such as wheels. Other units or components thereof, of sample preparation system 10 are mounted onto those system units or components thereof which are directly mounted onto system support assembly 75.

Sample Precursor Holding unit

In sample preparation system 10, sample precursor holding unit 100 is for holding a sample precursor 20.

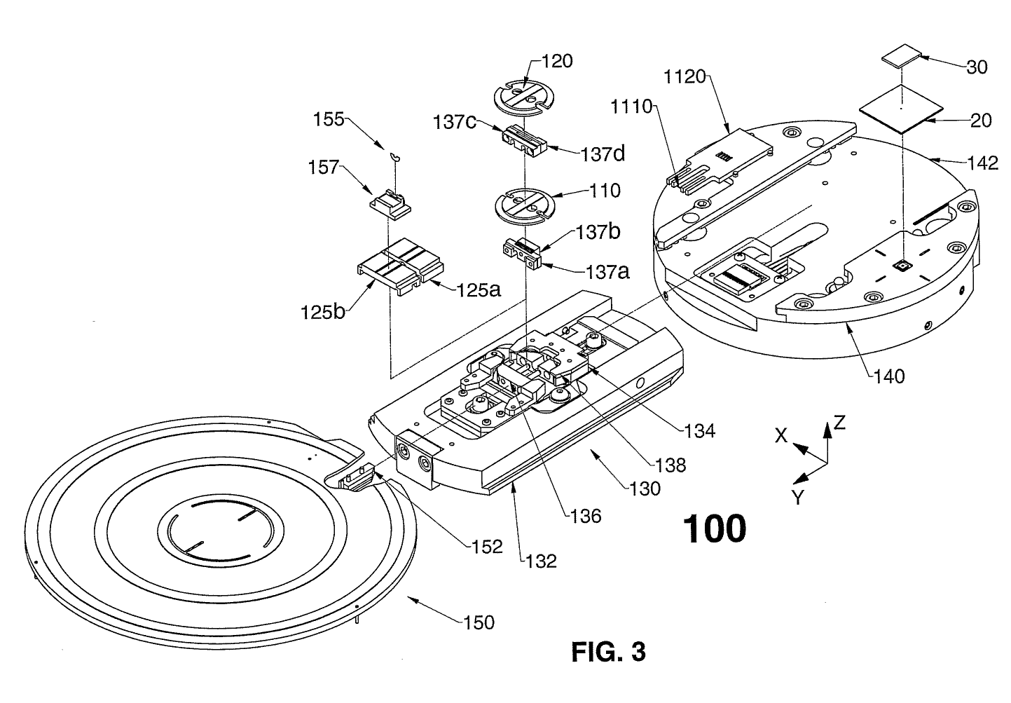

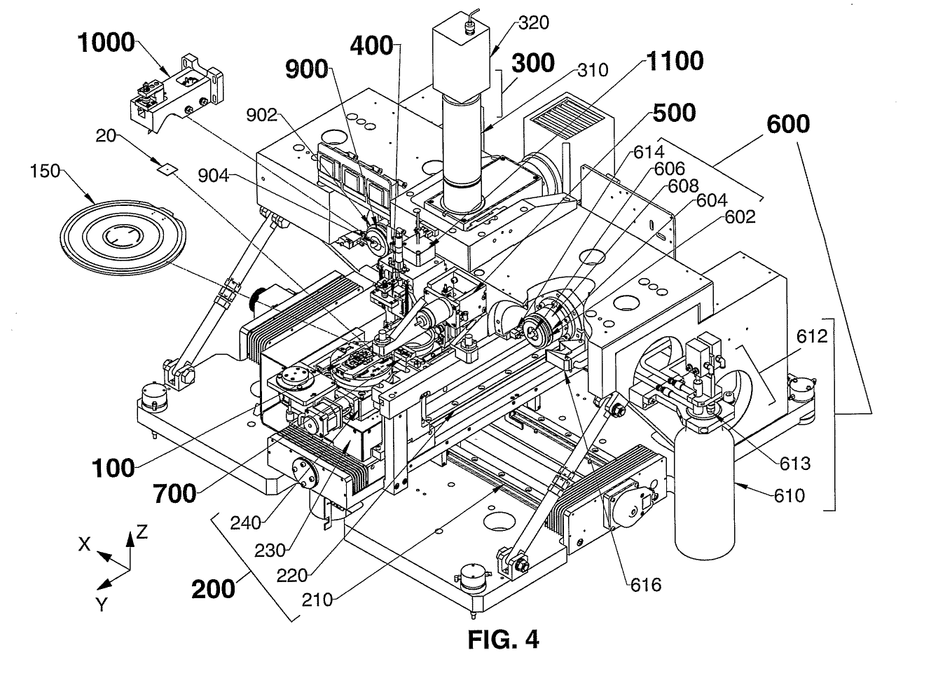

FIG. 3 is a schematic diagram illustrating a partly exploded perspective close-up view of sample precursor holding unit 100, and components thereof, as part of sample preparation system 10 illustrated in FIGS. 1 and 2. FIG. 4 is a schematic diagram illustrating a partly exploded perspective close-up view of sample precursor holding unit 100, in relation to other selected units (transporting and positioning unit 200, optical imaging unit 300, picking and placing unit 400, micro-groove generating unit 500, cryogenic sectioning unit 600, adhering interface assembly 700, sample precursor micro-size (surface area dimensions) reducing unit 900, scribing and cleaving unit 1000, and micro-mask adhering unit 1100), and components thereof, of sample preparation system 10 illustrated in FIGS. 1 and 2.

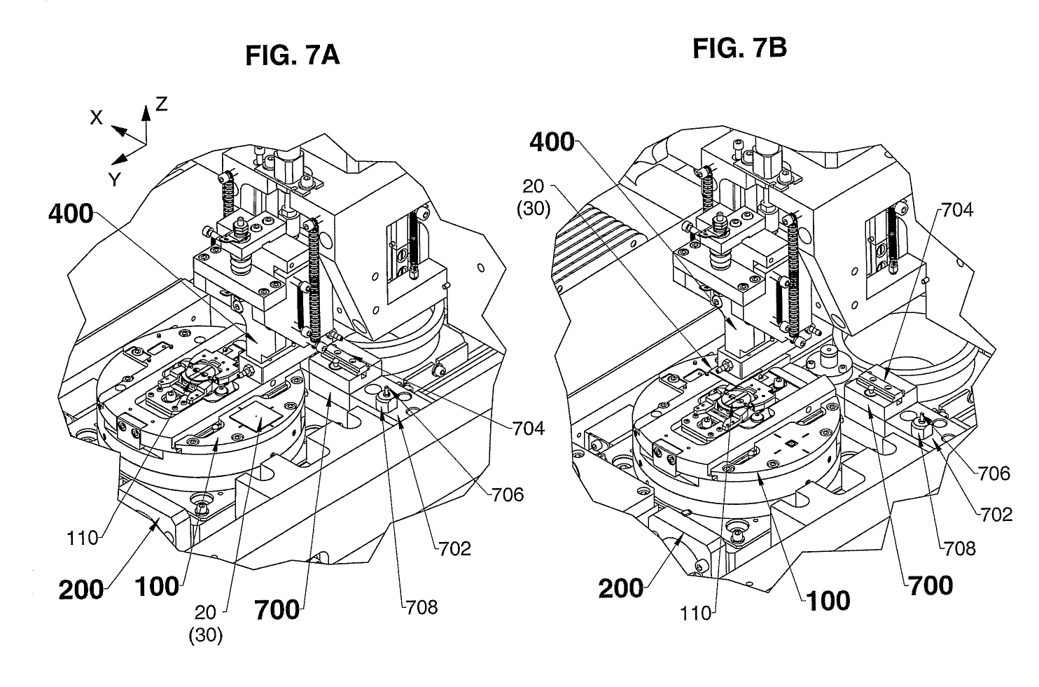

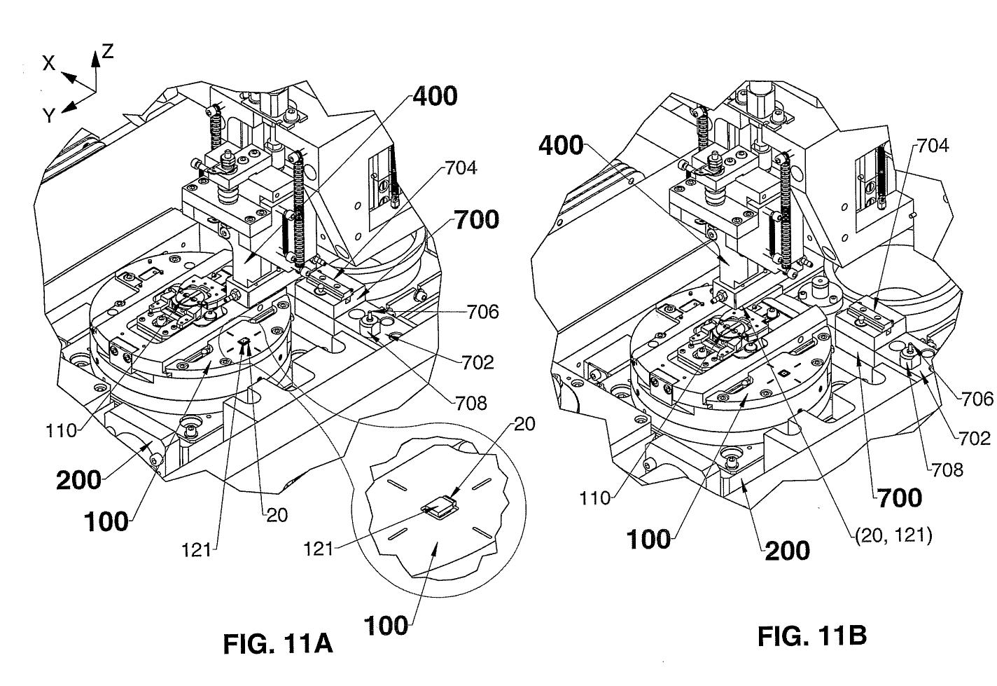

Sample precursor holding unit 100, and selected components thereof, are also illustrated in FIGS. 7A-7B, schematic diagrams illustrating additional perspective close-up views of adhering interface assembly 700, and components thereof, as part of sample preparation system 10 illustrated in FIGS. 1 and 2, in relation to sample precursor holding unit 100, transporting and positioning unit 200, and picking and placing unit 400, with (FIG. 7A) and (FIG. 7B) depicting final stages of adhering sample precursor 20 to an exemplary side view type of sample precursor support structure 110. Sample precursor holding unit 100, and selected components thereof, are also illustrated in FIGS. 11A-11B, schematic diagrams illustrating a perspective close-up view of a planar view sample preparation process involving performance of Step (d), using picking and placing unit 400, for picking and placing a material (for example, a processed (cut and mounted) form of sample precursor 20 adhered to a portion of sample precursor support structure 120), from an initial position to another functionally dependent position.

Sample precursor 20 corresponds to a pre-processed precursor of a final configured and sized sample thus prepared by completion of the sample preparation method of the present invention. Sample precursor 20, of an initial size, or of a reduced size, is ultimately cryogenically sawed to a pre-determined configuration and size, for forming the prepared sample, by cryogenic sectioning unit 600.

Sample precursor 20 is provided by an external source. In general, sample precursor 20 is includes or is composed of any number of a variety of different types of materials. For example, sample precursor 20 includes or is composed of at least one type of material selected from the group consisting of semiconductor materials, ceramic materials, pure metallic materials, metal alloy materials, polymeric materials, composite materials, and combinations thereof. For example, for sample precursor 20 including or being a semiconductor type of material, sample precursor 20 includes or is a single die (of a wafer), a wafer segment, or a whole wafer.

Sample precursor 20 has an initial size, herein, referred to as a sample precursor initial size, being defined by the two surface area dimensions of length and width, and by the third dimension of thickness or depth, of the initially provided sample precursor. Sample precursor 20 has surface area dimensions (in terms of length×width, or width×length, since the length and width of sample precursor 20 can be arbitrarily assigned) in the exemplary ‘operating or processing’ ranges of: (a) from about 1 mm×1 mm to the surface area dimensions of a large single die (for example, about 25 mm×25 mm), (b) a wafer segment (for example, about 40 mm×40 mm), or (c) a whole wafer (for example, a circular shape of about 300 mm diameter). Sample precursor 20 has an exemplary third dimension of thickness or depth of from about 0.1 mm to about 1.5 mm. For example, for sample precursor 20 being a semiconductor type of material (i.e., a single die (of a wafer), a wafer segment, or a whole wafer), typically, the wafer thickness is about 0.75 mm before any back grinding process is performed on the whole wafer during the wafer production stage.

A sample thus prepared and output by completing the method of the present invention, has a size, herein, referred to as a sample size, being defined by the two surface area dimensions of length and width, and by the third dimension of thickness or depth, of the sample. Preferably, the sample has an optimum size, herein, referred to as a sample optimum size, wherein values of the dimensions of the sample size are within optimum ranges which are most suitable for further processing the sample prepared by the present invention. For example, the value of each of the length and width of the sample is within an optimum range of equal to or greater than 1 mm and less than or equal to 3 mm. Accordingly, for the sample optimum size, the surface area dimensions of the sample are within an optimum range of equal to or greater than 1 mm×1 mm (length×width, or width×length, since the length and width of the sample can be arbitrarily assigned) and less than or equal to 3 mm×3 mm (length×width, or width×length).

Based on a comparison of the sample precursor initial size to the sample optimum size, the initially provided sample precursor is used ‘as is’, for continuing the sample preparation method, or is first processed, via at least one size (surface area dimensions) reducing procedure, for forming the sample precursor having a predetermined size which is then used for continuing the sample preparation method, all in accordance with the present invention.

With reference to FIG. 3, sample precursor holding unit 100 includes the main components of: (i) a sample precursor support structure 110 or 120, corresponding to a side view sample precursor support structure or a planar view sample precursor support structure, respectively, or, alternatively, a set of two sample precursor support structures 125a and 125b, (ii) a sample precursor support structure holder 130, and (iii) a chuck base assembly 140. Sample precursor holding unit 100, optionally, also includes a sample precursor macro-size holding chuck 150.

Sample precursor support structure 110 (side view) or 120 (planar view), corresponds to either a side view sample precursor support structure or a planar view sample precursor support structure, respectively, for rigidly and firmly supporting sample precursor 20 (during a side view sample preparation process), or for rigidly and firmly supporting a processed (cut and mounted) form of sample precursor 20 (during a planar view sample preparation process). An additional, optional, function of sample precursor support structure 110 (side view) or 120 (planar view), is for enabling re-working of a sample prepared by the method of the present invention. An exemplary type of re-work involves additional sectioning of a sample prepared by the present invention, for the purpose of enabling refined micro-analysis of the sample.

Sample precursor support structures 125a and 125b, as being an alternative to (i.e., instead of) a single sample precursor support structure 110 or 120, are for rigidly and firmly supporting sample precursor 20 during a side view or planar view sample preparation process, or for rigidly and firmly supporting a processed (cut and mounted) form of sample precursor 20 (during a planar view sample preparation process).

For the embodiment of sample precursor holding unit 100 which includes the set of two sample precursor support structures 125a and 125b, sample precursor holding unit 100 further includes: (iv) a prepared sample support element 155, and (v) a prepared sample support element holder 157.

Prepared sample support element 155 functions as either a side view prepared sample support element or a planar view prepared sample support element, for rigidly and firmly supporting a side view or planar view prepared sample. An additional, optional, function of prepared sample support element 155 is for enabling re-working of a sample prepared by the method of the present invention. An exemplary type of re-work involves additional sectioning of a sample prepared by the present invention, for the purpose of enabling refined micro-analysis of the sample.

Prepared sample support element holder 157 is for holding or fixing prepared sample support element 155. Preferably, prepared sample support element holder 157 is for being appropriately oriented and positioned relative to, and for being attached or connected to, one of the two sample precursor support structures 125a and 125b which supports sample precursor 20, in a manner such that prepared sample support element 155 can support, and be fixed to, the side of the final prepared sample.

Sample precursor support structure holder 130 is for holding or fixing sample precursor support structure 110 (side view) or 120 (planar view), or alternatively, for holding or fixing the set of two sample precursor support structures 125a and 125b. Sample precursor support structure holder 130 includes: (1) guides 132, configured along opposite sides of sample precursor support structure holder 130, for sliding and mounting of sample precursor support structure holder 130 into recessed mounting region 142 of chuck base assembly 140; (2) a holding or fixing mechanism 134, for holding or fixing sample precursor support structure 110 (side view) or 120 (planar view), or alternatively, the set of two sample precursor support structures 125a and 125b; and (3) a heating mechanism 136, for heating an adhesive applied to the top or upper side of sample precursor support structure 110 (side view) or 120 (planar view), or alternatively, of at least one of the two sample precursor support structures 125a and 125b.

For the embodiment of sample precursor holding unit 100 which includes sample precursor support structure 110 (side view) or 120 (planar view), sample precursor support structure holder 130 further includes: (4) an interface assembly [137a and 137b associated with sample precursor support structure 110 (side view), or, 137c and 137d associated with sample precursor support structure 120 (planar view)], for interfacing between sample precursor support structure 110 (side view) or 120 (planar view) and sample precursor support structure holder 130.

Holding or fixing mechanism 134 includes a clamping mechanism 138 for engaging and clamping sample precursor support structure 110 (side view) or 120 (planar view), or alternatively, for engaging and clamping the set of two sample precursor support structures 125a and 125b.

Chuck base assembly 140 is for serving as a base for initial mounting of sample precursor 20, and for subsequent mounting of sample precursor support structure holder 130. Chuck base assembly 140 includes a recessed mounting region 142, for mounting of sample precursor support structure holder 130, via guides 132. For a pre-determined initial size of sample precursor 20, chuck base assembly 140, optionally, is for serving as a base for the mounting of sample precursor macro-size holding chuck 150, via guides 152 configured beneath sample precursor macro-size holding chuck 150.

Sample precursor macro-size holding chuck 150 is for supporting and holding (and enabling navigation of) sample precursor 20 having surface area dimensions larger than pre-determined values. For example, sample precursor macro-size holding chuck 150 is for supporting and holding (and enabling navigation of) sample precursor 20 having above described surface area dimensions in the second or third exemplary operating or processing ranges of: (b) a wafer segment (for example, about 40 mm×40 mm), or (c) a whole wafer (for example, a circle of about 300 mm diameter). Guides 152 configured along the underside of sample precursor macro-size holding chuck 150 are for sliding and mounting of sample precursor macro-size holding chuck 150 into recessed mounting region 142 of chuck base assembly 140.

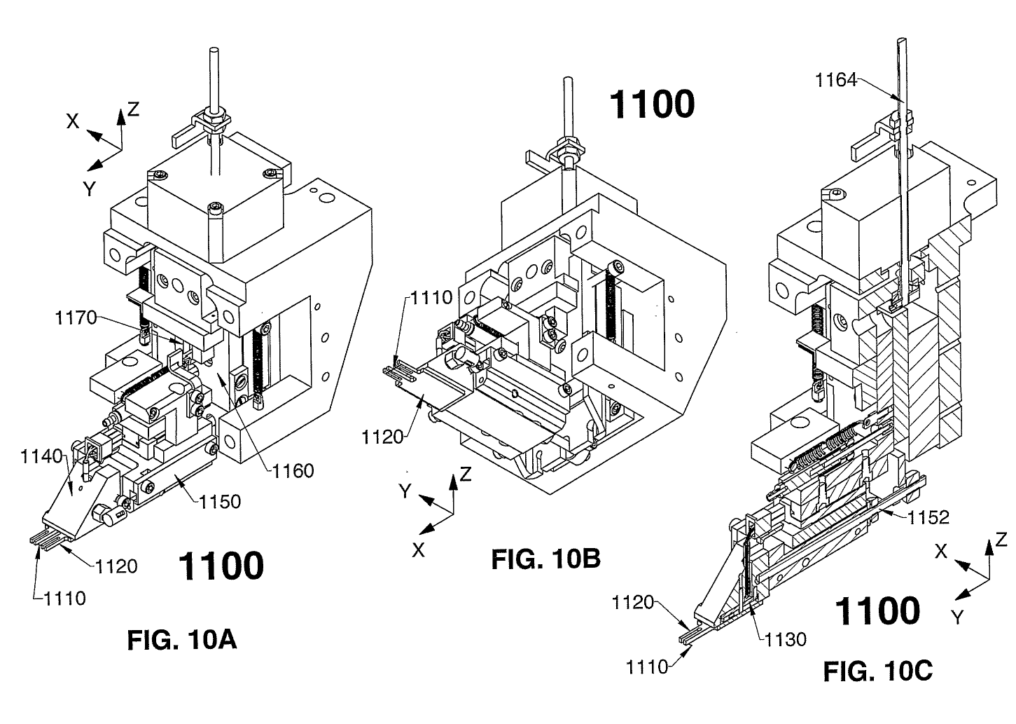

The functions of sample precursor holding unit 100, and components thereof, as illustratively described hereinabove, being performed on sample precursor 20, are alternatively or additionally, similarly performed on a masking element. Herein, a masking element refers to an element which masks at least a portion of a sample precursor, such as sample precursor 20, for the objective of protecting the at least portion of the sample precursor during another sample preparation procedure, not necessarily implemented by the present invention. Such a masking element may be in the form of a ‘macro-size’ masking element 30 (particularly shown, for example, in FIG. 3), for example, operatively associated with, or part of, picking and placing unit 400 (FIGS. 1, 2, 4, 7A, 7B, 11A, and 11B), or alternatively, may be in the form of a ‘micro-size’ masking element 1110 (particularly shown, for example, in FIGS. 10A, 10B, and 10C), for example, associated with, or part of, micro-mask adhering unit 1100 (FIGS. 1, 2, 4, 10A, 10B, and 10C).

### Transporting and Positioning Unit

Transporting and positioning unit 200 is for transporting and positioning at least a part of sample precursor holding unit 100.

Reference is again made to FIGS. 1, 2, and 4, where FIG. 4 shows a perspective close-up view of transporting and positioning unit 200 in relation to other selected units (sample precursor holding unit 100, optical imaging unit 300, picking and placing unit 400, micro-groove generating unit 500, cryogenic sectioning unit 600, adhering interface assembly 700, sample precursor micro-size (surface area dimensions) reducing unit 1000, scribing and cleaving unit 1100, and micro-mask adhering unit 1200), and components thereof, of sample preparation system 10 illustrated in FIGS. 1 and 2. Transporting and positioning unit 200, and selected components thereof, are also illustrated in FIGS. 7A-7B, and in FIGS. 11A-11B.

With reference to FIG. 4, transporting and positioning unit 200 includes the main components of: (i) an x-axis displacement sub-assembly 210, (ii) a y-axis displacement sub-assembly 220, (iii) a z-axis displacement sub-assembly 230, and (iv) a rotatable stage sub-assembly 240.

Each of x-axis displacement sub-assembly 210, y-axis displacement sub-assembly 220, z-axis displacement sub-assembly 230, and rotatable stage sub-assembly 240, includes a motor for enabling controllable motion of each respective axial displacement sub-assembly. In addition, each of x-axis displacement sub-assembly 210, y-axis displacement sub-assembly 220, z-axis displacement sub-assembly 230, and optionally, rotatable stage sub-assembly 240, includes an encoder for enabling control of the motion of each respective axial displacement sub-assembly. Rotatable stage sub-assembly 240 serves as a rotatable stage for chuck base assembly 140 of sample precursor holding unit 100.

### Optical Imaging Unit

Optical imaging unit 300 is for optically imaging, recognizing, and identifying, target features located on sample precursor 20, and is for monitoring steps and procedures of the overall sample preparation method.

Reference is again made to FIGS. 1, 2, and 4, where FIG. 4 shows a perspective close-up view of optical imaging unit 300, in relation to other selected units (sample precursor holding unit 100, transporting and positioning unit 200, picking and placing unit 400, micro-groove generating unit 500, cryogenic sectioning unit 600, adhering interface assembly 700, sample precursor micro-size (surface area dimensions) reducing unit 900, scribing and cleaving unit 1000, and micro-mask adhering unit 1100), and components thereof, of sample preparation system 10 illustrated in FIGS. 1 and 2.

Optical imaging unit 300 includes the main components of: (i) a microscope assembly 310, (ii) a camera 320, and (iii) a frame grabber. Preferred structural and functional features and characteristics of optical imaging unit 300 are as follows.

Microscope assembly 310 includes several objectives. Camera 320 is, for example, a CCD camera. The frame grabber is included as software or/and hardware as part of computerized control unit 1302 which is included in electronics and process control utilities 1300 (FIGS. 1, 2, 8). Optical imaging unit 300 generates raw images which are processed using image processing and analysis software algorithms, for producing processed images.

As an example, for sample precursor 20 being a semiconductor type of material (i.e., a single die (of a wafer), a wafer segment, or a whole wafer), typical exemplary target features located on sample precursor 20 which are optically imaged, recognized, and identified, by optical imaging unit 300 are defects, artifacts, or/and specific characteristics such as those pertaining to a lithographic process during a wafer manufacturing process.

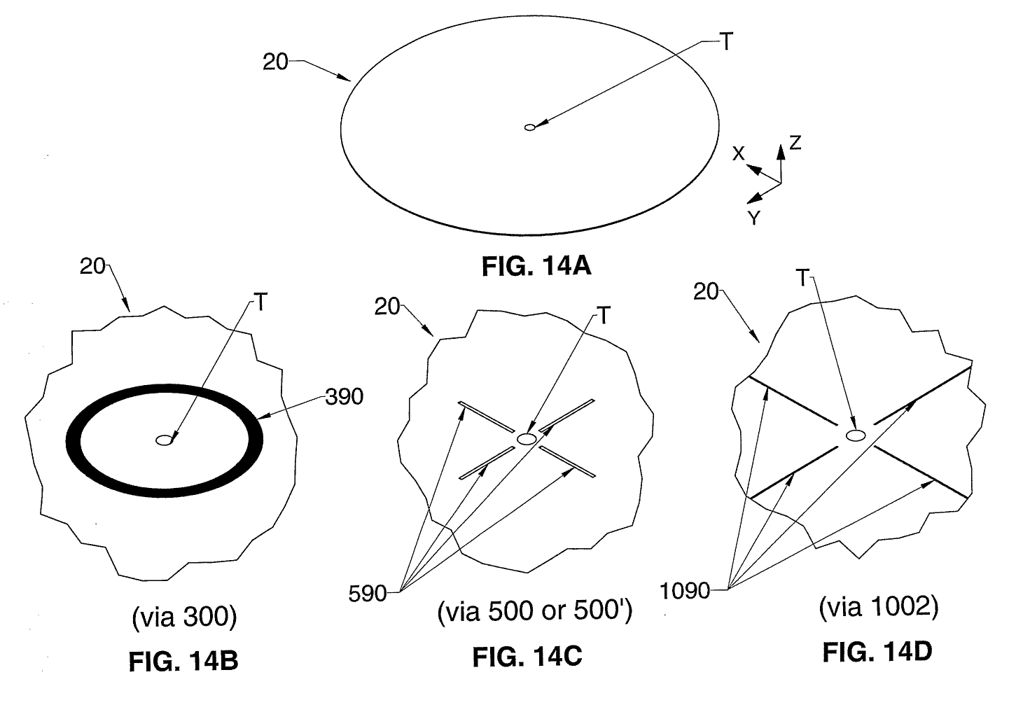

In addition to the main functions of optical imaging unit 300 optically imaging, recognizing, and identifying, target features located on sample precursor 20, and monitoring steps and procedures of the overall sample preparation method, optical imaging unit 300 can be used for performing (optional) Step (k), of marking a target area or region of interest (ROI) on a surface of sample precursor 20, by a marking device. In a first specific alternative preferred embodiment of the present invention, for performing (optional) Step (k), in sample preparation system 10, the marking device corresponds to optical imaging unit 300. According to this embodiment, one of the lens heads of microscope assembly 310 does not include an objective lens, and instead, has seated thereupon a spring loaded ink printing head, which is then used for marking, for example, via a circle 390, a target area or region of interest (ROI), for example, target area or region of interest (ROI) T, on a surface of sample precursor 20, as schematically illustrated in FIGS. 14A and 14B.

### Picking and Placing Unit

Picking and placing unit 400 is for picking and placing sample precursor 20 and various selected components of sample preparation system 10, from initial positions to other functionally dependent positions.

Reference is again made to FIGS. 1, 2, and 4, where FIG. 4 shows a perspective close-up view of picking and placing unit 400, in relation to other selected units (sample precursor holding unit 100, transporting and positioning unit 200, optical imaging unit 300, micro-groove generating unit 500, cryogenic sectioning unit 600, adhering interface assembly 700, sample precursor micro-size (surface area dimensions) reducing unit 900, scribing and cleaving unit 1000, and micro-mask adhering unit 1100), and components thereof, of sample preparation system 10 illustrated in FIGS. 1 and 2. Picking and placing unit 400, and selected components thereof, are also illustrated in FIGS. 7A-7B, and in FIGS. 11A-11B.

Picking and placing unit 400 includes the main components of: (i) a sample precursor holding aperture (not shown in FIG. 4), (ii) an adhesive application needle aperture (not shown in FIG. 4). Pneumatic and electronic control of the apertures are performed by pneumatics control unit 800, and electronics and process control utilities 1300, respectively, in such a manner that also enables the control of force of application of the components to which adhesive has been applied.

Picking and placing unit 400 is for picking and placing sample precursor 20, or one or more of the following components of sample preparation system 10, from initial positions to other functionally dependent positions: an adhesive applying needle, a masking element, or/and a processed (cut and mounted) form of sample precursor 20.

More specifically, for example, picking and placing unit 400 picks and places sample precursor 20 from an initial location or position (for example, on chuck base assembly 140) to at least one other location or position (for example, on sample precursor support structure 110 (side view) or 120 (planar view)), of sample precursor holding unit 100 (FIG. 3).

More specifically, for example, picking and placing unit 400 picks and places an adhesive applying needle, for example, adhesive applying needle 706 of adhesive applying sub-assembly 702, of adhering interface assembly 700 (as shown in FIGS. 7A and 7B, depicting final stages of adhering the sample precursor 20 to an exemplary side view type of sample precursor support structure 110).

More specifically, for example, picking and placing unit 400 picks and places a masking element, for example, a masking element being in the form of macro-size masking element 30 (particularly shown, for example, in FIG. 3), for example, operatively associated with, or part of, picking and placing unit 400 (FIGS. 1, 2, 4, 7A, 7B, 11A, and 11B).

Picking and placing unit 400 has a first additional functionality of assisting in measuring thickness of sample precursor 20, at any stage during implementation of the sample preparation method of the present invention. Picking and placing unit 400 has a second additional functionality of applying a controllable adhesive force to sample precursor 20 during performance of the adhesive process of Step (g), involving adhering sample precursor 20 to a sample precursor support structure 110 (side view) or 120 (planar view), by adhering interface assembly 700.

An illustrative example of using picking and placing unit 400 of sample preparation system 10, of the present invention, is shown in FIGS. 11A-11B, schematic diagrams illustrating a perspective close-up view of a planar view sample preparation process involving the performance of Step (d), illustratively described hereinbelow, for picking and placing a material, for example, a processed (cut and mounted) form of sample precursor 20 adhered to a portion 121 of sample precursor support structure 120, from an initial position to another functionally dependent position.

### Micro-Groove Generating Unit

Micro-groove generating unit 500 is for generating at least one micro-groove in a surface of sample precursor 20, wherein micro-groove generating unit 500 includes components for controlling depth and quality of each micro-groove in the surface of sample precursor 20.

Reference is again made to FIGS. 1, 2, and 4, where FIG. 4 shows a perspective close-up view of micro-groove generating unit 500, in relation to other selected units (sample precursor holding unit 100, transporting and positioning unit 200, optical imaging unit 300, picking and placing unit 400, cryogenic sectioning unit 600, adhering interface assembly 700, sample precursor micro-size (surface area dimensions) reducing unit 900, scribing and cleaving unit 1000, and micro-mask adhering unit 1100), and components thereof, of sample preparation system 10 illustrated in FIGS. 1 and 2.

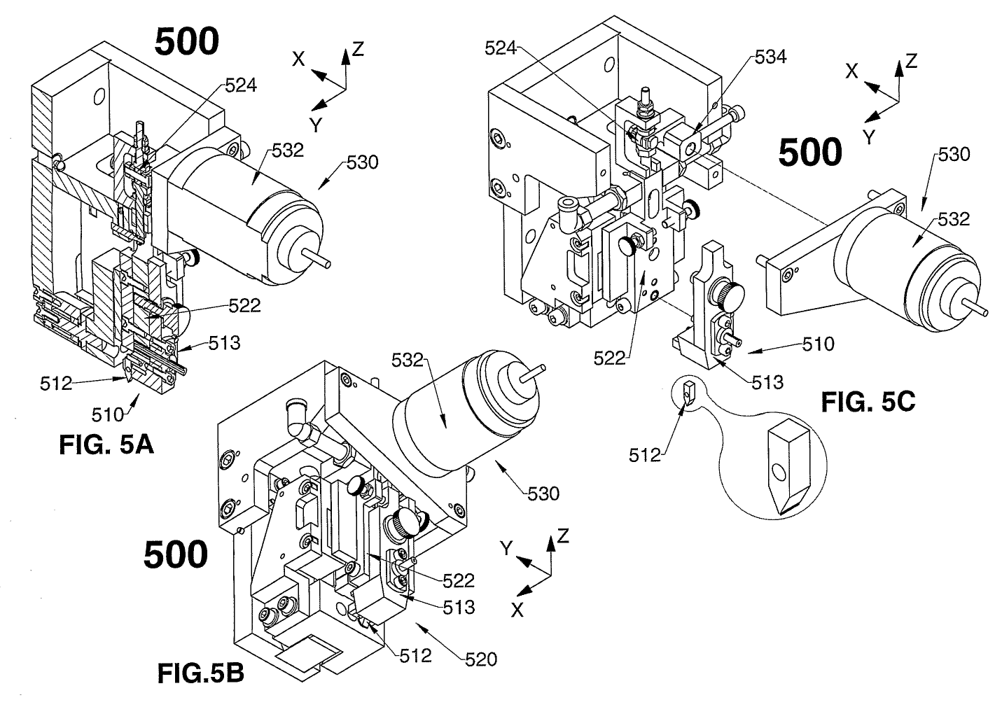

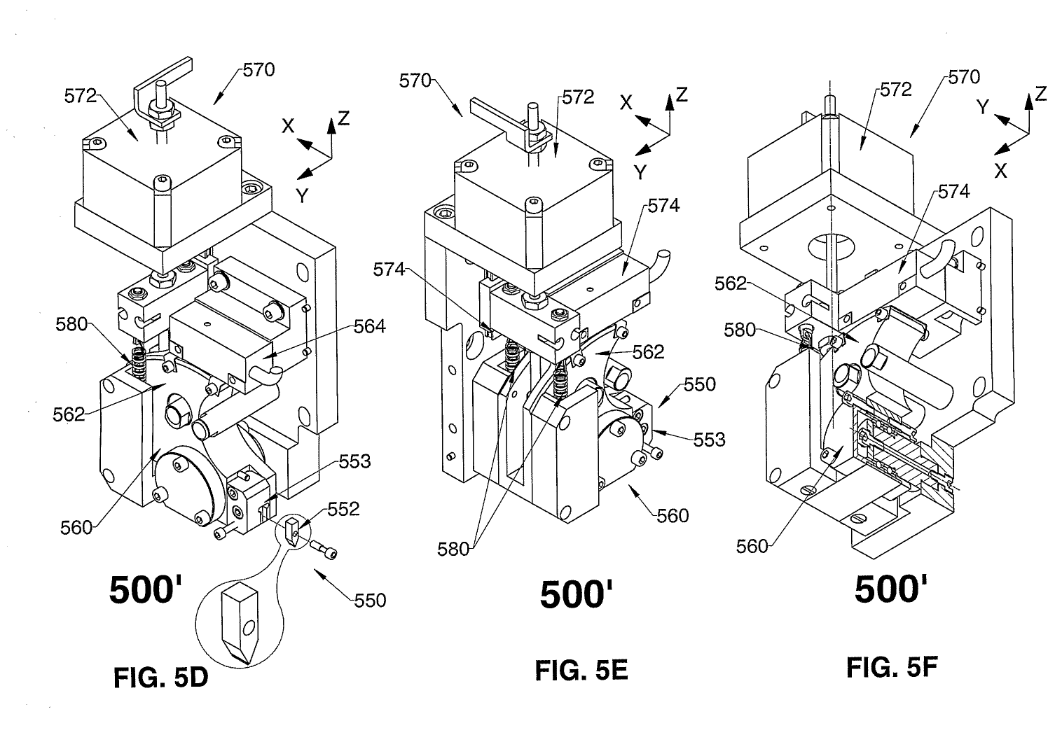

FIGS. 5A-5C are schematic diagrams illustrating additional perspective close-up front (FIG. 5A), underside (FIG. 5B), and partly exploded (FIG. 5C), views of micro-groove generating unit 500, and components thereof, as part of sample preparation system 10 illustrated in FIGS. 1 and 2.

Micro-groove generating unit 500 includes the main components of: (i) a micro-groove generating element assembly 510, (ii) a vertical displacement assembly 520, for example, an air bearing assembly, or alternatively, a low friction linear ball bearing assembly, and (iii) a force applying assembly 530.

Micro-groove generating element assembly 510 includes the main components of: (1) a micro-groove generating element 512, and (2) a micro-groove generating element holder assembly 513.

Micro-groove generating element 512 is, preferably, a blade or knife with a micro-groove generating tip. The micro-groove generating tip of the blade or knife has a radius, preferably, of less than about 100 nanometers, more preferably, less than about 30 nanometers, and most preferably, less than about 20 nanometers. The micro-groove generating tip of the blade or knife is, preferably, composed of a natural or synthetic diamond or diamond-like material. Micro-groove generating element 512 is a system consumable. Micro-groove generating element assembly 510 is readily reversibly mountable onto/off of vertical displacement assembly 520, for enabling ease of exchangeability of micro-groove generating element 512.

Vertical displacement assembly 520 includes the main components of: (1) a bearing sub-assembly 522, for example, an air bearing sub-assembly, or alternatively, a low friction linear ball bearing sub-assembly, and (2) a micro-groove depth (penetration) control sub-assembly 524. Vertical displacement assembly (air type or low friction linear ball type) 520 is for vertically displacing, and therefore, penetrating, micro-groove generating element 512 into the surface of sample precursor 20.

Vertical displacement assembly 520 is particularly mountable onto the housing of micro-groove generating unit 500 in a manner that allows for a rotational degree of freedom of micro-groove generating element 512 with respect to the x-axis, and therefore, in relation to the surface of sample precursor 20. This provides for a variably controllable angle of approach of micro-groove generating element 512 towards the surface of sample precursor 20. Such rotation, and therefore, angle of approach of micro-groove generating element 512 towards the surface of sample precursor 20 is enabled by an aligning assembly (for example, a combination of two pneumatic pistons operatively connected to, and controlled by, pneumatics control unit 800), that acts upon vertical displacement assembly 520, and is controllable by micro-groove depth (penetration) control sub-assembly 524.

Force applying assembly 530 includes the main components of: (1) a force generating motor 532, for example, a direct current (DC) motor, and (2) a force applying arm 534. Force applying assembly 530 is for applying a controllable force to micro-groove generating element 512. Via operation of micro-groove depth (penetration) control sub-assembly 524 of vertical displacement assembly 520, there is provided a controllable displacement of micro-groove generating element 512 into the surface of sample precursor 20.

An alternative embodiment of micro-groove generating unit 500, and components thereof, as part of sample preparation system 10 illustrated in FIGS. 1 and 2, is herein illustratively described. Reference is made to FIGS. 5D-5F, which are schematic diagrams illustrating perspective close-up front (FIG. 5D), side (FIG. 5E), and partly section underside (FIG. 5F), views of micro-groove generating unit 500′, and components thereof, as an alternative embodiment of the micro-groove generating unit 500, and components thereof, as part of sample preparation system 10 illustrated in FIGS. 1 and 2.

As shown in FIGS. 5D-5F, micro-groove generating unit 500′ includes the main components of: (i) a micro-groove generating element assembly 550, (ii) an aligning assembly 560, (iii) a vertical displacement assembly 570, and (iv) a force applying assembly 580.

Micro-groove generating element assembly 550 includes the main components of: (1) a micro-groove generating element 552, and (2) a micro-groove generating element holder assembly 553.

Micro-groove generating element 552 is, preferably, a blade or knife with a micro-groove generating tip. The micro-groove generating tip of the blade or knife has a radius, preferably, of less than about 100 nanometers, more preferably, less than about 30 nanometers, and most preferably, less than about 20 nanometers. The micro-groove generating tip of the blade or knife is, preferably, composed of a natural or synthetic diamond or diamond-like material. Micro-groove generating element 552 is a system consumable. Micro-groove generating element assembly 550 is readily reversibly mountable onto/off of vertical displacement assembly 570, for enabling ease of exchangeability of micro-groove generating element 552.

Aligning assembly 560 includes the main components of: (1) a rotational stage sub-assembly 562, and (2) a micro-groove depth (penetration) control sub-assembly 564. Aligning assembly 560 controls the angle of approach of micro-groove generating element 552 towards, and penetration into, the surface of sample precursor 20.

Vertical displacement assembly 570 includes the main components of: (1) a motorized linear actuator 572, and (2) a linear bearing sub-assembly 574. Vertical displacement assembly 570 transmits movement to aligning assembly 560 such that the vertical displacement of micro-groove generating element 552 is converted, via rotational stage sub-assembly 562, to a rotational displacement, whereby micro-groove depth (penetration) control sub-assembly 564 controls the angle of approach towards, and penetration into, the surface of sample precursor 20 by micro-groove generating element 552.

Force applying assembly 580 includes the main component of a set of force applying members, for example, springs. Force applying assembly 580 is for applying a controllable force to micro-groove generating element 552.

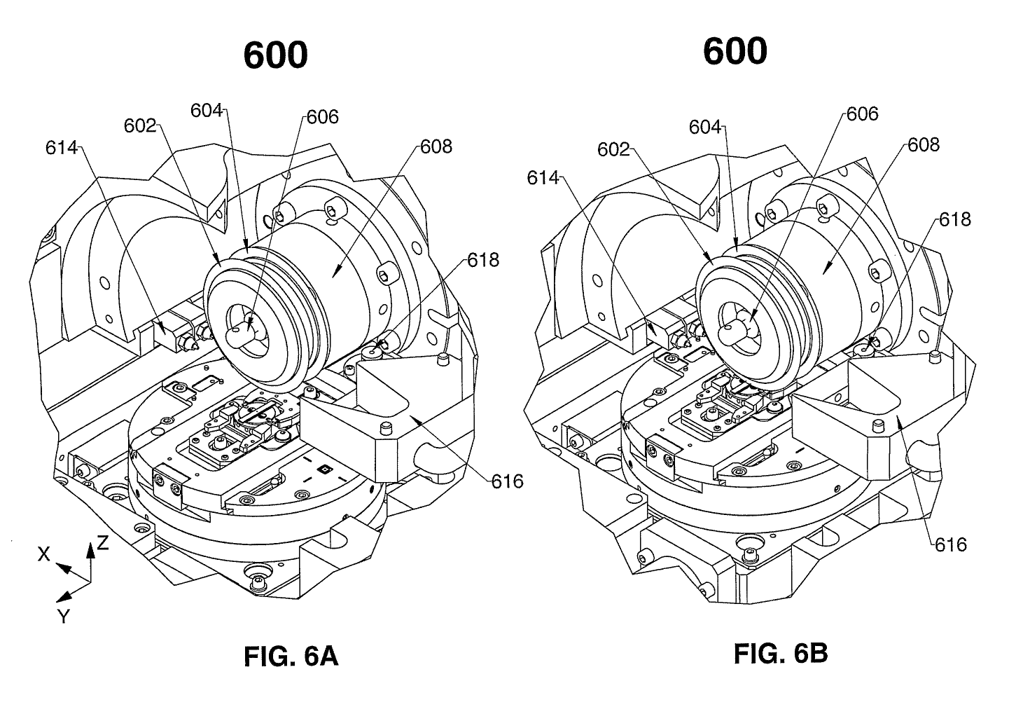

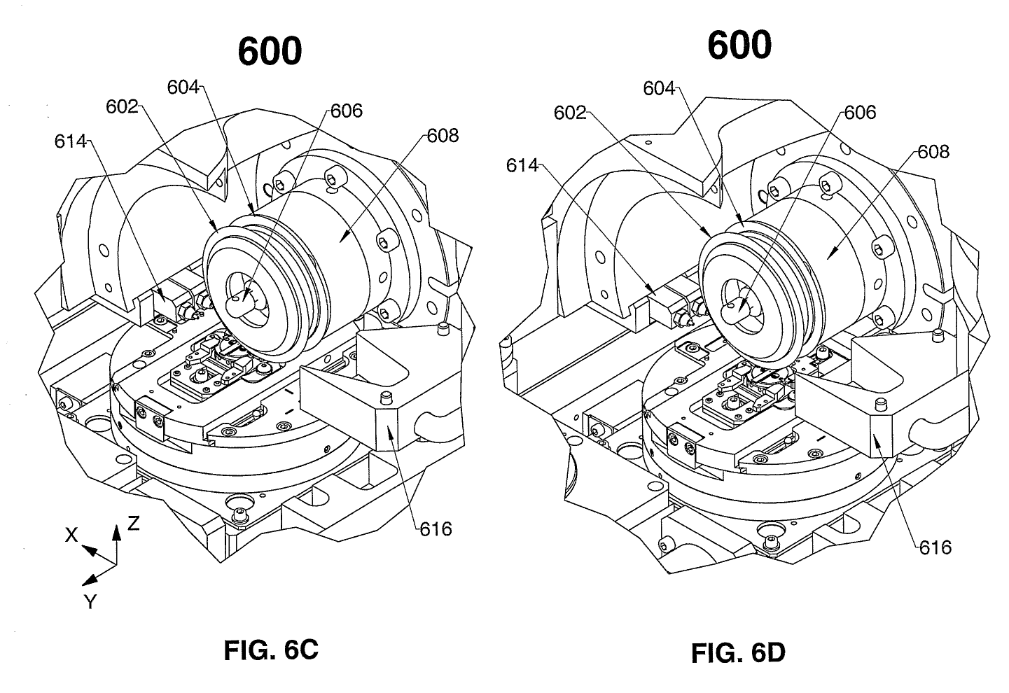

The micro-groove generating unit of sample preparation system 10 of the present invention, being either preferred embodiment, micro-groove generating unit 500 or micro-groove generating unit 500′, has a primary function of detaching a pre-determined number of layers of sample precursor 20 adjacent to features in a target area or region of interest (ROI) on sample precursor 20, in order to avoid undesirable generation of artifacts which may be induced during cryogenically sectioning of sample precursor 20. This function enables achieving the main objective of using a fine sectioning blade, for example, fine sectioning blade 602, of cryogenic sectioning unit 600, to obtain a required ‘critical’ thickness (critical width (CW)) dimension having a typical range of from about 3 microns to about 30 microns, with the best quality of side walls adjacent to the target area, as described and illustrated in FIGS. 6A-6D hereinbelow.

The micro-groove generating unit of sample preparation system 10 of the present invention, being either preferred embodiment, micro-groove generating unit 500 or 500′, includes the hereinabove illustratively described specially designed, constructed, and operated, components, which enable highly accurate control of depth (penetration), incremental resolution of depth (penetration), and quality, during the formation and generation of each micro-groove in the surface of the material of sample precursor 20.

A first critical parameter for characterizing operation of the micro-groove generating unit of sample preparation system 10 of the present invention, being either preferred embodiment, micro-groove generating unit 500 or micro-groove generating unit 500′, relates to the depth (penetration) of the micro-groove generating element, that is, micro-groove generating element 512 or micro-groove generating element 552, respectively, into the surface of sample precursor 20. For example, the depth (penetration) of micro-groove generating element 512 or 552 into the surface of sample precursor 20 is, preferably, in a range of from about 10 nanometers to about 10,000 nanometers, more preferably, in a range of from about 100 nanometers to about 2,000 nanometers, and most preferably, in a range of from about 300 nanometers to about 1,500 nanometers.

A second critical parameter for characterizing operation of the micro-groove generating unit of sample preparation system 10 of the present invention, being either preferred embodiment, micro-groove generating unit 500 or micro-groove generating unit 500′, relates to the incremental resolution of depth (penetration) of micro-groove generating element 512 or 552 into the surface of sample precursor 20. Herein, the incremental resolution of depth (penetration) of micro-groove generating element 512 or 552 into the surface of sample precursor 20, refers to the smallest incremental step of depth (penetration) that is attainable by the micro-groove depth (penetration) control sub-assembly, that is, micro-groove depth (penetration) control sub-assembly 524, and micro-groove depth (penetration) control sub-assembly 564, respectively. For example, the incremental resolution of depth (penetration) of micro-groove generating element 512 or 552 into the surface of sample precursor 20 is, preferably, in a range of from about 3 nanometers to about 7 nanometers.

A third critical parameter for characterizing operation of the micro-groove generating unit of sample preparation system 10 of the present invention, being either preferred embodiment, micro-groove generating unit 500 or micro-groove generating unit 500′, relates to the quality of each micro-groove generated in the surface of sample precursor 20. Herein, the quality of each micro-groove generated in the surface of sample precursor 20, refers to a set of features which indicate the integrity of the generated micro-groove. Such features are, for example, absence of micro-sized cracks along the walls of the generated micro-groove, topographical uniformity in terms of smoothness, straightness, and consistency, along the walls of the generated micro-groove.

There are several characteristics of the micro-groove generating unit of sample preparation system 10 of the present invention, being either preferred embodiment, micro-groove generating unit 500 or micro-groove generating unit 500′, which lead to achieving the above described primary function of detaching a pre-determined number of layers of sample precursor 20 adjacent to features in a target area or region of interest (ROI) on the surface of sample precursor 20, in order to avoid undesirable generation of artifacts which may be induced during cryogenically sectioning of sample precursor 20.

For each respective preferred embodiment, micro-groove generating unit 500 or micro-groove generating unit 500′, of the micro-groove generating unit of sample preparation system 10 of the present invention, such characteristics are: (1) the type of material of micro-groove generating element 512 or 552, respectively, (2) the configuration, shape, or form, of micro-groove generating element 512 or 552, respectively, (3) the sharpness or radius of the tip of micro-groove generating element 512 or 552, respectively, (4) the angle of approach of micro-groove generating element 512 or 552, respectively, towards the surface of sample precursor 20, and (5) the manner by which the force is applied towards the surface of sample precursor 20, by micro-groove generating element 512 or 552, respectively.

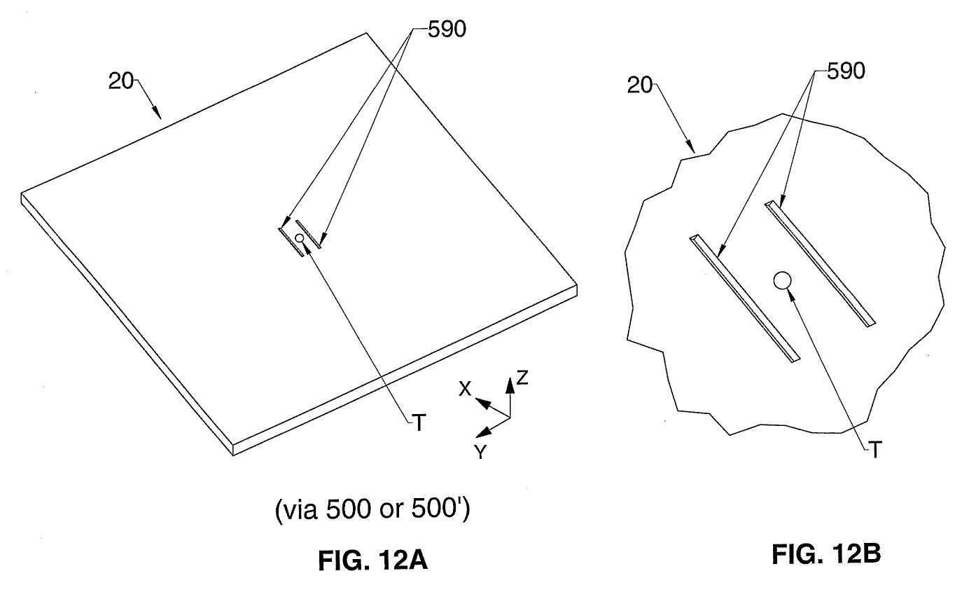

An illustrative example of using micro-groove generating unit 500 or 500′, of sample preparation system 10, of the present invention, is shown in FIGS. 12A-12B, schematic diagrams illustrating perspective views (FIG. 12B being a close-up of FIG. 12A) of Step (e), described hereinbelow, of generating at least one micro-groove, for example, a pair of micro-grooves 590, in a surface of sample precursor 20 having a designated target area or region of interest (ROI) T.

In addition to the main function of micro-groove generating unit 500 or 500′ generating at least one micro-groove in a surface of sample precursor 20, micro-groove generating unit 500 or 500′ can be used for performing (optional) Step (k), of marking a target area or region of interest (ROI) on a surface of sample precursor 20, by a marking device. In a second specific alternative preferred embodiment of the present invention, for performing (optional) Step (k), in sample preparation system 10, the marking device corresponds to the micro-groove generating unit, being either preferred embodiment, micro-groove generating unit 500 or 5001. According to this embodiment, micro-groove generating unit 500 or 500′ is used for marking, for example, via micro-grooves 590, a target area or region of interest (ROI), for example, target area or region of interest (ROI) T, on a surface of sample precursor 20, as schematically illustrated in FIGS. 14A and 14C.

Above illustratively described two alternative preferred embodiments 500 or 5001 of a micro-groove generating unit or device for generating at least one micro-groove in a surface of sample precursor 20, as an exemplary material, correspond to two alternative preferred embodiments of an integrated unit or device of the overall sample preparation system 10, in accordance with another main aspect of the present invention of a system for preparing a sample for micro-analysis. Micro-groove generating unit 500 or 500′ of the present invention is also separable and integratable with other sample preparation systems.

### Cryogenic Sectioning Unit

Cryogenic sectioning unit 600 is for cryogenically sectioning sample precursor 20 to a pre-determined configuration and size, for forming a sectioned sample precursor 20. Cryogenic sectioning unit 600 is performed by using a sequential combination of fine and coarse sectioning procedures, with the specific objective of forming the intended sample subsequently prepared by implementing the present invention.

Reference is again made to FIGS. 1, 2, and 4, where FIG. 4 shows a perspective close-up view of cryogenic sectioning unit 600, in relation to other selected units (sample precursor holding unit 100, transporting and positioning unit 200, optical imaging unit 300, picking and placing unit 400, micro-groove generating unit 500, adhering interface assembly 700, sample precursor micro-size (surface area dimensions) reducing unit 900, scribing and cleaving unit 1000, and micro-mask adhering unit 1100), and components thereof, of sample preparation system 10 illustrated in FIGS. 1 and 2.

FIGS. 6A-6D are schematic diagrams illustrating additional perspective close-up views of the cryogenic sectioning unit 600, and components thereof, as part of sample preparation system 10 illustrated in FIGS. 1 and 2, along with directional movements thereof [(FIGS. 6A-6B): vertical movement, and (FIGS. 6C-6D): horizontal movement, during sectioning of the sample precursor 20].

Cryogenic sectioning unit 600 includes the main components of: (i) a fine sectioning blade 602, (ii) a coarse sectioning blade 604, (iii) a sectioning blade drive shaft 606, (iv) a sectioning blade drive shaft motor 608, and (v) a cryogenic fluid supply and control assembly (610 [FIG. 4]+612 [FIG. 4]+613 [FIG. 4]+614 [FIGS. 4, 6A-6D]).

Fine sectioning blade 602 is for sectioning sample precursor 20 at positions located along sample precursor 20 which are adjacent to target features of sample precursor 20. Main objective for using fine sectioning blade 602 is to achieve a required ‘critical’ thickness (critical width (CW)) dimension having a typical range of from about 3 microns to about 30 microns, with the best quality of side walls adjacent to the target area. The depth of such fine cuts has a value in a range of from about 10 microns to about 300 microns. Preferably, fine sectioning blade 602 is made of a resin or other material impregnated with fine diamond or diamond-like particles.

Coarse sectioning blade 604 is for reducing, via sectioning, sample precursor 20 at positions along sample precursor 20 which are not adjacent to target features. Invariably, coarse sectioning blade 604 is used for sectioning (cutting, slicing) entirely through sample precursor 20 and sample precursor support structure 110 (side view) or 120 (planar view) while sample precursor 20 is mounted upon sample precursor support structure 110 or 120. The width of the sample resulting from such coarse cuts has a value in a range of from about 50 microns to about 300 microns. A typical width of such coarse cuts has a value of about 150 microns.

Sectioning blade drive shaft 606 serves as a shaft for driving both fine sectioning blade 602 and coarse sectioning blade 604. In general, each of fine sectioning blade 602 and coarse sectioning blade 604 can have its own designated sectioning blade drive shaft. Sectioning blade drive shaft motor 608 rotates blade drive shaft 606 for enabling the fine and coarse sectioning procedures. Sectioning blade drive shaft motor 608 rotates, sectioning blade drive shaft 606 at an exemplary rate of about 40,000 rpm.

Cryogenic fluid supply and control assembly (610 [FIG. 4]+612 [FIG. 4]+613 [FIG. 4]+614 [FIGS. 4, 6A-6D]) is for supplying and controlling the use of a cryogenic fluid as a coolant or cooling agent for cooling the sectioning blade, i.e., fine sectioning blade 602 or coarse sectioning blade 604, as well as sample precursor 20, during the cryogenic sectioning process. Moreover, the cryogenic fluid acts as a cleaner or cleaning agent for cleaning the sectioning blade, i.e., fine sectioning blade 602 or coarse sectioning blade 604, as well as sample precursor 20, during the cryogenic sectioning process.

Cryogenic fluid supply and control assembly includes the main components of: (1) a cryogenic fluid, (2) a cryogenic fluid reservoir 610 (FIG. 4), (3) a cryogenic fluid supply valving and distributing sub-assembly 612 (FIG. 4), which includes a pressure control mechanism 613, and (4) a cryogenic fluid outlet nozzle(s) sub-assembly 614 (FIG. 4, 6A-6D).

In general, the cryogenic fluid is any sufficiently low temperature single or dual phase fluid evaporative cooling medium, exhibiting the physicochemical property of having capacity to absorb heat, thereby functioning as a coolant or cooling agent. Preferably, the cryogenic fluid is a dual phase evaporative cooling medium (for example, dual-phase liquid and gaseous nitrogen), for ‘dry’ cooling the saw blade and sample precursor 20 during the sectioning process, for highly accurately sectioning sample precursor 20 to a pre-determined shaped or formed sample.

The cryogenic fluid reservoir 610 is operatively connected to cryogenic fluid supply valving and distributing sub-assembly 612, which includes a pressure control mechanism 613. Pressure control mechanism 613 functions for maintaining the pressure of cryogenic fluid reservoir 610 at a constant value, regardless of changes or variability in the volume of the cryogenic fluid (for example, dual-phase liquid and gaseous nitrogen) present in cryogenic fluid reservoir 610. Operation of pressure control mechanism 613 ensures that the cryogenic fluid is controllably and reproducibility supplied through cryogenic fluid supply valving and distributing sub-assembly 612, and cryogenic fluid outlet nozzle(s) sub-assembly 614, as well as onto the sectioning blade (fine sectioning blade 602 or coarse sectioning blade 604), as well as onto sample precursor 20, during the cryogenic sectioning process.

The presence and operative connection of pressure control mechanism 613 to cryogenic fluid reservoir 610, and use thereof, for improving the controllability and reproducibility of cryogenically sectioning sample precursor 20, represents a significant improvement over the cryogenic sectioning type of micro-analytical sample sectioning procedure which is disclosed in present assignee/applicant PCT Int'l. Pat. Appl. Publ. No. WO 02/054042. Specifically, the cryogenic sawing method disclosed in PCT Int'l. Pat. Appl. Publ. No. WO 02/054042 is absent of a procedure, as well as of a pressure control mechanism, for maintaining the pressure of the cryogenic fluid reservoir at a constant value. Accordingly, by using that cryogenic sawing method there is inherently lack of controllability and reproducibility of cryogenically sectioning a sample precursor.

Cryogenic sectioning unit 600, optionally, further includes a sectioning waste removal assembly 616, in the form of a waste (dust) suctioning conduit. Sectioning waste removal assembly 616 is for removing waste material generated during the sectioning process.

Cryogenic sectioning unit 600, optionally, further includes a measuring pin assembly 618 (FIG. 6A-6B), which is used for measuring a characteristic dimension (typically, the diameter) of a cryogenic sectioning blade (fine sectioning blade 602 or coarse sectioning blade 604), in order to calibrate the sectioning depth of the cryogenic sectioning blade.

Above illustratively described cryogenic sectioning unit 600 for cryogenically sectioning sample precursor 20, as an exemplary material, to a pre-determined configuration and size, for forming a sectioned sample precursor 20, corresponds to an integrated unit or device of the overall sample preparation system 10, in accordance with another main aspect of the present invention of a system for preparing a sample for micro-analysis. Cryogenic sectioning unit 600 of the present invention is also separable and integratable with other sample preparation systems.

As previously stated hereinabove, with reference again to FIGS. 1 and 2, sample preparation system 10, optionally, further includes at least one additional main component selected from the group consisting of: (g) an adhering interface assembly 700, (h) a pneumatics control unit 800, (i) a sample precursor micro-size (surface area dimensions) reducing unit 900, (j) a scribing and cleaving unit 1000, (k) a micro-mask adhering unit 1100, and (l) an anti-vibration unit 1200. Preferably, electronics and process control utilities 1300 is also operatively connected to each optional at least one additional main component 700, or/and 800, or/and 900, or/and 1000, or/and 1100, or/and 1200, for providing electronics to, and enabling process control of, each respective optional at least one additional main component 700, or/and 800, or/and 900, or/and 1000, or/and 1100, or/and 1200, in a manner operatively integrated with the hereinabove illustratively described sample preparation system main components 100, 200, 300, 400, 500, and 600.

### (Optional) Aditerin Interface Assembly

(Optional) adhering interface assembly 700, when included in sample preparation system 10, is for enabling interfacing of transporting and positioning unit 200 with picking and placing unit 400. Such interfacing is needed for adhering a first component to a second component within sample preparation system 10.

Reference is again made to FIGS. 1, 2, and 4, where FIG. 4 shows a perspective close-up view of adhering interface assembly 700, in relation to other selected units (sample precursor holding unit 100, transporting and positioning unit 200, optical imaging unit 300, picking and placing unit 400, micro-groove generating unit 500, cryogenic sectioning unit 600, sample precursor micro-size (surface area dimensions) reducing unit 900, scribing and cleaving unit 1000, and micro-mask adhering unit 1100), and components thereof, of sample preparation system 10 illustrated in FIGS. 1 and 2.

FIGS. 7A-7B are schematic diagrams illustrating additional perspective close-up views of the adhering interface assembly 700, and components thereof, as part of sample preparation system 10 illustrated in FIGS. 1 and 2, in relation to the sample precursor holding unit 100, the transporting and positioning unit 200, and the picking and placing unit 400, with (FIGS. 7A and 7B) depicting final stages of adhering the sample precursor 20 to an exemplary side view type of sample precursor support structure 110. Adhering interface assembly 700, and selected components thereof, are also illustrated in FIGS. 11A-11B.

Consequent to picking and placing unit 400 picking and placing a component, for example, sample precursor 20, a masking element, or/and a processed (cut and mounted) form of sample precursor 20, of sample preparation system 10, from an initial position to another functionally dependent position, adhering interface assembly 700 enables the adhering of that picked and placed (first) component to a second component within sample preparation system 10.

More specifically, for example, adhering interface assembly 700 enables the adhering of sample precursor 20 to, for example, sample precursor support structure 110 (side view) or 120 (planar view)), of sample precursor holding unit 100 (FIG. 3).

More specifically, for example, adhering interface assembly 700 enables the adhering of a macro-size masking element 30, to a surface of, for example, sample precursor 20, or a processed (cut and mounted) form of sample precursor 20.

Adhering interface assembly 700 includes the main components of: (i) an adhesive applying sub-assembly 702, and (ii) an adhesive receptacle 704.

Adhesive applying sub-assembly 702 includes: (1) an adhesive applying needle 706, and (2) an adhesive applying needle holder 708. Adhesive receptacle 704 is for containing an adhesive material which ultimately will be applied by adhesive applying needle 706 to any number of various different components of sample preparation system 10. An exemplary adhesive material is, preferably, an epoxy or epoxy-like material. For the adhesive material being an epoxy or epoxy-like material, then, preferably, adhesive receptacle 704 includes two separate receptacles for containing the two components of the epoxy or epoxy-like material.

### (Optional) Pneumatics Control Unit

(Optional) pneumatics control unit 800, when included in sample preparation system 10, is for controlling pneumatics of selected sample preparation system units.

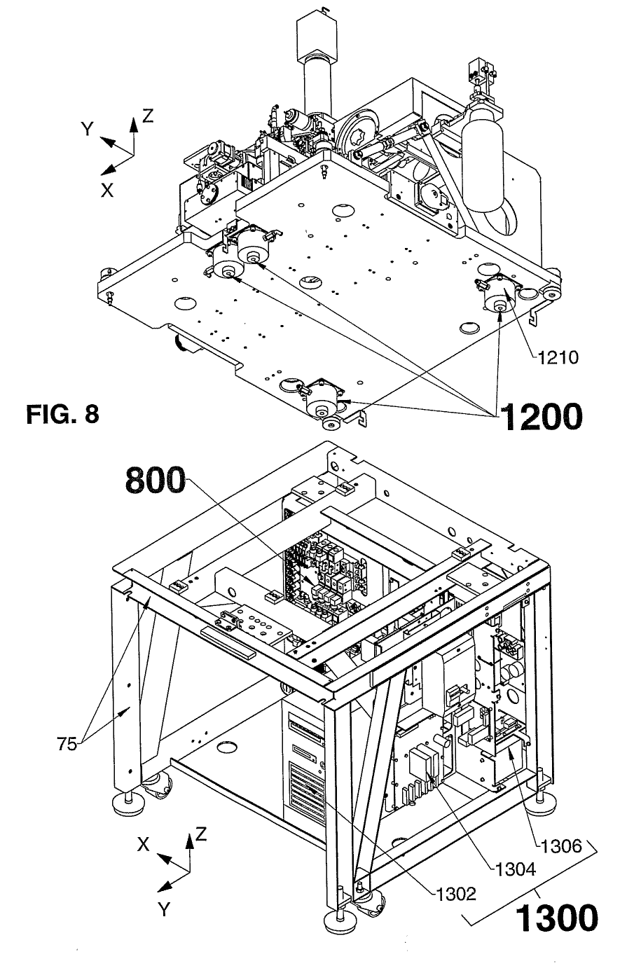

Reference is now made to FIG. 8, which is a schematic diagram illustrating an additional perspective close-up view of pneumatics control unit 800, anti-vibration unit 1200, and electronics and process control utilities 1300, and components thereof, as part of sample preparation system 10 illustrated in FIGS. 1 and 2.

Pneumatics control unit 800 controls the pneumatics of the following selected main components of sample preparation system 10: sample precursor holding unit 100, transporting and positioning unit 200, picking and placing unit 400, and cryogenic sectioning unit 600.

In alternative preferred embodiments of sample preparation system 10, wherein sample preparation system 10 optionally, further includes at least one additional main component selected from the group consisting of: adhering interface assembly 700, sample precursor micro-size (surface area dimensions) reducing unit 900, scribing and cleaving unit 1000, and anti-vibration unit 1200, then, pneumatics control unit 800 controls the pneumatics of such optional, additional main components.

Pneumatics control unit 800 includes the main components of solenoids, valves, distributors, wiring, a vacuum recognition assembly, and a centralized pneumatic control board. Pneumatics control unit 300 is electronically controlled via electronics and process control utilities 1300.

### (Optional) Sample Precursor Size Reducing Unit

(Optional) sample precursor size reducing unit 900, when included in sample preparation system 10, is for reducing the size (surface area dimensions) of sample precursor 20 to a pre-determined sample precursor size.

Reference is again made to FIGS. 1, 2, and 4, where FIG. 4 shows a perspective close-up view of sample precursor size (surface area dimensions) reducing unit 900, in relation to other selected units (sample precursor holding unit 100, transporting and positioning unit 200, optical imaging unit 300, picking and placing unit 400, micro-groove generating unit 500, cryogenic sectioning unit 600, adhering interface assembly 700, scribing and cleaving unit 1000, and micro-mask adhering unit 1100), and components thereof, of sample preparation system 10 illustrated in FIGS. 1 and 2.

The decision to use sample precursor size reducing unit 900 is based on the comparison whereby the sample precursor initial size is larger than the sample optimum size, such that the initially provided sample precursor is not used ‘as is’, but is first processed, via at least one size (surface area dimensions) reducing procedure, for forming the sample precursor having a pre-determined size. Such a predetermined size is defined by the particular type of the initial sample precursor used and of the sectioned sample subsequently prepared, and as relating to the particular preparatory requirements of the micro-analytical technique which is ultimately used for analyzing a given sample.

Sample precursor size reducing unit 900 includes the main components of: (i) a sectioning blade 902, and (ii) a sectioning blade drive shaft and motor assembly 904. Sample precursor size reducing unit 900, optionally, further includes a cryogenic fluid supply and control assembly, for example, similar to, or the same as, cryogenic fluid supply and control assembly (610 [FIG. 4]+612 [FIG. 4]+613 [FIG. 4]+614 [FIGS. 4, 6A-6D]) included in cryogenic sectioning unit 600.

Sample precursor size reducing unit 900 is designed, constructed, and operated, for having components typically rotating at about 10,000 rpm, and does not require relatively high levels of stability and precision which are required for proper operation of cryogenic sectioning unit 600.

### (Optional) Scribing and Cleaving Unit

(Optional) scribing and cleaving unit 1000, when included in sample preparation system 10, is for generating a scribe line on a surface of sample precursor 20, and cleaving sample precursor 20 along the scribe line.

Reference is again made to FIGS. 1, 2, and 4, where FIG. 4 shows a perspective close-up view of scribing and cleaving unit 1000, in relation to other selected units (sample precursor holding unit 100, transporting and positioning unit 200, optical imaging unit 300, picking and placing unit 400, micro-groove generating unit 500, cryogenic sectioning unit 600, adhering interface assembly 700, and sample precursor micro-size (surface area dimensions) reducing unit 900, and micro-mask adhering unit 1100), and components thereof, of sample preparation system 10 illustrated in FIGS. 1 and 2.

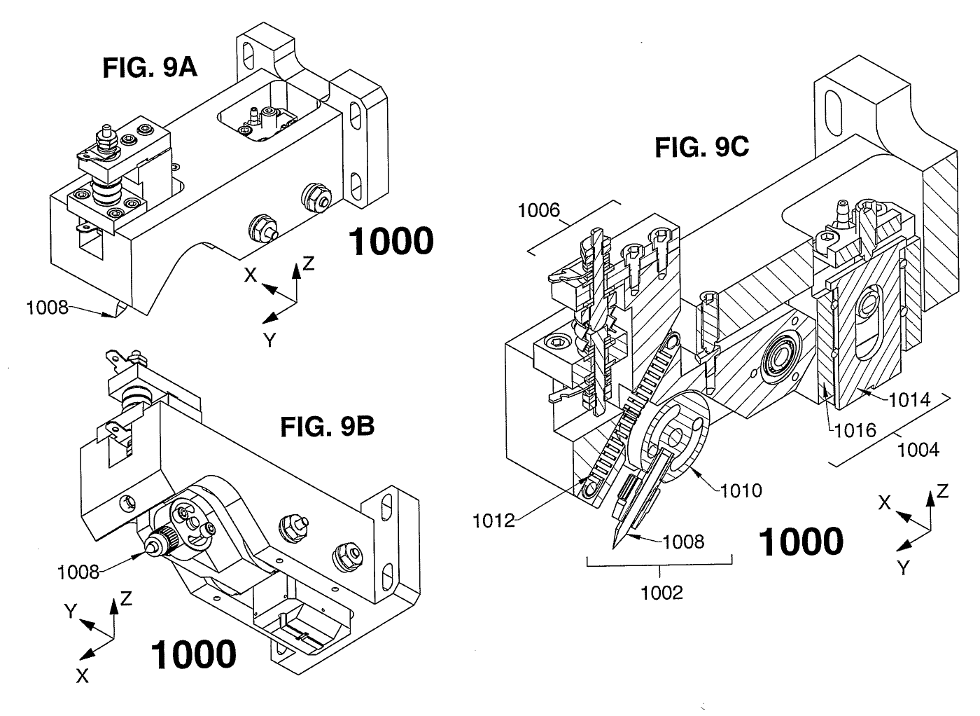

FIGS. 9A-9B are schematic diagrams illustrating additional perspective close-up views of the scribing and cleaving unit 1000, and components thereof, as part of sample preparation system 10 illustrated in FIGS. 1 and 2. FIG. 9C is a schematic diagram illustrating a perspective close-up section view of the scribing and cleaving unit 1000 illustrated in FIG. 9A.

Scribing and cleaving unit 1000 includes the main components of: (i) a scribing assembly 1002, (ii) a cleaving assembly 1004, and (iii) a surface contact sensing mechanism 1006.

Scribing assembly 1002 includes the main components of: (1) a scribing element 1008, (2) a scribing element holder 1010, and (3) a scribing element force and orientation controlling mechanism 1012. Scribing element 1008, has a sharp tip, for effectively forming a sufficiently sharply indented scribe line along a surface of sample precursor 20, which facilitates the subsequent cleaving also performed by scribing and cleaving unit 1000. Scribing element force and orientation controlling mechanism 1012 is, for example, spring loaded. Preferably, scribing assembly 1002 is mounted onto a base element by means of a fixed axle, thus enabling rotation of scribing assembly 1002 relative to the scribed surface of sample precursor 20.

Cleaving assembly 1004 includes the main components of: (1) a cleaving plunger 1014, and (2) a cleaving plunger housing and guide sub-assembly 1016. Cleaving plunger 1014 is electronically activated and controlled via electronics and process control unit 1300. Preferably, cleaving assembly 1004 is mounted onto a base element by means of a fixed axle, thus enabling rotation and self-alignment of cleaving assembly 1004 relative to the cleaved surface of sample precursor 20.

Surface contact sensing mechanism 1006 is for sensing a condition of contact between a surface of sample precursor 20 and scribing element 1008 of scribing assembly 1002.

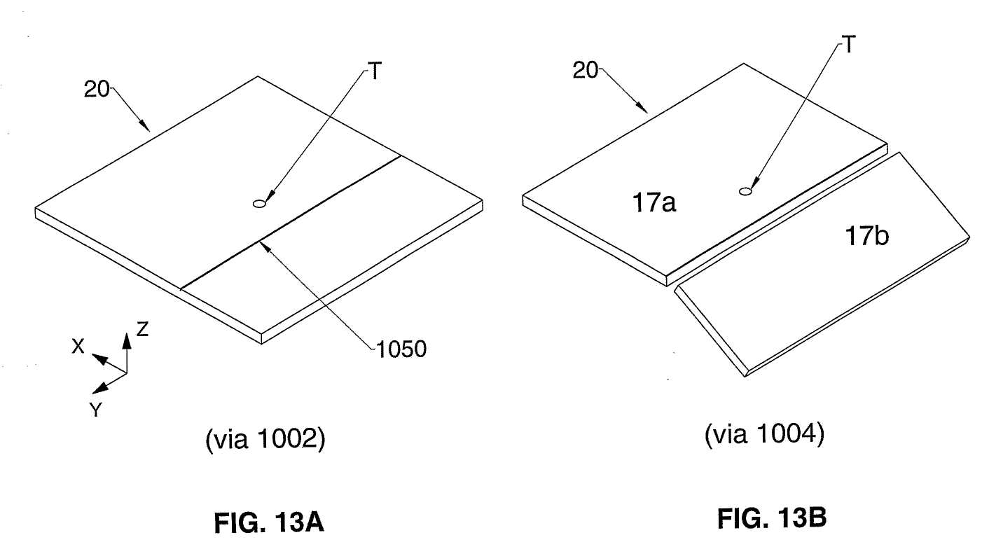

An illustrative example of using scribing and cleaving unit 1000 of sample preparation system 10, of the present invention, is shown in FIGS. 13A-13B, schematic diagrams illustrating perspective close-up views of (optional) Step (j), generating a scribe line, for example, scribe line 1050, on a surface of sample precursor 20 having a designated target area or region of interest (ROI) T, by scribing assembly 1002, (FIG. 13A), and cleaving sample precursor 20 along scribe line 1050, by cleaving assembly 1004, (FIG. 13B). As shown in FIG. 13B, subsequent to cleaving sample precursor 20 along scribe line 1050 by cleaving assembly 1004, the first portion 17a of cleaved sample precursor 20 includes target area or region of interest (ROI) T, and the second portion 17b is without target area or region of interest (ROI) T.

In addition to the main function of scribing assembly 1002 of scribing and cleaving unit 1000 generating a scribe line on a surface of sample precursor 20, scribing assembly 1002 can be used for performing (optional) Step (k), of marking a target area or region of interest (ROI) on a surface of sample precursor 20, by a marking device. In a third specific alternative preferred embodiment of the present invention, for performing (optional) Step (k), in sample preparation system 10, the marking device corresponds to scribing assembly 1002 of scribing and cleaving unit 1000. According to this embodiment, as schematically illustrated in FIGS. 14A and 14D, scribing assembly 1002 is used for marking, for example, via scribe lines 1090, a target area or region of interest (ROI), for example, target area or region of interest (ROI) T, on a surface of sample precursor 20,

### (Optional) Micro-Mask Adhering Unit

(Optional) micro-mask adhering unit 1100, when included in sample preparation system 10, is for adhering a micro-mask onto a surface of sample precursor 20.

Reference is again made to FIGS. 1, 2, and 4, where FIG. 4 shows a perspective close-up view of micro-mask adhering unit 1100, in relation to other selected units (sample precursor holding unit 100, transporting and positioning unit 200, optical imaging unit 300, picking and placing unit 400, micro-groove generating unit 500, cryogenic sectioning unit 600, adhering interface assembly 700, and sample precursor micro-size (surface area dimensions) reducing unit 900, and scribing and cleaving unit 1000) and components thereof, of sample preparation system 10 illustrated in FIGS. 1 and 2.

FIGS. 10A-10B are schematic diagrams illustrating perspective close-up views of the micro-mask adhering unit 1100, and components thereof, as part of sample preparation system 10 illustrated in FIGS. 1 and 2. FIG. 10C is a schematic diagram illustrating a perspective close-up section view of the micro-mask adhering unit 1100 illustrated in FIG. 10A.

Micro-mask adhering unit 1100 includes the main components of: (i) a micro-size masking element 1110, (ii) a micro-size masking element holder assembly 1120, (iii) an electrical contact assembly 1130, (iv) a housing assembly 1140, (v) a y-axis displacement sub-assembly 1150, (v) a z-axis displacement sub-assembly 1160, and (vi) a light beam interruption sensor assembly 1170.

Micro-size masking element 1110 is composed of an electrically and thermally conductive material, having a variable geometrical configuration, shape or form. Micro-size masking element 1110 is for enabling the sample prepared according to the present invention to be subjected to ion beam milling types of micro-analytical sample final preparation techniques, in general, and broad ion beam milling types of micro-analytical sample final preparation techniques, in particular. Accordingly, micro-size masking element 1110 is of such material and geometrical configuration, shape or form, such that preferably, the ion milling (material removal) rate of micro-size masking element 1110 is compatible with the ion milling rate of a sample on which micro-size masking element 1110 is placed, during a final thinning process performed in a subsequent sample final preparation procedure.

Exemplary materials which compose micro-size masking element 1110 are carbon materials, ceramic materials, metallic (pure metal or metal alloy) materials, and combination materials thereof. Exemplary geometrical configuration, shape or form, of such a material is cylindrical, rectangular, and trapezoidal. Exemplary diameter of a cylindrical configured material is in a range of from about 6 microns to about 25 microns. Exemplary section or profile of a rectangular configured material is in a range of from about 6 microns to about 25 microns.

Micro-size masking element holder assembly 1120 is for holding micro-size masking element 1110, as well for containing electrically conductive wires which transfer electrical current to micro-size masking element 1110.

Electrical contact assembly 1130 (FIG. 10C) is for transferring electrical current, for example, via electrical conductors, such as electrically conductive wires, to micro-size masking element holder assembly 1120.

Housing assembly 1140 is for housing micro-size masking element holder assembly 1120 and electrical contact assembly 1130. Housing assembly 1140 has a self-aligning capability by being rotatable around the y-axis in relation to y-axis displacement sub-assembly 1150.

Y-axis displacement sub-assembly 1150 includes a spring loaded piston 1152, and enables displacement of micro-size masking element holder assembly 1120 from an initial position to an active position along the y-axis.

Z-axis displacement sub-assembly 1160 includes a motorized drive shaft 1164, and enables displacement of micro-size masking element holder assembly 1120 from an initial position to an active position along the z-axis.

Light beam interruption sensor assembly 1170 (FIG. 10A) is for sensing certain positions of micro-size masking element holder assembly 1120. Exemplary types of light beam interruption sensor assembly 1170 are an LED (light emitting diode), or a paired LED and light detector assembly.

There are two main particular embodiments of the present invention wherein micro-mask adhering unit 1100 is used, in accordance with (optional) Step (m), illustratively described hereinbelow, for adhering a micro-mask onto a surface of sample precursor 20. In a first particular embodiment, (optional) Step (m) is performed by using micro-mask adhering unit 1100 for adhering a micro-mask onto a surface of a previously cryogenically sectioned sample precursor 20, at a pre-determined position and with a positioning accuracy in a range of between about 50 nanometers and about 150 nanometers, typically, being about 100 nanometers, having been cryogenically sectioned according to Step (f), previously illustratively described hereinabove. Alternatively, in a second particular embodiment, (optional) Step (m) is performed by using micro-mask adhering unit 1100 for adhering a micro-mask onto a surface of sample precursor 20, at a pre-determined position and with a positioning accuracy in a range of between about 50 nanometers and about 150 nanometers, typically, being about 100 nanometers, wherein sample precursor 20 has not been subjected to a cryogenic sectioning procedure.

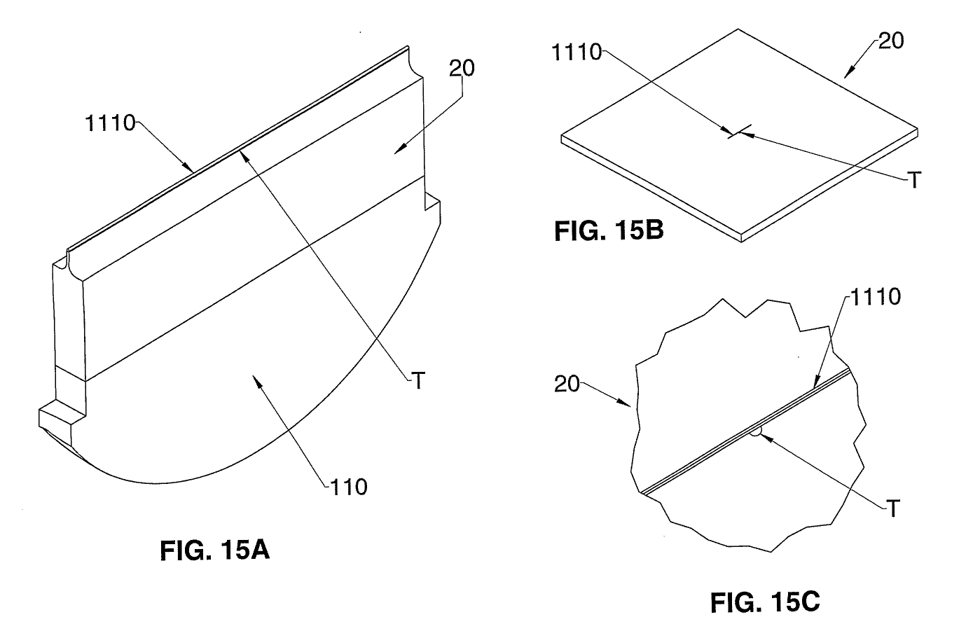

The above two main particular embodiments of using micro-mask adhering unit 1100 of sample preparation system 10, of the present invention, are illustratively exemplified in FIG. 15A (first main particular embodiment), and in FIGS. 15B-15C (second main particular embodiment). FIGS. 15A, and 15B-15C, are schematic diagrams illustrating perspective close-up views of the two main particular embodiments, respectively, of performing (optional) Step (m), for adhering a micro-mask, for example, micro-masking element 1110 (having a cylindrical shaped micron-sized wire (FIG. 15A), or a rectangular shaped profile (FIGS. 15B-15C)), onto a surface of sample precursor 20. The first particular embodiment of using micro-mask adhering unit 1100 is illustrated in FIG. 15A, wherein sample precursor 20 has been previously cryogenically sectioned according to the cryogenic sectioning procedure of Step (f). In FIG. 15A, cryogenically sectioned sample precursor 20 is shown adhered to a side view type of sample precursor support structure 110. The second particular embodiment of using micro-mask adhering unit 1100 is illustrated in FIGS. 15B-15C, wherein sample precursor 20 has not been subjected to a cryogenic sectioning procedure. In FIGS. 15B and 15C, sample precursor 20 is shown including a target area or region of interest (ROI) T.

Above illustratively described micro-mask adhering unit 1100 for adhering a micro-mask onto a surface of sample precursor 20, as an exemplary material, corresponds to an integrated unit or device of the overall sample preparation system 10, in accordance with another main aspect of the present invention of a system for preparing a sample for micro-analysis. Micro-mask adhering unit 1100 of the present invention is also separable and integratable with other sample preparation systems.

### (Optional) Anti-Vibration Unit

(Optional) anti-vibration unit 1200, when included in sample preparation system 10, is for preventing or minimizing occurrence of vibrations during operation of sample preparation system 10.

Reference is now made to FIG. 8 (upper part), which shows a perspective close-up view of the anti-vibration unit 1200, and components thereof, as part of sample preparation system 10 illustrated in FIGS. 1 and 2.

Anti-vibration unit 1200, and components thereof, are directly mounted onto, and operatively connected to, system support assembly 75 (FIGS. 2 and 8). Anti-vibration unit 1200 includes the main components of a plurality of electro-pneumatic or/and electro-mechanical active damping assemblies, for example, four electro-pneumatic active damping assemblies, each generally indicated by 1210 in FIG. 8. Anti-vibration unit 1200 is operatively connected to electronics and process control utilities 1300 which provides electronics to, and enables process control of anti-vibration unit 1200.

Electronics and Process Control utilities

Electronics and process control utilities 1300 is for providing electronics to, and enabling process control of, main components of sample preparation system 10.

Electronics and process control utilities 1300 is operatively (structurally or/and functionally) connected to each sample preparation system main component: sample precursor holding unit 100, transporting and positioning unit 200, optical imaging unit 300, picking and placing unit 400, micro-groove generating unit 500, and cryogenic sectioning unit 600, for providing electronics to, and enabling process control of, each respective main component 100, 200, 300, 400, 500, and 600, of sample preparation system 10. As shown in FIG. 1, operative (structural or/and functional) connection of electronics and process control utilities 1300 to each sample preparation system main component—sample precursor holding unit 100, transporting and positioning unit 200, optical imaging unit 300, picking and placing unit 400, micro-groove generating unit 500, and cryogenic sectioning unit 600, is indicated by the larger (centrally located) ellipse intersecting operative connection lines extending from each sample preparation system main component to sample precursor holding unit 100.

When sample preparation system 10 includes at least one of the hereinabove illustratively described (optional) additional main components 700, or/and 800, or/and 900, or/and 1000, or/and 1100, or/and 1200, then, electronics and process control utilities 1300 is also operatively (structurally or/and functionally) connected to each respective additionally included sample preparation system main component, for providing electronics to, and enabling process control of, each respective additionally included main component, in a manner operatively (structurally or/and functionally) integrated with previously stated sample preparation system main components 100, 200, 300, 400, 500, and 600. As shown in FIG. 1, operative (structural or/and functional) connection of electronics and process control utilities 1300 to each optional at least one additional sample preparation system main component—adhering interface assembly 700, pneumatics control unit 800, sample precursor micro-size (surface area dimensions) reducing unit 900, scribing and cleaving unit 1000, micro-mask adhering unit 1100, and anti-vibration unit 1200, is indicated by the larger (centrally located) ellipse intersecting operative connection lines extending from each optional at least one additional sample preparation system main component to sample precursor holding unit 100.

In general, electronics and process control utilities 1300 includes any number and type or kind of the following main components: a central control panel or board, at least one computer, microprocessor, or central processing unit (CPU), along with associated computer software, power supplies, power converters, controllers, controller boards, various printed circuit boards (PCBs), for example, including input/output (I/O) and D/A (digital to analog) and A/D (analog to digital) functionalities, cables, wires, connectors, shieldings, groundings, various electronic interfaces, and network connectors. For example, with reference again made to FIG. 8 (lower part), electronics and process control utilities 1300 includes the main components of: (i) a computerized control unit 1302, (ii) an electronics board 1304, and (iii) a power supply module 1306. Computerized control unit 1302 includes, for example, a computer, such as a PC computer, operative with a plurality of electronic boards, such as motion control and signal interface types of electronic boards. Computerized control unit 1302 also includes the frame grabber, being of software or/and hardware, of optical imaging unit 300 (FIG. 1, 2, 3).

In a non-limiting manner, as shown in FIG. 2, several units or components thereof, of sample preparation system 10, are directly mounted onto, and operatively connected to, a fixed or mobile (movable) table, stand, or frame, type of system support assembly 75. System support assembly 75 includes appropriately constructed support elements, legs, brackets, and mobile (movable) elements, such as wheels. Other units or components thereof, of sample preparation system 10 are mounted onto those system units or components thereof which are directly mounted onto system support assembly 75.

### Overall Sample Preparation Method

According to another main aspect of the present invention, there is provision of a method of preparing a sample for micro-analysis.

The corresponding method of preparing a sample for micro-analysis, utilizing sample preparation system 10 as illustratively described above in FIGS. 1-15, according to the present, is illustratively described herein as follows. It is to be fully understood that, for the purpose of generally describing the method of preparing a sample for micro-analysis of the present invention, herein, a system process refers to at least part of an individual step, a combination of two or more parts of individual steps, an entire individual step, or a combination of two or more entire individual steps, of the method of the present invention.

As previously stated hereinabove, it is to be understood that the present invention is not limited in its application to the details of type, composition, construction, arrangement, order, and number, of the system units, system sub-units, devices, assemblies, sub-assemblies, mechanisms, structures, components, elements, and configurations, and, peripheral equipment, utilities, accessories, and materials, of the system, or to the details of the order or sequence, number, of procedures, steps, and sub-steps, of operation of the system, or of the method, set forth in the following illustrative description, and accompanying drawings, and examples, unless otherwise specifically stated herein.

With reference again made to FIGS. 1-15, the method of preparing a sample for micro-analysis, of the present invention, includes the following, main steps, and main components thereof: (a) loading a sample precursor 20 onto a sample precursor holding unit 100; (b) transporting and positioning at least a part of sample precursor holding unit 100, by a transporting and positioning unit 200; (c) optically imaging, recognizing, and identifying, target features located on sample precursor 20, and monitoring steps of the sample preparation, by an optical imaging unit 300; (d) picking and placing sample precursor 20 and selected components of the sample preparation system from initial positions to other functionally dependent positions, by a picking and placing unit 400; (e) generating at least one micro-groove in a surface of sample precursor 20, by a micro-groove generating unit 500, wherein depth and quality of each micro-groove in the surface of sample precursor 20 are controlled by components of micro-groove generating unit 500; and (i) cryogenically sectioning sample precursor 20 to a pre-determined configuration and size, for forming a prepared sample, by a cryogenic sectioning unit 600.

The method of preparing a sample for micro-analysis further includes the step of providing electronics to, and enabling process control of, each main component of each above stated main step (a)-step (f), by an electronics and process control utilities 1300 which is operatively connected to each above stated main component.

### Loading a Sample Precursor

In Step (a) of the method of preparing a sample for micro-analysis, of the present invention, there is loading a sample precursor 20 onto a sample precursor holding unit 100.

Reference is again made to FIGS. 1, 2, and 3, along with the illustrative description, hereinabove, of sample precursor holding unit 100, and components thereof, of sample preparation system 10. Additional reference is made to FIGS. 7A-7B, schematic diagrams illustrating additional perspective close-up views of adhering interface assembly 700, and components thereof, as part of sample preparation system 10 illustrated in FIGS. 1 and 2, in relation to sample precursor holding unit 100, transporting and positioning unit 200, and picking and placing unit 400, with (FIG. 7A) and (FIG. 7B) depicting final stages of adhering sample precursor 20 to an exemplary side view type of sample precursor support structure 110. Additional reference is made to FIGS. 11A-11B, schematic diagrams illustrating a perspective close-up view of a planar view sample preparation process involving performance of Step (d), using picking and placing unit 400, for picking and placing a material (for example, a processed (cut and mounted) form of sample precursor 20 adhered to a portion of sample precursor support structure 120), from an initial position to another functionally dependent position.

Sample precursor 20 is fully described, characterized, and exemplified, hereinabove, in the section illustratively describing the sample preparation system of the present invention. As stated therein, based on a comparison of the sample precursor initial size to the sample optimum size, the initially provided sample precursor 20 is used ‘as is’, for continuing the sample preparation method, or is first pre-processed, via at least one size (surface area dimensions) reducing procedure, for forming the sample precursor 20 having a predetermined size which is then used for continuing the sample preparation method, all in accordance with the present invention.

In a non-limiting manner, the following three exemplary cases are applicable for deciding whether or not sample precursor 20 is used ‘as is’, for continuing the sample preparation method, or is first pre-processed, via at least one size (surface area dimensions) reducing procedure:

Case 1: If the value of each surface area dimension, length and width, of the initially provided sample precursor 20 is in a first pre-determined range, for example, of less than a first pre-determined value (for example, about 3 mm), and larger than a second pre-determined value (for example, about 1 mm), then the initially provided sample precursor 20 is subjected to direct continuation of the method.

Case 2: If the value of one or both surface area dimensions, length or/and width, of the initially provided sample precursor 20 is/are in a second pre-determined range, for example, of less than a third pre-determined value (for example, about 18 mm), and larger than the first pre-determined value (for example, about 3 mm), then the initially provided sample precursor 20 is subjected to a sample precursor size (surface area dimensions) reducing procedure, using the (preferably, automatic) sample precursor size (surface area dimensions) reducing unit 900, for reducing the value of the corresponding one or both surface area dimensions to be within the first pre-determined range (of case (1)), for forming the sample precursor 20 having a pre-determined size. Then the sample precursor 20 is subjected to continuation of the method.

Case 3: If the value of one or both surface area dimensions, length or/and width, of the initially provided sample precursor 20 is/are equal to or larger than the third pre-determined value (of case (2)) (for example, about 18 mm), then the initially provided sample precursor 20 is first subjected to a macro-size optical inspection and marking, and is then subjected to a (manual) macro-size (surface area dimensions) reducing procedure, using optional sample precursor macro-size holding chuck 150 of sample precursor holding unit 100. Then, either Case 1 or Case 2 is performed.

Following sample precursor 20 being of an appropriate size, preferably, sample precursor 20 is manually mounted onto chuck base assembly 140, as shown in FIG. 3, via pneumatics control unit 800 (FIGS. 2 and 9A).

Step (a) includes loading of consumables or/and disposables, for example, sample precursor support structure 110 (side view) or 120 (planar view), or alternatively, the set of sample precursor support structures 125a and 125b, adhesive receptacle 704 and adhesive applying needle 706 of adhering interface assembly 700 (FIGS. 7A and 7B). Accordingly, optionally, for an embodiment of the present invention including application of a micro-mask onto the sample prepared from precursor 20, in accordance with (optional) Step (m), described hereinbelow, then Step (a) additionally includes loading a micro-size masking element, for example, micro-size masking element 1110 of micro-mask adhering unit 1100 (FIGS. 10A, 10B, 10C).

Step (a) further includes recognizing the presence of sample precursor 20 mounted on chuck base assembly 140, and recognizing the presence of the loaded consumables, by a vacuum recognition assembly as part of pneumatics control unit 800.

With reference to FIGS. 2 and 3, for the embodiment of sample precursor holding unit 100 which includes sample precursor support structure 110 (side view) or 120 (planar view), Step (a) further includes (preferably, manual) mounting of sample precursor support structure 110 (side view) or 120 (planar view), onto sample precursor support structure holder 130, by means of interface assembly [137a and 137b associated with sample precursor support structure 110 (side view), or, 137c and 137d associated with sample precursor support structure 120 (planar view)]. Alternatively, for the embodiment of sample precursor holding unit 100 which includes the set of sample precursor support structures 125a and 125b, Step (a) further includes (preferably, manual) mounting of sample precursor support structures 125a and 125b onto sample precursor support structure holder 130.

Then, sample precursor support structure 110 (side view) or 120 (planar view), or alternatively, the set of sample precursor support structures 125a and 125b, is engaged and clamped via holding or fixing mechanism 134 which includes a clamping mechanism 138. Then, there is sliding and mounting of sample precursor support structure holder 130 into recessed mounting region 142 of chuck base assembly 140, followed by recognizing the presence of the mounted sample precursor support structure holder 130 by the vacuum recognition assembly as part of pneumatics control unit 800.

For a sufficiently large initial size of sample precursor 20, for example, for sample precursor 20 being a wafer segment (for example, about 40 mm×40 mm) or a whole wafer (for example, a circular shape of about 300 mm diameter), then, Step (a), optionally, includes manual mounting of sample precursor 20 onto sample precursor macro-size holding chuck 150, via guides 152 configured beneath sample precursor macro-size holding chuck 150, as shown in FIG. 3, via pneumatics control unit 800 (FIGS. 2 and 9A). Presence of sample precursor 20 mounted onto sample precursor macro-size holding chuck 150 is recognized by the vacuum recognition assembly as part of pneumatics control unit 800.

Step (a), as illustratively described hereinabove, being performed on sample precursor 20, are alternatively or additionally, similarly performed on a masking element, for the objective of protecting at least a portion of sample precursor 20 during another sample preparation procedure. Such a masking element may be in the form of a ‘macro-size’ masking element 30 (particularly shown, for example, in FIG. 3), for example, operatively associated with, or part of, picking and placing unit 400 (FIGS. 1, 2, 4, 7A, 7B, 11A, and 11B), or alternatively, may be in the form of a ‘micro-size’ masking element 1110 (particularly shown, for example, in FIGS. 10A, 10B, and 10C), for example, associated with, or part of, micro-mask adhering unit 1100 (FIGS. 1, 2, 4, 10A, 10B, and 10C).

### Transporting and Positioning Sample Precursor

In Step (b), there is transporting and positioning at least a part of sample precursor holding unit 100, by a transporting and positioning unit 200.

Reference is again made to FIGS. 1, 2, and 4, along with the illustrative description, hereinabove, of transporting and positioning unit 200, and components thereof, of sample preparation system 10. Additional reference is made to FIGS. 7A-7B, and to FIGS. 11A-11B.

Step (b) includes activating and moving selected components of transporting and positioning unit 200 to an initial position at the start of each system process, where system process is defined above. Transporting and positioning unit 200 is then activated for being in a position suitable for loading/unloading sample precursor 20 and system consumables. As previously stated above, consumables are, for example, sample precursor support structure 110 (side view) or 120 (planar view), adhesive receptacle 704 and adhesive applying needle 706 of adhering interface assembly 700. Optionally, for an embodiment of the present invention including application of a mask onto the sample prepared from precursor 20, in accordance with (optional) Step (l), described hereinbelow, then another system consumable transported and positioned by transporting and positioning unit 200 is a micro-size masking element, for example, micro-size masking element 1110 of micro-mask adhering unit 1100 (FIGS. 10A, 10B, 10C).

Step (b) additionally includes transporting and positioning, and aligning, sample precursor 20, for the objective of enabling optical imaging unit 300 to optically image, recognize, and identify, target features located on sample precursor 20, and for monitoring steps, procedures, and system processes, of the overall sample preparation method.

Step (b) additionally includes transporting and positioning unit 200 transporting and positioning sample precursor holding unit 100 prior to mounting, and following mounting, of sample precursor 20, among relevant system units.

In Step (b), transporting and positioning unit 200 is additionally employed for performing any of a variety of different required process steps, for example, reciprocating x-motion during cryogenically sectioning sample precursor 20 to a pre-determined configuration and size, by cryogenic sectioning unit 600.

### Optically Imaging

In Step (c), there is optically imaging, recognizing, and identifying, target features located on sample precursor 20, and monitoring steps of the sample preparation, by an optical imaging unit 300.

Reference is again made to FIGS. 1, 2, and 4, along with the illustrative description, hereinabove, of optical imaging unit 300, and components thereof, of sample preparation system 10.

Step (c) includes the following main sub-steps:

(i) Activating and operating optical imaging unit 300 by executing a focusing algorithm, for achieving the best focus during performance of the various system processes.

(ii) Activating and operating optical imaging unit 300 by executing a material (sample precursor 20) edge recognition algorithm, for achieving the best edge recognition and alignment of sample precursor 20, during performance of the various system processes.

(iii) Selecting a pre-determined magnification of optical imaging unit 300, as a function of the particular system process.

(iv) Operating optical imaging unit 300 by executing a distance (dimension) measuring algorithm, for calculating distances (dimensions) based on operator or/and machine input.

(v) Optical monitoring of system process steps, and outputting the monitored information and data.

(vi) Acquiring and retaining image information and data.

Each of the focusing algorithm, the material (sample precursor 20) edge recognition algorithm, and the distance (dimension) measuring algorithm, are customized versions which are based on readily available software algorithms in the field of image acquisition and processing. All images acquired during each of above stated main sub-steps are digitized by means of the frame grabber which is included as software or/and hardware as part of computerized control unit 1302, included in electronics and process control utilities 1300 (FIGS. 1, 2, 8).

### Picking and Placing Sample Precursor and System Components

In Step (d), there is picking and placing sample precursor 20 and selected components of system 10 from initial positions to other functionally dependent positions, by a picking and placing unit 400.

Reference is again made to FIGS. 1, 2, and 4, along with the illustrative description, hereinabove, of picking and placing unit 400, and components thereof, of sample preparation system 10. Additional reference is made to FIGS. 7A-7B, and to FIGS. 11A-11B.

For a particular embodiment of the present invention wherein picking and placing unit 400 picks and places sample precursor 20, Step (d) includes the following main sub-steps:

(i) Lifting sample precursor 20 by applying vacuum induced force to the surface of sample precursor 20, by means of vacuum aperture connected to pneumatics control unit 800. Then, there is verifying pick up of sample precursor 20, by a dedicated sensor assembly.

(ii) Enabling adhering by operation of adhering interface assembly 700, which interfaces transporting and positioning unit 200 with picking and placing unit 400, by the following procedure:
(1) Measuring the level of an adhesive material inside of adhesive receptacle 704, by probing with adhesive applying needle 706.
(2) Dipping adhesive applying needle 706 into adhesive receptacle 704 to a pre-determined level, so as to pick up an exact amount of adhesive material.
(3) Applying (dispensing) the exact amount of adhesive material onto a surface of a first component (for example, sample precursor 20 or unit component).
(4) Picking and placing a surface of a second component (unit component) of the system onto the surface of the first component (sample precursor 20). More specifically, for example, picking and placing unit 400 picks and places a masking element (as an exemplary second component), for example, a masking element being in the form of macro-size masking element 30 (particularly shown, for example, in FIG. 3), for example, operatively associated with, or part of, picking and placing unit 400 (FIGS. 1, 2, 4, 7A, 7B, 11A, and 11B).
(5) Applying and controlling the applied force at the interface between the surfaces of the two components, for a pre-determined curing time.

An illustrative example of performing Step (d), using picking and placing unit 400, of sample preparation system 10, of the present invention, is shown in FIGS. 11A-11B, schematic diagrams illustrating a perspective close-up view of a planar view sample preparation process involving performance of Step (d), for picking and placing a material, for example, a processed (cut and mounted) form of sample precursor 20 adhered to a portion 121 of sample precursor support structure 120, from an initial position to another functionally dependent position.

### Generating Micro-Groove in Sample Precursor

In Step (e), there is generating at least one micro-groove in a surface of sample precursor 20, by a micro-groove generating unit 500 (or unit 500′), wherein depth and quality of each micro-groove in the surface are controlled by components included in micro-groove generating unit 500 (or unit 500′).

Reference is again made to FIGS. 1, 2, and 4, FIGS. 5A-5C, and FIGS. 5D-5F, along with the illustrative description, hereinabove, of micro-groove generating unit 500, and components thereof, and alternative micro-groove generating unit 500′, and components thereof, respectively, of sample preparation system 10.

Step (e) is generally performed by activating micro-groove generating unit 500 (or 500′), so that micro-groove generating element 512, penetrates the surface of sample precursor 20, with controlled displacement and force. Immediately following there is described different specific modes of micro-groove generating element 512 penetrating the surface of sample precursor 20.

According to a first specific mode of penetration, micro-groove generating element 512 (or 552) is utilized for measuring a vertical slant of the surface of sample precursor 20.

This procedure is performed by bringing the tip of micro-groove generating element 512 (or 552) into contact with a first pre-determined position of the surface, by activating the z-axis displacement sub-assembly 230 of transporting and positioning unit 200. The surface of sample precursor 20 is then transported a predetermined distance along the x-axis, and the vertical displacement of micro-groove generating element 512 (or 552) is measured and registered. This results in a calculation of the slope of the surface of sample precursor 20. The angle of approach of micro-groove generating element 512 (or 552) is then aligned according to the value of the measured slope. Activation of the micro-grooving procedure is continued by elevating sample precursor 20 to a pre-determined position along the z-axis, by z-axis displacement sub-assembly 230, and then by activating force applying assembly 530 (or 580), while controlling depth and force of penetration of micro-groove generating element 512.

According to a second specific mode of penetration, micro-groove generating element 512 (or 552) is utilized for measuring a vertical slant of the surface of sample precursor 20. This procedure is performed by bringing the tip of micro-groove generating element 512 (or 552) into contact with a first pre-determined position of the surface, by activating the z-axis displacement sub-assembly 230 of transporting and positioning unit 200. The surface of sample precursor 20 is then transported a pre-determined distance along the x-axis, and the vertical displacement of micro-groove generating element 512 (or 552) is measured and registered. This results in a calculation of the slope of the surface of sample precursor 20. The angle of approach of micro-groove generating element 512 (or 552) is then intentionally off-set from (as opposed to being aligned according to) the value of the measured slope. Activation of the micro-grooving procedure is continued by elevating sample precursor 20 to a pre-determined position along the z-axis, by z-axis displacement sub-assembly 230, and then by activating force applying assembly 530 (or 580), while controlling depth and force of penetration of micro-groove generating element 512 (or 552). At this stage of this embodiment, sample precursor 20 is then transported a pre-determined distance along the x-axis, thereby causing a relative sliding motion of micro-groove generating element 512 (or 552) relative to sample precursor 20.

There are several characteristics of the micro-groove generating unit of sample preparation system 10 of the present invention, being either preferred embodiment, micro-groove generating unit 500 or micro-groove generating unit 500′, which lead to achieving the above described primary function of detaching a pre-determined number of layers of sample precursor 20 adjacent to features in a target area or region of interest (ROI) on the surface of sample precursor 20, in order to avoid undesirable generation of artifacts which may be induced during cryogenically sectioning of sample precursor 20.

For each respective preferred embodiment, micro-groove generating unit 500 or micro-groove generating unit 500′, of the micro-groove generating unit of sample preparation system 10 of the present invention, such characteristics are: (1) the type of material of micro-groove generating element 512 or 552, respectively, (2) the configuration, shape, or form, of micro-groove generating element 512 or 552, respectively, (3) the sharpness or radius of the tip of micro-groove generating element 512 or 552, respectively, (4) the angle of approach of micro-groove generating element 512 or 552, respectively, towards the surface of sample precursor 20, and (5) the manner by which the force is applied towards the surface of sample precursor 20, by micro-groove generating element 512 or 552, respectively.

An illustrative example of performing Step (e), by using micro-groove generating unit 500 or 500′, of sample preparation system 10, of the present invention, is shown in FIGS. 12A-12B, schematic diagrams illustrating perspective views (FIG. 12B being a close-up of FIG. 12A) of generating at least one micro-groove, for example, a pair of micro-grooves 590, in a surface of sample precursor 20 having a designated target area or region of interest (ROI), T.

Above illustratively described Step (e) of generating at least one micro-groove in a surface of sample precursor 20, as an exemplary material, by a micro-groove generating unit 500 (or 500′), corresponds to an integrated step or procedure of the overall sample preparation method, in accordance with another main aspect of the present invention of a method of preparing a sample for micro-analysis. The micro-groove generating step or procedure of the present invention is also separable and integratable with other sample preparation methods.

### Cryogenically Sectioning Sample Precursor

In Step (f), there is cryogenically sectioning sample precursor 20 to a pre-determined configuration and size, for forming a sectioned sample precursor 20, by a cryogenic sectioning unit 600.

Reference is again made to FIGS. 1, 2, and 4, and FIGS. 6A-6D, along with the illustrative description, hereinabove, of cryogenic sectioning unit 600, and components thereof, of sample preparation system 10.

Ordinarily, cryogenic sectioning of sample precursor 20 is performed following completion of Step (e), of generating at least one micro-groove in a surface of sample precursor 20, by micro-groove generating unit 500 (or 500′). The cryogenic sectioning is initiated by positioning sample precursor 20 in a predetermined location and configuration (orientation) by operation of transporting and positioning unit 200, according to a different specific sequence of sub-steps for performing Step (f) of cryogenically sectioning sample precursor 20. Each sub-step of the cryogenic sectioning process is performed by vertically moving either fine sectioning blade 602, or coarse sectioning blade 604, to a pre-determined level of penetration. Moreover, a given sub-step of the cryogenic sectioning process is performed according to only the vertical movement, or according to a subsequent horizontal movement of sample precursor 20 by operation of transporting and positioning unit 200. Optimum results of the cryogenic sectioning process are achieved by optimizing parameters associated with the vertical and horizontal movements of sample precursor 20.

Main objective for using fine sectioning blade 602 is to achieve a required ‘critical’ thickness (critical width (CW)) dimension having a typical range of from about 3 microns to about 30 microns, with the best quality of side walls adjacent to the target area.

Following completion of the cryogenic sectioning process, the exposed surfaces of the sectioned sample precursor 20 can be smoothed or polished by use of either fine sectioning blade 602, or coarse sectioning blade 604. This ‘post-cyrogenic sectioning’ smoothing or polishing procedure is accomplished by coordinated operation and fine movements of x-axis displacement sub-assembly 210 and y-axis displacement sub-assembly 220 of transporting and positioning unit 200, and optimum operation of the cryogenic fluid supply and control assembly. The smoothing or polishing procedure, optionally, is performed by adding a polishing slurry, along with optionally applying an electric current for enhancing the procedure.

As previously stated hereinabove, the presence and operative connection of pressure control mechanism 613 to cryogenic fluid reservoir 610, and use thereof, for improving the controllability and reproducibility of cryogenically sectioning sample precursor 20, represents a significant improvement over the cryogenic sectioning type of micro-analytical sample sectioning procedure which is disclosed in present assignee/applicant PCT Int'l. Pat. Appl. Publ. No. WO 02/054042. Specifically, the cryogenic sawing method disclosed in PCT Int'l. Pat. Appl. Publ. No. WO 02/054042 is absent of a procedure, as well as of a pressure control mechanism, for maintaining the pressure of the cryogenic fluid reservoir at a constant value. Accordingly, by using that cryogenic sawing method there is inherently lack of controllability and reproducibility of cryogenically sectioning a sample precursor.

Above illustratively described Step (f) of cryogenically sectioning sample precursor 20, as an exemplary material, to a pre-determined configuration and size, for forming a sectioned sample precursor 20, by a cryogenic sectioning unit 600, corresponds to an integrated step or procedure of the overall sample preparation method, in accordance with another main aspect of the present invention of a method of preparing a sample for micro-analysis. The cryogenic sectioning step or procedure of the present invention is also separable and integratable with other sample preparation methods.

As previously stated hereinabove, the method of preparing a sample for micro-analysis, of the present invention, optionally, further includes at least one additional main step (and components thereof) selected from the group consisting of: (g) adhering a first component to a second component within a sample preparation system 10, by an adhering interface assembly 700 which enables interfacing of a transporting and positioning unit 200 with a picking and placing unit 400; (h) controlling pneumatics of selected main components (a sample precursor holding unit 100, a transporting and positioning unit 200, a picking and placing unit 400, and a cryogenic sectioning unit 600) of sample preparation system 10, by a pneumatics control unit 800; (i) reducing size (surface area dimensions) of sample precursor 20 to a pre-determined sample precursor size, by a sample precursor micro-size (surface area dimensions) reducing unit 900; (j) generating a scribe line on a surface of sample precursor 20, and cleaving sample precursor 20 along the scribe line, by a scribing and cleaving unit 1000; (k) marking a target area or region of interest (ROI) on a surface of sample precursor 20, by a marking device; (l) adhering a macro-mask onto a surface of sample precursor 20, by selected sample preparation system main components; (m) adhering a micro-mask onto a surface of sample precursor 20, by a micro-mask adhering unit 1100; and (n) preventing or minimizing occurrence of vibrations during operation of sample preparation system 10, by an anti-vibration unit 1200.

The method of preparing a sample for micro-analysis further includes the step of providing electronics to, and enabling process control of, each main component of each above stated at least one additional main step (g)-step (n), by electronics and process control utilities 1300 which is operatively connected to each main component of each respective above stated at least one additional main step (g)-step (n), in a manner operatively integrated with each previously stated sample preparation method main step (a)-step (f).

### (Optional) Adiering a First Component to a Second Component

In (optional) Step (g), there is adhering a first component to a second component within sample preparation system 10, by an adhering interface assembly 700 which enables interfacing of transporting and positioning unit 200 with picking and placing unit 400.

Reference is again made to FIGS. 1, 2, and 4, and FIGS. 7A-7B, along with the illustrative description, hereinabove, of adhering interface assembly 700, and components thereof, of sample preparation system 10.

Adhering a first component to a second component within sample preparation system 10, by adhering interface assembly 700, is fully described hereinabove, with respect to performance of Step (d). Specifically, the adhering of Step (g) is performed by operation of adhering interface assembly 700, which interfaces transporting and positioning unit 200 with picking and placing unit 400, by the following procedure:

(1) Measuring the level of an adhesive material inside of adhesive receptacle 704, by probing with adhesive applying needle 706.

(2) Dipping adhesive applying needle 706 into adhesive receptacle 704 to a pre-determined level, so as to pick up an exact amount of adhesive material.

(3) Applying (dispensing) the exact amount of adhesive material onto a surface of a first component (for example, sample precursor 20 or unit component).

### (Optional) Controlling Pneumatics of System Components

In (optional) Step (h), there is controlling pneumatics of selected main components of sample preparation system 10, by a pneumatics control unit 800.

Reference is again made to FIGS. 1, 2, and 4, and FIG. 8A, along with the illustrative description, hereinabove, of pneumatics control unit 800, and components thereof, of sample preparation system 10.

Pneumatics of each of the following selected main components of sample preparation system 10: sample precursor holding unit 100, transporting positioning unit 200, picking and placing unit 400, and cryogenic sectioning unit 600, and of each of the following optional, additional main components: adhering interface assembly 700, sample precursor micro-size (surface area dimensions) reducing unit 900, scribing and cleaving unit 1000, and anti-vibration unit 1200, are controlled by operation of the main components, being solenoids, valves, distributors, wiring, and a centralized pneumatic control board, of pneumatics control unit 800, which, in turn, are electronically controlled via electronics and process control utilities 1300.

### (Optional) Reducing Size of Sample Precursor

In (optional) Step (i), there is reducing size (surface area dimensions) of the sample precursor 20 to a pre-determined sample precursor size, by a sample precursor size (surface area dimensions) reducing unit 900.

Reference is again made to FIGS. 1, 2, and 4, along with the illustrative description, hereinabove, of sample precursor size reducing unit 900, and components thereof, of sample preparation system 10.

In (optional) Step (i), there is reducing size (surface area dimensions) of sample precursor 20 to a pre-determined sample precursor size, by the main components, being sectioning blade 902, and sectioning blade drive shaft and motor assembly 904, of sample precursor size (surface area dimensions) reducing unit 900.

The micro-reducing procedure is initiated by positioning sample precursor 20 in a pre-determined location and configuration (orientation) by operation of transporting and positioning unit 200, according to a different specific sequence of sub-steps for performing Step (i) of reducing the size (surface area dimensions) of sample precursor 20. Each sub-step of the size reducing process is performed by vertically moving sectioning blade 902 to a pre-determined level of penetration. Step (i), optionally, is performed with cryogenic cooling, similar to that described for Step (f) as relating to cryogenically sectioning sample precursor 20 to a pre-determined configuration and size, by cryogenic sectioning unit 600. According to such an embodiment, sample precursor size reducing unit 900, optionally, further includes a cryogenic fluid supply and control assembly similar to the one included in cryogenic sectioning unit 600.

Step (i) is performed by sample precursor size reducing unit 900 being designed, constructed, and operated, for having components typically rotating at about 10,000 rpm, and does not require relatively high levels of stability and precision which are required for proper operation of cryogenic sectioning unit 600.

Preferably, Step (i) is performed by using sample precursor size reducing unit 900 (optionally, including a cryogenic fluid supply and control assembly, for example, similar to, or the same as, cryogenic fluid supply and control assembly (610 [FIG. 4]+612 [FIG. 4]+613 [FIG. 4]+614 [FIGS. 4, 6A-6D]) included in cryogenic sectioning unit 600). In an alternative preferred embodiment, Step (i) is performed by scribing and cleaving unit 1000.

### (Optional) Generating a Scribe Line on Sample Precursor

In (optional) Step (j), there is generating a scribe line on a surface of sample precursor 20, and cleaving sample precursor 20 along the scribe line, by a scribing and cleaving unit 1000.

Reference is again made to FIGS. 1, 2, and 4, and FIGS. 9A-9B, along with the illustrative description, hereinabove, of scribing and cleaving unit 1000, and components thereof, of sample preparation system 10.

Optional Step (j) includes the following main sub-steps:

(i) generating a scribe line on a surface of sample precursor 20.

(ii) cleaving sample precursor 20 along the scribe line.

For performing sub-step (i) of Step (j), there is using scribing assembly 1002, which includes the main components of: (1) scribing element 1008, (2) scribing element holder 1010, and (3) scribing element force and orientation controlling mechanism 1012. Scribing assembly 1002 is mounted onto a base element by means of a fixed axle, thus enabling rotation of scribing assembly 1002 relative to the scribed surface of sample precursor 20. Scribing element 1008, which has a sharp tip, and is held by scribing element holder 1010, is used for effectively forming a sufficiently sharply indented scribe line along a surface of sample precursor 20, thereby facilitating the subsequent cleaving of sub-step (2). Scribing element force and orientation controlling mechanism 1012 is, for example, spring loaded. Surface contact sensing mechanism 1006, part of scribing and cleaving unit 1000, is used for sensing a condition of contact between the surface of sample precursor 20 and scribing element 1008 of scribing assembly 1002.

For performing sub-step (ii) of Step (j), there is using cleaving assembly 1004, which includes the main components of: (1) cleaving plunger 1014, and (2) cleaving plunger housing and guide sub-assembly 1016. Cleaving assembly 1004 is mounted onto a base element by means of a fixed axle, thus enabling rotation and self-alignment of cleaving assembly 1004 relative to the cleaved surface of sample precursor 20. Cleaving plunger 1014, housed in cleaving plunger housing and guide sub-assembly 1016, is electronically activated and controlled via electronics and process control utilities 1300, for effectively cleaving sample precursor 20 along the scribe line generated by completion of sub-step (i).

An illustrative example of performing (optional) Step (j), by scribing and cleaving unit 1000, of sample preparation system 10, of the present invention, is shown in FIGS. 13A-13B, which are schematic diagrams illustrating perspective close-up views of generating a scribe line, for example, scribe line 1050, on a surface of sample precursor 20 having a designated target area or region of interest (ROI), T, by scribing assembly 1002, (FIG. 13A), and cleaving sample precursor 20 along scribe line 1050, by cleaving assembly 1004, (FIG. 13B). As shown in FIG. 13B, subsequent to cleaving sample precursor 20 along scribe line 1050 by cleaving assembly 1004, the first portion 17a of cleaved sample precursor 20 includes target area or region of interest (ROI) T, and the second portion 17b is without target area or region of interest (ROI) T.

### (Optional) Marking a Target Area (ROI) on Sample Precursor

In (optional) Step (k), there is marking a target area or region of interest (ROI) on a surface of sample precursor 20, by a marking device.

Reference is again made to FIGS. 1, 2, and 4, FIGS. 5A-5C, FIGS. 5D-5F, and FIGS. 9A-9B, along with the illustrative description, hereinabove, of using the optical imaging unit 300, micro-groove generating unit 500 or 500′, or scribing and cleaving unit 1000, and components thereof, for marking a region of interest (ROI) on sample precursor 20.

(Optional) Step (k) is performed according to any one of the following specific alternative preferred embodiments of the present invention.

In a first specific alternative preferred embodiment of the present invention, as schematically illustrated in FIGS. 14A and 14B, for performing (optional) Step (k), in sample preparation system 10, the marking device corresponds to optical imaging unit 300. According to this embodiment, one of the lens heads of microscope assembly 310 does not include an objective lens, and instead, has seated thereupon a spring loaded ink printing head, which is then used for marking, for example, via a circle 390, a target area or region of interest (ROI), for example, target area or region of interest (ROI) T, on a surface of sample precursor 20.

In a second specific alternative preferred embodiment of the present invention, as schematically illustrated in FIGS. 14A and 14C, for performing (optional) Step (k), in sample preparation system 10, the marking device corresponds to the micro-groove generating unit, being either preferred embodiment, micro-groove generating unit 500 or micro-groove generating unit 500′. According to this embodiment, micro-groove generating unit 500 or 500′ is used for marking, for example, via micro-grooves 590, a target area or region of interest (ROD, for example, target area or region of interest (ROI) T, on a surface of sample precursor 20.

In a third specific alternative preferred embodiment of the present invention, as schematically illustrated in FIGS. 14A and 14D, for performing (optional) Step (k), in sample preparation system 10, the marking device corresponds to scribing assembly 1002 of scribing and cleaving unit 1000. According to this embodiment, scribing assembly 1002 is used for marking, for example, via scribe lines 1090, a target area or region of interest (ROI), for example, target area or region of interest (ROI) T, on a surface of sample precursor 20.

(Optional) Adhering a Macro-mask onto Sample Precursor

In (optional) Step (l), there is adhering a macro-mask onto a surface of sample precursor 20, by selected system units.

Reference is again made to FIGS. 1, 2, 3, and 4, and FIGS. 7A-7B, along with the illustrative description, hereinabove, of sample precursor holding unit 100, picking and placing unit 400, and the adhering interface assembly 700, and components thereof, of sample preparation system 10.

As previously stated hereinabove, the functions of sample precursor holding unit 100, and components thereof, as illustratively described hereinabove, being performed on sample precursor 20, are alternatively or additionally, similarly performed on a masking element, where a masking element refers to an element which masks at least a portion of a sample precursor, such as sample precursor 20, for the objective of protecting the at least portion of the sample precursor during another sample preparation procedure, not necessarily implemented by the present invention. Such a masking element may be in the form of ‘macro-size’ masking element 30 (particularly shown, for example, in FIG. 3), for example, operatively associated with, or part of, picking and placing unit 400 (FIGS. 1, 2, 4, 7A, 7B, 11A, and 11B).

Optional Step (l) includes the following main sub-steps:

(i) Generating at least one micro-groove in a surface of sample precursor 20, in accordance with above described Step (e), by using micro-groove generating unit 500 (or 500′).

(ii) Adhering, via the adhering procedure of Step (g), macro-mask 30 at a pre-determined location and according to a pre-determined configuration (orientation) onto the surface of sample precursor 20, in such a way that each generated micro-groove is extended in reference to macro-mask 30, and therefore, is visible by optical imaging unit 300 for subsequent subjection to cryogenic sectioning by cryogenic sectioning unit 600. Accordingly, the micro-groove acts as a mark for performing the cryogenic sectioning procedure of Step (f), as described hereinabove.

A main purpose of the macro-mask adhering procedure of optional Step (l) is to facilitate subjection of a prepared sample to subsequent micro-analytical sample final preparation techniques, such as those involving ion beam milling. Such sample final preparation techniques are relevant for at least four different main categories of different exemplary specific preferred embodiments of implementing the present invention, being: (A) TEM side view (cross section), (B) TEM plan (planar) view, (C) SEM side view (cross section), and (D) Back-side Exposing.

Above illustratively described Step (l) of adhering a macro-mask onto a surface of sample precursor 20, as an exemplary material, by selected system units, corresponds to an integrated step or procedure of the overall sample preparation method, in accordance with another main aspect of the present invention of a method of preparing a sample for micro-analysis. The macro-mask adhering step or procedure of the present invention is also separable and integratable with other sample preparation methods.

(Optional) Adhering a Micro-Mask onto Sample Precursor

In (optional) Step (m), there is adhering a micro-mask onto a surface of sample precursor 20, by micro-mask adhering unit 1100.

Reference is again made to FIGS. 1, 2, and 4, FIGS. 10A-10B, and FIG. 10C, along with the illustrative description, hereinabove, of micro-mask adhering unit 1100, and components thereof, of sample preparation system 10.

There are two main particular embodiments of the present invention wherein (optional) Step (m) is performed by using micro-mask adhering unit 1100 for adhering a micro-mask onto a surface of sample precursor 20. In a first particular embodiment, (optional) Step (m) is performed for adhering a micro-mask onto a surface of a previously cryogenically sectioned sample precursor 20, having been cryogenically sectioned according to Step (f), previously illustratively described hereinabove. Alternatively, in a second particular embodiment, (optional) Step (m) is performed by using micro-mask adhering unit 1100 for adhering a micro-mask onto a surface of sample precursor 20, wherein sample precursor 20 has not been subjected to a cryogenic sectioning procedure.

For the first particular embodiment of the present invention wherein (optional) Step (m) is performed by using micro-mask adhering unit 1100 for adhering a micro-mask onto a surface of a cryogenically sectioned sample precursor 20, optional Step (m) includes the following main sub-steps:

(i) Recognizing the presence of micro-size masking element 1110 mounted on chuck base assembly 140 of sample precursor holding unit 100, by using a vacuum recognition assembly as part of pneumatics control unit 800.

(ii) Transporting and positioning micro-size masking element 1110 mounted on chuck base assembly 140, by using transporting and positioning unit 200, along with operation of optical imaging unit 300.

(iii) Moving Y-axis displacement sub-assembly 1150 to an active position (beneath optical imaging unit 300).

(iv) Picking up micro-size masking element 1110 from chuck base assembly 140, by housing assembly 1140, as shown in FIGS. 10A-10B, and FIG. 10C.

(v) Recognizing the presence of micro-size masking element 1110 being picked up by housing assembly 1140, by the vacuum recognition assembly of pneumatics control unit 800.

(vi) Applying adhesive onto a dedicated area on a surface of sample precursor 20, by picking and placing unit 400.

(vii) Positioning the dedicated area with the adhesive applied under micro-size masking element 1110, by using transporting and positioning unit 200.

(viii) Controllably dipping micro-size masking element 1110 into the adhesive, by using z-axis displacement sub-assembly 230 of transporting and positioning unit 200.

(ix) Focusing micro-size masking element 1110, by using z-axis displacement sub-assembly 1160.

(x) Registering the xy position of micro-size masking element 1110, by using optical imaging unit 300.

(xi) Vertically moving micro-size masking element 1110 out of focus of optical imaging unit 300, by using z-axis displacement sub-assembly 1160.

(xii) Positioning the target feature on the surface of sample precursor 20, to be coincident with the position formerly occupied by micro-size masking element 1110 prior to being taken out of focus, by using all components of transporting and positioning unit 200.

(xiii) Vertically moving micro-size masking element 1110 down until contact is made with the surface of sample precursor 20, by using z-axis displacement sub-assembly 1160.

(xiv) Applying an electrical current to micro-size masking element 1110, for the purpose of heating, and thereby, curing, micro-size masking element 1110.

(xv) Increasing the applied electrical current to the edges of micro-size masking element 1110, in order to trim, via melting, the edges of micro-size masking element 1110.

(xvi) Performing optical verification of sub-steps (i) through (xv), as a form of quality control of the micro-mask adhering process.

For performing (optional) Step (m), inclusion of above described main sub-steps (i), (ii), (iii), (iv), and (v), are preferred, but not required for completing the micro-mask adhering process in a manner such that the micro-mask becomes adhered onto the surface of the cryogenically sectioned sample precursor 20.

The above two main particular embodiments of performing (optional) Step (m) by using micro-mask adhering unit 1100 of sample preparation system 10, of the present invention, are illustratively exemplified in FIGS. 15A, and 15B-15C, respectively. FIGS. 15A, and 15B-15C, are schematic diagrams illustrating perspective close-up views of the two main particular embodiments, respectively, of performing (optional) Step (m), for adhering a micro-mask, for example, micro-masking element 1110 (having a cylindrical shaped micron-sized wire (FIG. 15A), or a rectangular shaped profile (FIGS. 15B-15C)), onto a surface of sample precursor 20. The first particular embodiment of using micro-mask adhering unit 1100 is illustrated in FIG. 15A, wherein sample precursor 20 has been previously cryogenically sectioned according to the cryogenic sectioning procedure of Step (f). In FIG. 15A, cryogenically sectioned sample precursor 20 is shown adhered to a side view type of sample precursor support structure 110. The second particular embodiment of using micro-mask adhering unit 1100 is illustrated in FIGS. 15B-15C, wherein sample precursor 20 has not been subjected to a cryogenic sectioning procedure. In FIGS. 15B and 15C, sample precursor 20 is shown including a target area or region of interest (ROI) T.

A main purpose of the micro-mask adhering procedure of (optional) Step (m) is to facilitate subsequent micro-analytical sample final preparation techniques, such as those involving ion beam milling. This is accomplished by implementing the system and corresponding method of the present invention according to the following four different main categories of various different exemplary specific preferred embodiments: (A) TEM side view (cross section), (B) TEM plan (planar) view, (C) SEM side view (cross section), and (D) Back-side Exposing.

Above illustratively described Step (m), there is adhering a micro-mask onto a surface of sample precursor 20, as an exemplary material, by micro-mask adhering unit 1100, corresponds to an integrated step or procedure of the overall sample preparation method, in accordance with another main aspect of the present invention of a method of preparing a sample for micro-analysis. The micro-mask adhering step or procedure of the present invention is also separable and integratable with other sample preparation methods.

### (Optional) Preventing/Minimizing Vibrations

In (optional) Step (n), there is preventing or minimizing occurrence of vibrations during operation of sample preparation system 10, by an anti-vibration unit 1200.

Reference is again made to FIGS. 1, 2, and 4, and FIG. 8B, along with the illustrative description, hereinabove, of anti-vibration unit 1200, and components thereof, of sample preparation system 10.

(Optional) Step (n) of preventing or minimizing occurrence of vibrations during operation of sample preparation system 10, is performed by operation of the main components of anti-vibration unit 1200, being a plurality of electro-pneumatic or/and electro-mechanical active damping assemblies, for example, four electro-pneumatic active damping assemblies, each generally indicated by 1210 in FIG. 8. For performing (optional) Step (n), anti-vibration unit 1200 is operatively connected to electronics and process control utilities 1300 which provides electronics to, and enables process control of anti-vibration unit 1200.

### Providing Electronics and Process Control to System Components

The method of preparing a sample for micro-analysis further includes the step of providing electronics to, and enabling process control of, each main component of each above stated main Step (a)-Step (f), by an electronics and process control utilities 1300 which is operatively connected to each above stated main component. Moreover, the method of preparing a sample for micro-analysis further includes the step of providing electronics to, and enabling process control of, each main component of each above stated at least one additional main Step (g)-Step (n), by the electronics and process control utilities which is operatively connected to each main component of each respective above stated at least one additional main Step (g)-Step (n), in a manner operatively integrated with each previously described sample preparation method main Step (a)-Step (f).

In general, any number and type or kind of the following main components: a central control panel or board, at least one computer, microprocessor, or central processing unit (CPU), along with associated computer software, power supplies, power converters, controllers, controller boards, various printed circuit boards (PCBs), for example, including input/output (I/O) and D/A (digital to analog) and A/D (analog to digital) functionalities, cables, wires, connectors, shieldings, groundings, various electronic interfaces, and network connectors, of electronics and process control utilities 1300, are used for providing electronics to, and enabling process control of, main components of the sample preparation system, in a manner operatively integrated with each previously described sample preparation method main step.

For example, with reference again made to FIG. 8 (lower part), electronics and process control utilities 1300 includes the main components of: (i) a computerized control unit 1302, (ii) an electronics board 1304, and (iii) a power supply module 1306. Computerized control unit 1302 includes a computer, for example, a PC computer, operative with a plurality of electronic boards, such as motion control and signal interface types of electronic boards.

The system and corresponding method for preparing a sample for micro-analysis, according to the present, as illustratively described hereinabove, are implemented according to several different specific embodiments. The different specific embodiments of implementing the present invention are based on different specific micro-analytical techniques (as briefly summarized in the Background section) subsequently applied to the prepared sample, where the sample is prepared according to a corresponding specific geometrical configuration, shape, or form, and dimensions. Four different main categories of various different exemplary specific preferred embodiments of implementing the system and corresponding method of the present invention are: (A) TEM side view (cross section), (B) TEM plan (planar) view, (C) SEM side view (cross section), and (D) Back-side Exposing.

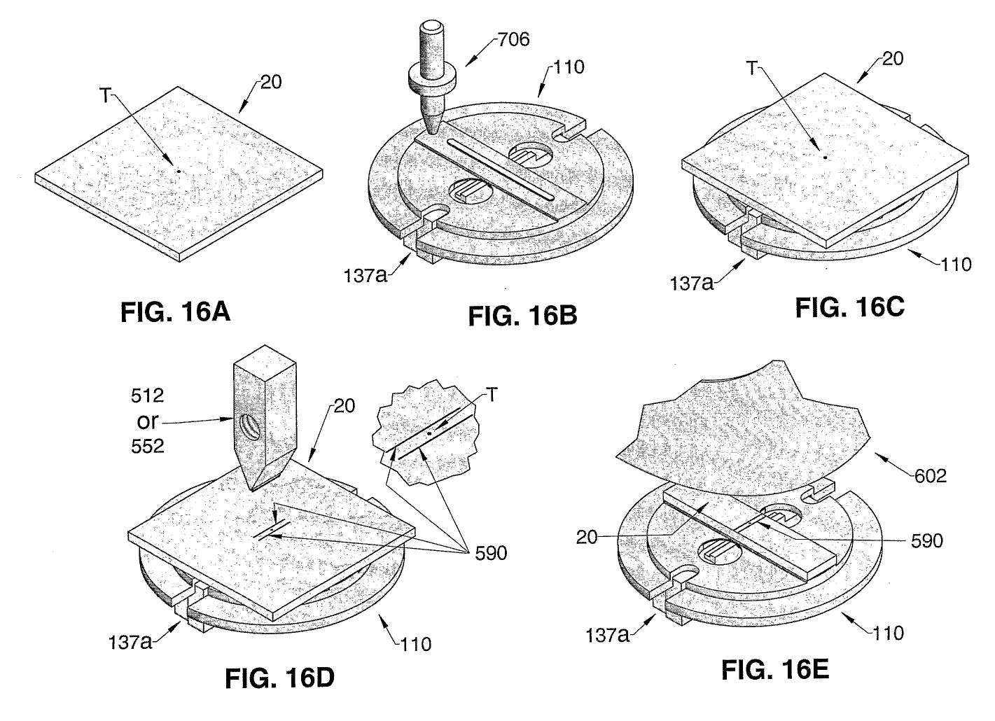

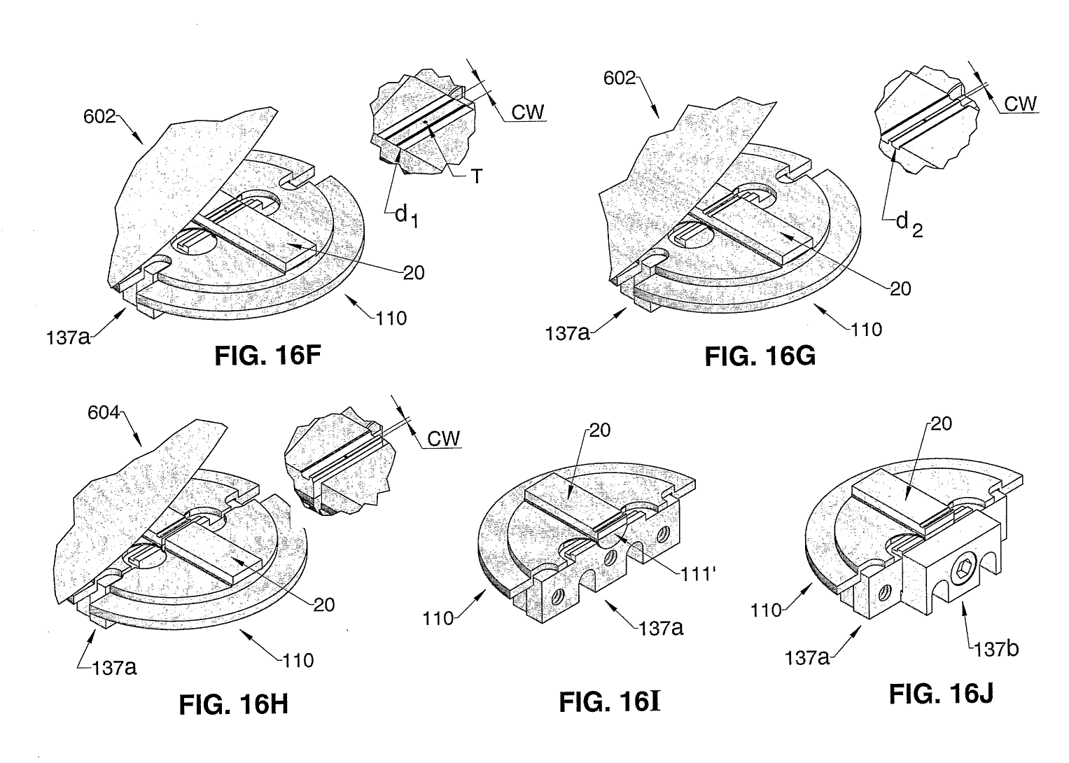

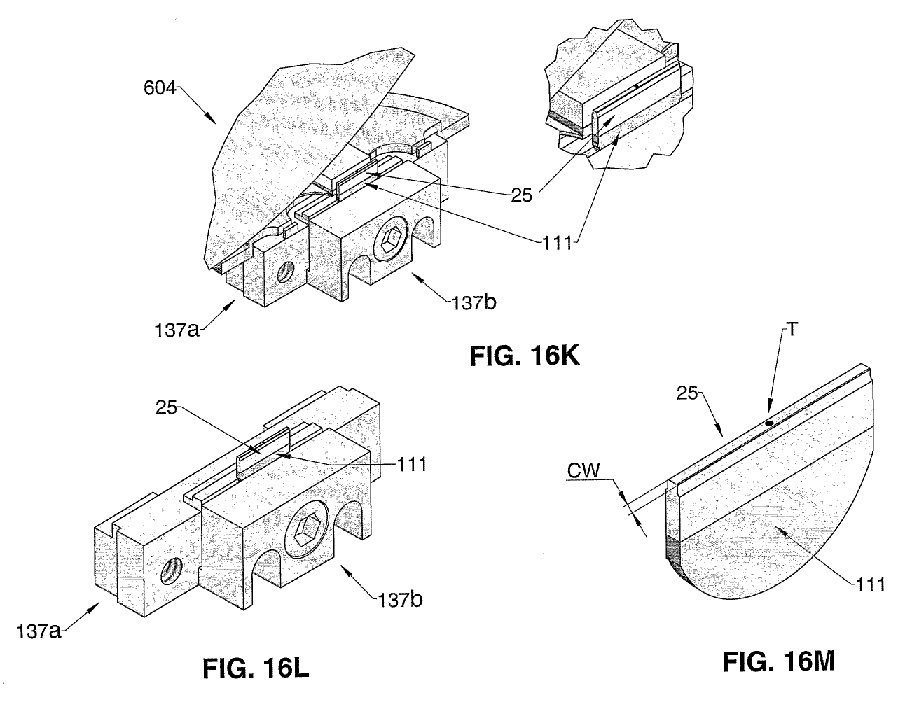

Reference is now made to FIGS. 16A-16M, FIGS. 17A-17R, FIGS. 18A-18K, and FIGS. 19A-19P, which are schematic diagrams illustrating exemplary specific preferred embodiments of typical sequences of selected steps which are performed during a category (A), (B), or (C), type of sample preparation procedure, by implementing the hereinabove described sample preparation system 10, and the corresponding sample preparation method, as illustrated in FIGS. 1-15, for preparing a sample for micro-analysis, in accordance with the present invention. Throughout the following illustrative description and accompanying drawings of FIGS. 16-19, same reference numbers refer to same system units, system sub-units, devices, assemblies, sub-assemblies, mechanisms, structures, components, elements, and configurations, and materials, which are shown in FIGS. 16-19, as well as those which are shown in FIGS. 1-15.

### TEM Side View (Cross Section)

FIGS. 16A-16M are schematic diagrams illustrating an exemplary specific preferred embodiment of a typical sequence of selected steps which are performed during a category (A)—TEM side view (cross section), type of sample preparation procedure, by implementing sample preparation system 10, and the corresponding sample preparation method, for preparing a sample for micro-analysis.

FIG. 16A illustrates an exemplary sample precursor 20 including a target area or region of interest (ROI), for example, target area or region of interest (ROI) T, where sample precursor 20 is to be subjected to implementation of the present invention.

FIGS. 16B-16C illustrate performing Step (a) of loading sample precursor 20 onto side view (cross section) type of sample precursor support structure 110 of sample precursor holding unit 100, and Step (d) of picking and placing sample precursor 20 from an initial position to a position on sample precursor support structure 110 by picking and placing unit 400.

FIG. 16D illustrates performing Step (e) of generating a pair of micro-grooves 590, in the surface of sample precursor 20 having designated target area or region of interest (ROI), T, by micro-groove generating unit 500 or 500′.

FIGS. 16E-16M illustrate performing Step (f) of cryogenically sectioning sample precursor 20 to a pre-determined configuration and size, for forming prepared sample 25, by cryogenic sectioning unit 600. Therein, FIG. 16F particularly shows fine cutting of sample precursor 20 by vertically moving fine sectioning blade 602, to a pre-determined level of penetration, for example, to a depth, d₁, for the purpose of initial penetrating or breaking of the surface of sample precursor 20. Fine sectioning blade 602 is primarily used for achieving a required ‘critical’ thickness or width, shown in FIG. 16 as CW. FIG. 16G particularly shows a final stage of the fine cutting of sample precursor 20 with penetration to the pre-determined depth, d₂, into sample precursor 20. FIGS. 16H-16K particularly show the stage of coarse cutting of sample precursor 20, for cuffing completely through sample precursor 20 and sample precursor support structure 110. FIG. 16M particularly shows TEM side view (cross section) prepared sample 25 rigidly and firmly supported by prepared sample support element 111 (whose precursor is indicated by 111′ as shown in FIG. 16I).

### TEM Plan (Planar) View

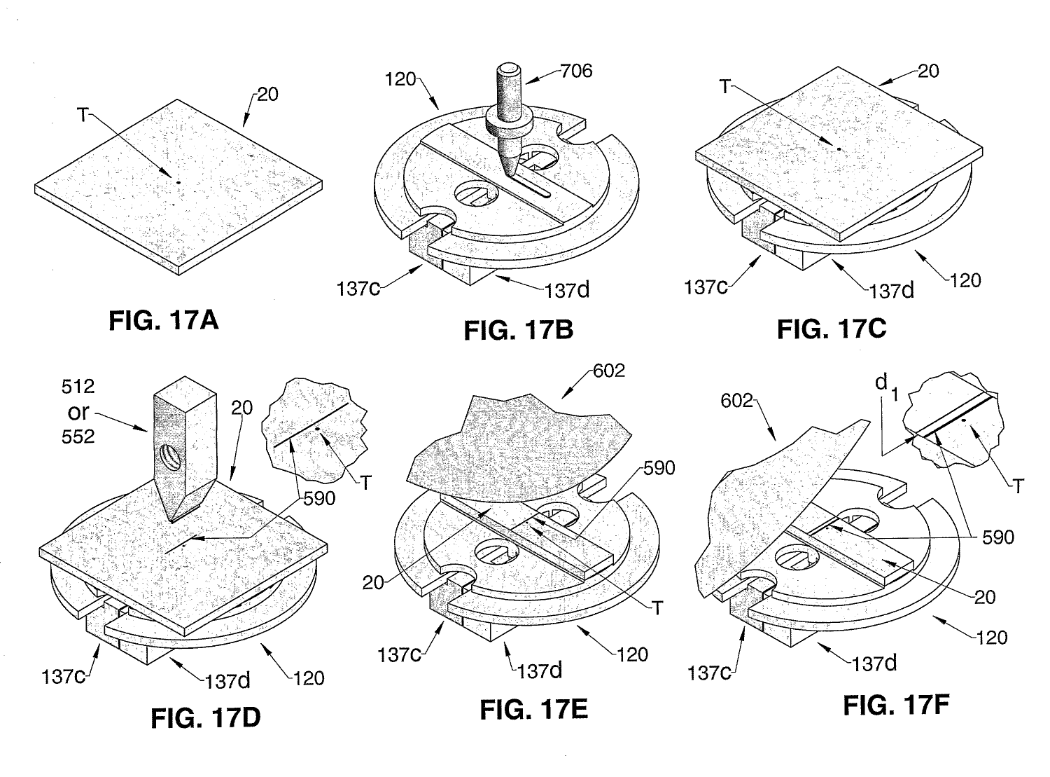

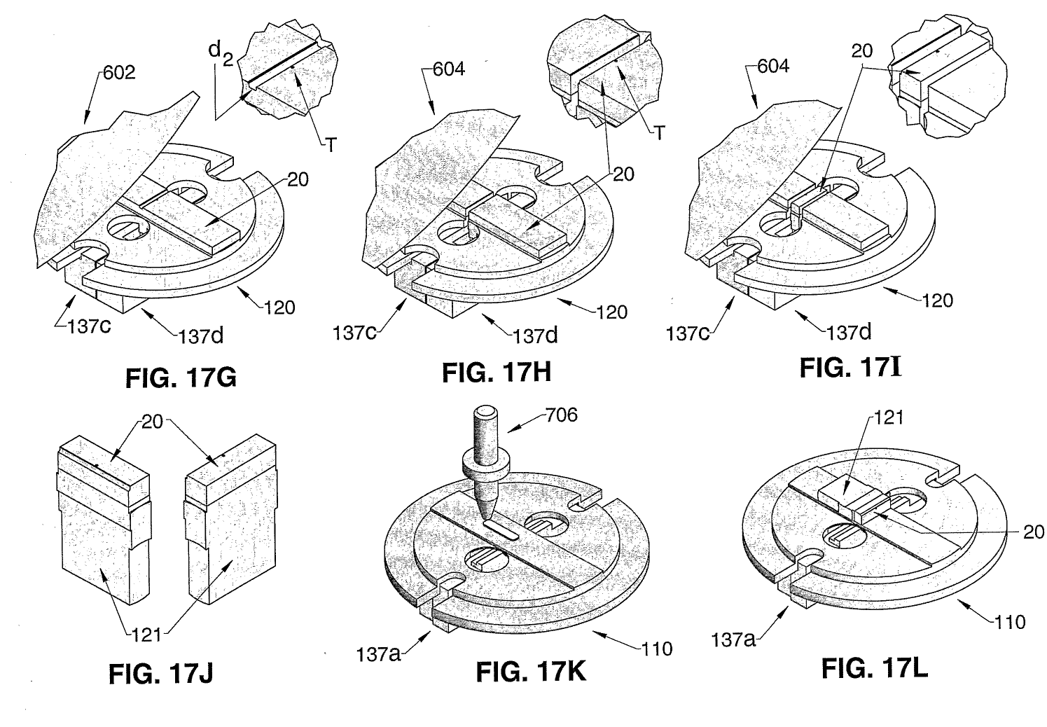

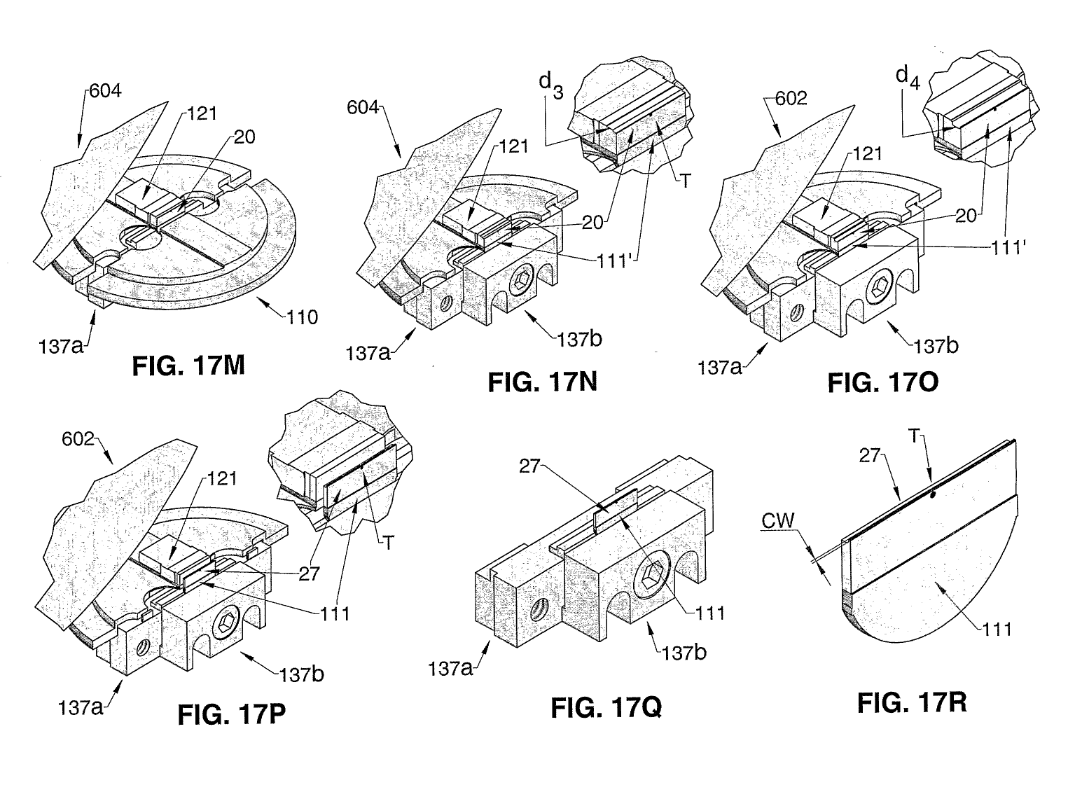

FIGS. 17A-17R are schematic diagrams illustrating an exemplary specific preferred embodiment of a typical sequence of selected steps which are performed during a category (B)—TEM plan (planar) view, type of sample preparation procedure, by implementing sample preparation system 10, and the corresponding sample preparation method, for preparing a sample for micro-analysis.

The TEM plan (planar) view type of sample preparation procedure can be characterized as a two-stage process. The first stage is specific for preparing an interim type of processed sample precursor, and the second stage is specific for preparing the final prepared sample, in particular, prepared sample 25, according to a similar sequence of steps (except for Step (e)) which are included in the TEM side view (cross section) type of sample preparation procedure previously illustrated in FIGS. 16B-16M.

FIG. 17A illustrates an exemplary sample precursor 20 including a target area or region of interest (ROI), for example, target area or region of interest (ROI) T, where sample precursor 20 is to be subjected to implementation of the present invention.

FIGS. 17B-17C illustrate performing Step (a) of loading sample precursor 20 onto plan (planar) view type of sample precursor support structure 120 of sample precursor holding unit 100, and Step (d) of picking and placing sample precursor 20 from an initial position to a position on sample precursor support structure 120 by picking and placing unit 400.

FIG. 17D illustrates performing Step (e) of generating a single micro-groove 590, in the surface of sample precursor 20 having designated target area or region of interest (ROI), T, by micro-groove generating unit 500 or 500′.

FIGS. 17E-17J illustrate performing Step (f) of cryogenically sectioning sample precursor 20 to a pre-determined configuration and size, for preparing an interim type of processed sample precursor. Therein, FIGS. 17F-17G show the stage of forming two fine cuts, of depths d₁, and d₂, and FIGS. 17H-17I show the stage of coarse cutting of sample precursor 20, for cutting completely through sample precursor 20 and sample precursor support structure 120.

FIGS. 17K-17R particularly show the second stage of the TEM plan (planar) view type of sample preparation procedure, by continuing processing of the preceding, formed interim type of processed sample precursor, for preparing the final prepared sample, in particular, prepared sample 27. Therein, FIGS. 17M-17N show the stage of forming a coarse cut, of depth d₃, and FIG. 17O shows the stage of fine cutting of sample precursor 20, for forming a fine cut, of depth, d₄.

### TEM Side View (Cross Section)

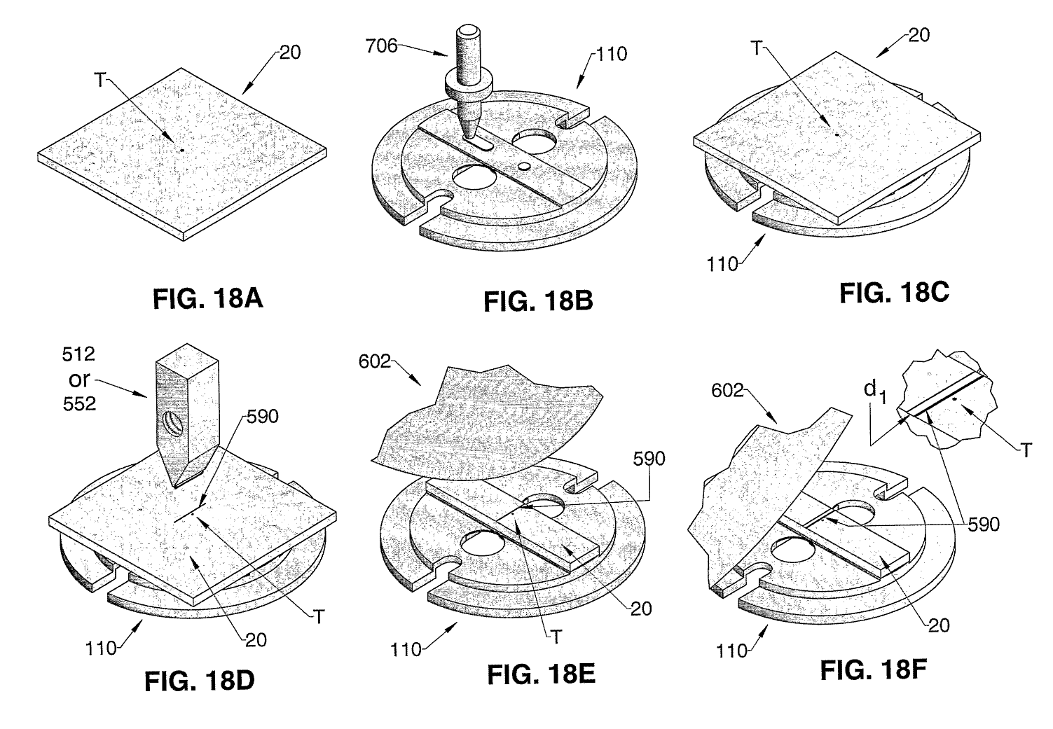

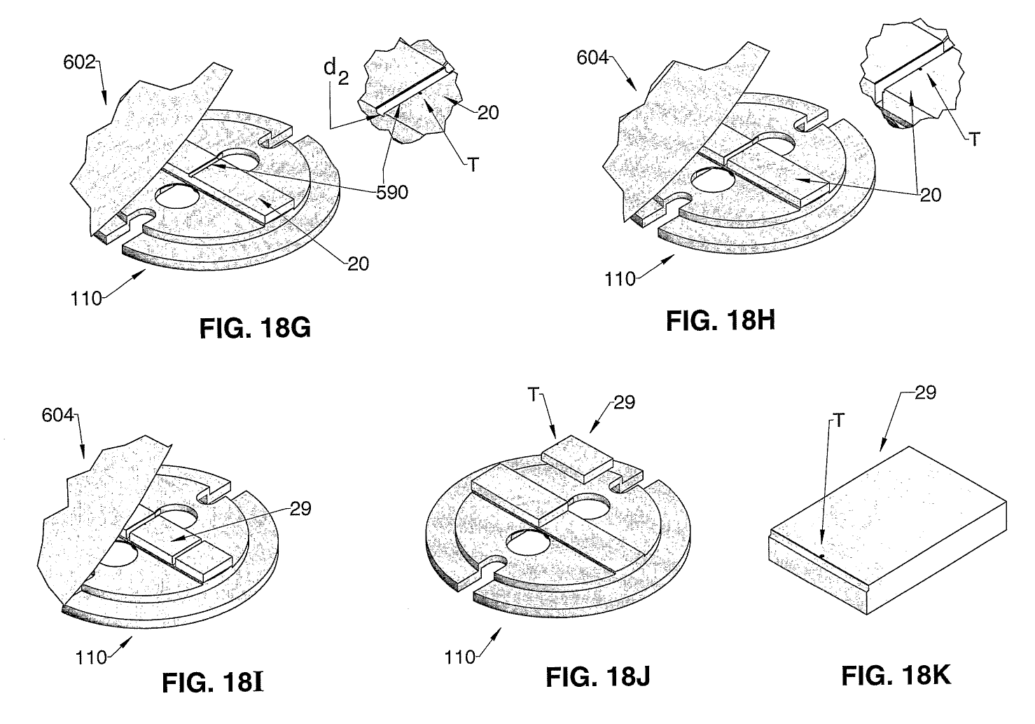

FIGS. 18A-18K are schematic diagrams illustrating an exemplary specific preferred embodiment of a typical sequence of selected steps which are performed during a category (C)—SEM side view (cross section), type of sample preparation procedure, by implementing sample preparation system 10, and the corresponding sample preparation method, for preparing a sample for micro-analysis.

FIG. 18A illustrates an exemplary sample precursor 20 including a target area or region of interest (ROI), for example, target area or region of interest (ROI) T, where sample precursor 20 is to be subjected to implementation of the present invention.

FIGS. 18B-18C illustrate performing Step (a) of loading sample precursor 20 onto side view (cross section) type of sample precursor support structure 110 of sample precursor holding unit 100, and Step (d) of picking and placing sample precursor 20 from an initial position to a position on sample precursor support structure 110 by picking and placing unit 400.

FIG. 18D illustrates performing Step (e) of generating a single micro-groove 590, in the surface of sample precursor 20 having designated target area or region of interest (ROI), T, by micro-groove generating unit 500 or 500′.

FIGS. 18E-18K illustrate performing Step (f) of cryogenically sectioning sample precursor 20 to a pre-determined configuration and size, for forming prepared sample 29, by cryogenic sectioning unit 600. Therein, FIGS. 18E-18G show the stage of forming two fine cuts, of depths d₁, and d₂, and FIGS. 18H-18K show the stage of coarse cutting of sample precursor 20, for cutting completely through sample precursor 20 and sample precursor support structure 110. Therein, it is particularly noted that coarse cutting of sample precursor 20 is performed only on sample precursor 20, followed by lifting off final prepared sample 29 from sample precursor support structure 110, in contrast to performing Step (f) in TEM side view (cross section), and TEM plan (planar) view, types of sample preparation procedures (FIGS. 16E-16M, and FIGS. 17E-17J, respectively).

### TEM Side View (Cross Section)

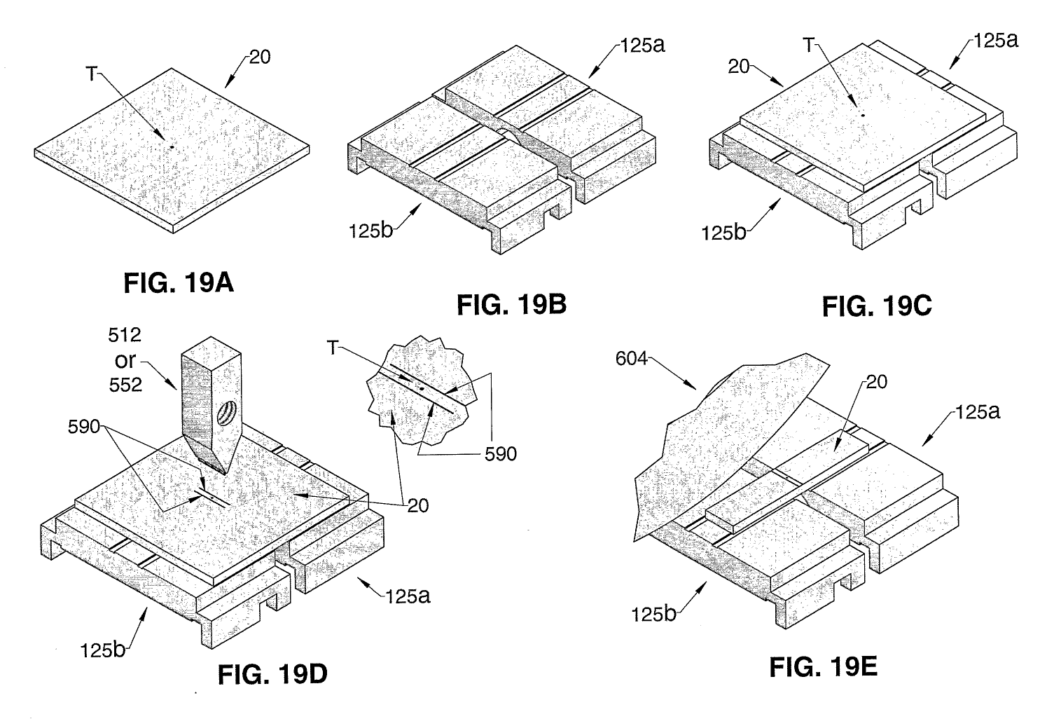

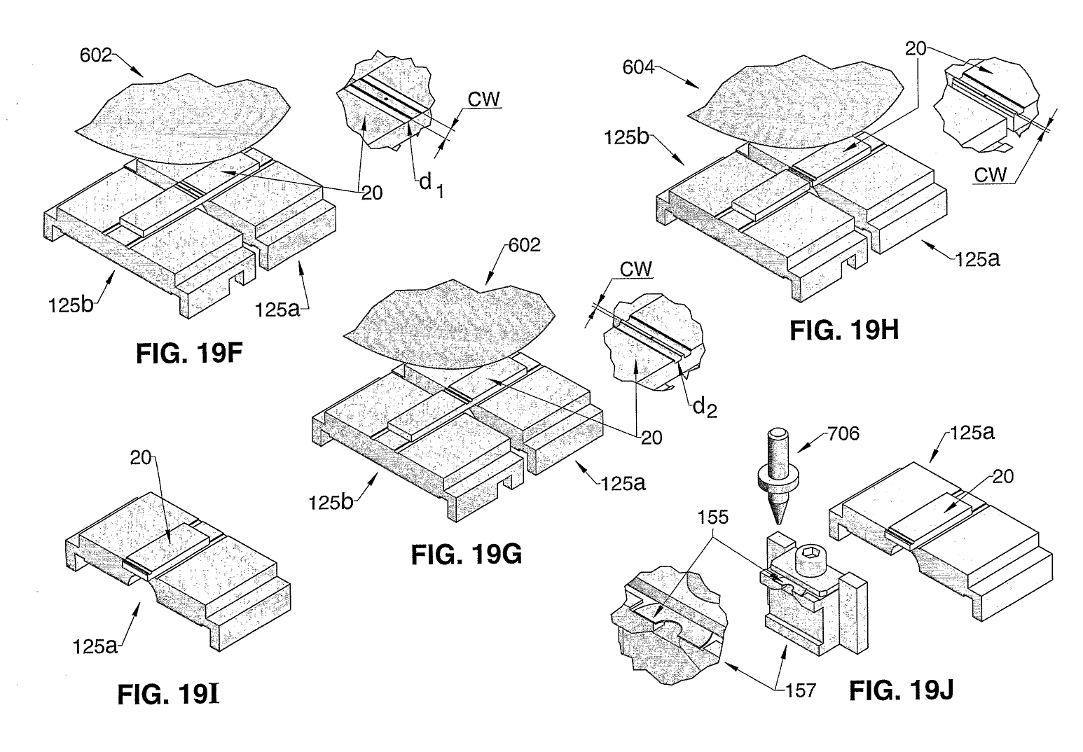

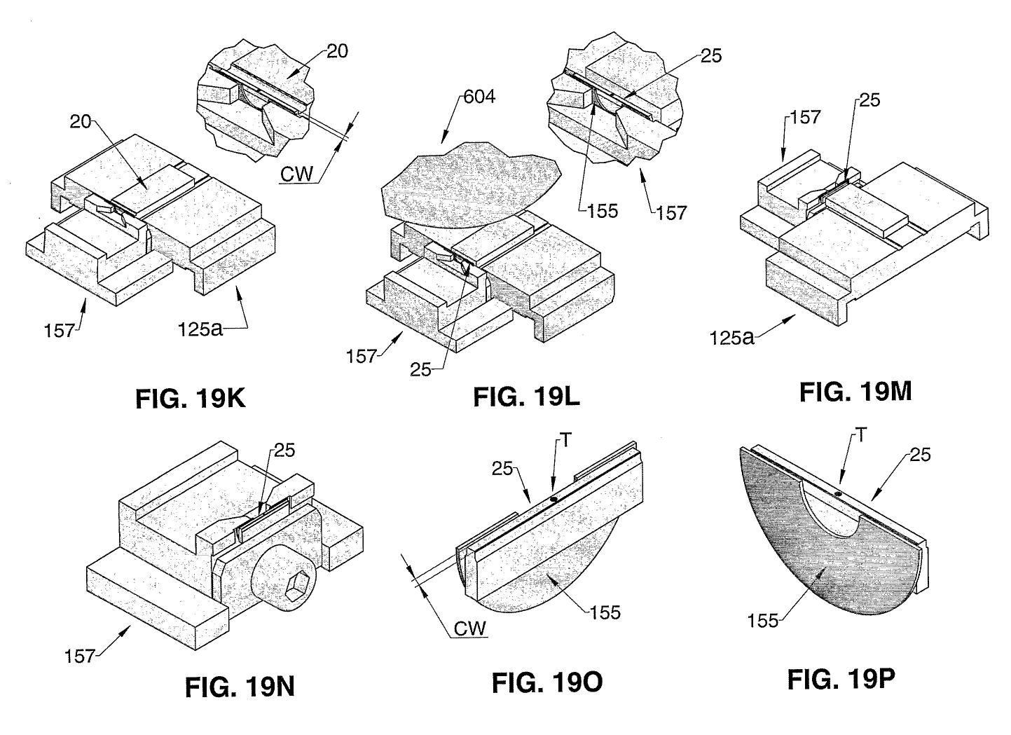

FIGS. 19A-19P are schematic diagrams illustrating an exemplary specific preferred embodiment of a typical sequence of selected steps which are performed during a category (A)—TEM side view (cross section) type of sample preparation procedure, wherein the final prepared sample is supported by a prepared sample support element, by implementing sample preparation system 10, and corresponding sample preparation method, for preparing a sample for micro-analysis.

FIG. 19A illustrates an exemplary sample precursor 20 including a target area or region of interest (ROI), for example, target area or region of interest (ROI) T, where sample precursor 20 is to be subjected to implementation of the present invention.

FIGS. 19B-19C illustrate performing Step (a) of loading sample precursor 20 onto the set of side view (cross section) type of sample precursor support structures 125a and 125b of sample precursor holding unit 100, and Step (d) of picking and placing sample precursor 20 from an initial position to a position on the set of sample precursor support structures 125a and 125b by picking and placing unit 400.

FIG. 19D illustrates performing Step (e) of generating a pair of micro-grooves 590, in the surface of sample precursor 20 having designated target area or region of interest (ROI), T, by micro-groove generating unit 500 or 500′.

FIGS. 19E-19P illustrate performing Step (i) of cryogenically sectioning sample precursor 20 to a pre-determined configuration and size, for forming prepared sample 25, by cryogenic sectioning unit 600. Therein, FIG. 19F particularly shows fine cutting of sample precursor 20 by vertically moving fine sectioning blade 602, to a pre-determined level of penetration, for example, to a depth, d₁, for the purpose of initial penetrating or breaking of the surface of sample precursor 20. Fine sectioning blade 602 is primarily used for achieving a required ‘critical’ thickness or width, shown in FIGS. 19 as CW. FIG. 19G particularly shows a final stage of the fine cutting of sample precursor 20 with penetration to the pre-determined depth, d₂, into sample precursor 20. FIGS. 19H-19I particularly show removal of sample precursor support structure 125b, thereby leaving in place sample precursor support structure 125a supporting sample precursor 20. FIG. 19J particularly shows prepared sample support element 155 being held or fixed by prepared sample support element holder 157. FIG. 19K particularly shows prepared sample support element holder 157 appropriately oriented and positioned relative to sample precursor support structure 125a supporting sample precursor 20, and subsequently attached or connected thereto. FIGS. 19L-19P particularly show completion of performing Step (f) using coarse sectioning blade 604. FIG. 19P particularly shows prepared sample support element 155 supporting and fixed to the side of prepared sample 25.

In a non-limiting manner, it is to be fully understood that hereinabove described embodiment of a typical sequence of selected steps which are performed during a category (A)—TEM side view (cross section) type of sample preparation procedure, wherein the final prepared sample is supported by a prepared sample support element, as illustrated in FIGS. 19A-19P, is applicable as part of performing a typical sequence of steps during a category (B)—TEM plan (planar) view type of sample preparation procedure, wherein the final prepared sample is supported by a prepared sample support element, by implementing sample preparation system 10, and corresponding sample preparation method, for preparing a sample for micro-analysis.

Thus, based on, in addition to, or a consequence of, the above described aspects of novelty and inventiveness, the present invention as illustratively described and exemplified hereinabove, has several beneficial and advantageous aspects, characteristics, or features.

The present invention, particularly as relating to semiconductor manufacturing, micro-analytical testing, and materials science, is implementable prior to applying a micro-analytical sample final preparation technique, which, in turn, is used for preparing a sample in a final form ready for subjection to micro-analysis, such as by an electron microscopy technique, an atomic force microscopy technique, or/and an ion spectrometry technique, primarily for the purpose of inspecting or examining samples, especially for the presence of manufacturing defects or/and artifacts.

The present invention is a type of micro-analytical sample preparation technique which is based on sectioning or segmenting of at least a part of a material, such as a sample precursor, via reducing at least one dimension (length, width, or/and thickness, depth or height), of the size of the sample precursor, thereby producing a prepared sample ready for subjection to another process.

The present invention is applicable for performing various different procedures involved during the implementation of (1) thinning, (2) cross-sectioning, or/and (3) plan view sectioning, main categories of sectioning types of micro-analytical sample preparation techniques, according to the particular type of micro-analytical technique ultimately applied for analyzing a sample. The present invention is applicable for preparing micro-analytical samples of different types of materials, such as semiconductor materials (particularly, wafers, wafer segments, and wafer dies), ceramic materials, pure metallic materials, metal alloy materials, and composite materials thereof, where a given material is mono-crystalline, poly-crystalline, or amorphous. The present invention is applicable for preparing general area or specific site (target) samples that are suitable for being subjected to any of a variety of different types of sample final preparation techniques, and that are suitable for ultimately being subjected to any of a variety of different types of micro-analytical techniques.

Based upon the above indicated aspects of novelty and inventiveness, and, beneficial and advantageous aspects, characteristics, or features, the present invention successfully overcomes several significant limitations, and widens the scope, of presently known techniques of preparing samples for micro-analysis.

The present invention overcomes the various significant limitations and disadvantages which are associated with current practice of prior art sectioning types of micro-analytical sample preparation techniques, previously described in the Background, hereinabove, as relating to the particular type (physicochemical properties, characteristics, and behavior, and dimensions) of the initial sample precursor used and of the sectioned sample subsequently prepared, and as relating to the particular preparatory requirements of the micro-analytical technique which is ultimately used for analyzing a given sample.

Specifically, regarding the type of sample precursor which is used for preparing a sectioned (cut, sliced) sample, the present invention is particularly suitable for sectioning (cutting, slicing) in any specific direction in a mono-crystalline, poly-crystalline, or amorphous, type of sample precursor material, regardless of crystal boundaries or edges. The present invention is suitable for processing sample precursors having adjacent layers which poorly adhere to each other. The present invention is suitable for ‘in-line’ initial handling and processing of relatively large sample precursors, for example, a whole semiconductor wafer having a diameter of about 300 mm.

Specifically, regarding the type of the sectioned sample subsequently prepared, the present invention is suitable for preparing a sectioned sample which can be subsequently further sectioned (cut, cleaved, sliced, or/and polished) by essentially any type of sample final preparation technique, such as focused ion beam (FIB) milling, or broad ion beam (BIB) milling, or both. For preparation of a sectioned sample that is subsequently subjected to an ion beam milling type of sample final preparation technique, the present invention can produce a sectioned sample having relatively small size dimensions that require proportionately small amounts of ion beam milling time. This translates to decreasing the potential for introduction of contamination and artifacts to the sample, as a result of re-deposition during the ion beam milling process, thereby decreasing the potential that such contamination and artifacts may interfere with the mass spectrometry, and analysis thereof, required during a typical micro-analytical technique.

Specifically, regarding the particular preparatory requirements of the micro-analytical technique which is ultimately used for analyzing a given sample, the present invention is generally applicable for ultimate preparation of an SEM sample, or a TEM sample, or an STEM sample, or an EDS sample, or an AFM sample, or an SIMS sample, or a GDS sample. The present invention is therefore, generally applicable for the ultimate purpose of essentially any type of micro-analytical technique, for example, SEM, or TEM, or STEM, or EDS, or AFM, or SIMS, or GDS, respectively, without requiring a number of various different systems, equipment, and methodologies. Moreover, the present invention is fully applicable for ultimately preparing different types of sectioned samples, according to each main category, that is, (1) thinning, (2) cross-sectioning, and (3) plan view sectioning, of sectioning types of micro-analytical sample preparation techniques.

Furthermore, the present invention is implemented in a manner which significantly minimizes the formation of undesirable micro-sized cracks or/and artifacts in the sample during the sectioning (cutting, slicing) sawing process.

It is appreciated that certain aspects and characteristics of the invention, which are, for clarity, described in the context of separate embodiments, may also be provided in combination in a single embodiment. Conversely, various aspects and characteristics of the invention, which are, for brevity, described in the context of a single embodiment, may also be provided separately or in any suitable sub-combination.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

While the invention has been described in conjunction with specific embodiments and examples thereof, it is evident that many alternatives, modifications and variations will be apparent to those skilled in the art. Accordingly, it is intended to embrace all such alternatives, modifications and variations that fall within the spirit and broad scope of the appended claims.

What is claimed is:

1. A system for preparing a sample for micro-analysis, comprising:
(a) a sample precursor holding unit, for supporting and holding a sample precursor;
(b) a transporting and positioning unit, for transporting and positioning at least a part of said sample precursor holding unit;
(c) an optical imaging unit, for optically imaging, recognizing, and identifying, target features located on said sample precursor, and for monitoring steps of the sample preparation;
(d) a picking and placing unit, for picking and placing said sample precursor and selected components of the system from initial positions to other functionally dependent positions;
(e) a micro-groove generating unit, for generating at least one micro-groove in a surface of said sample precursor, wherein said micro-groove generating unit includes components for controlling depth and quality of each said micro-groove in said surface; and
(f) a cryogenic sectioning unit, for cryogenically sectioning said sample precursor to a pre-determined configuration and size, for forming the prepared sample.

2. The system of claim 1, wherein said sample precursor holding unit includes at least one sample precursor support structure, for supporting the sample precursor during a side view or planar view sample preparation process.

3. The system of claim 2, wherein said at least one sample precursor support structure supports a cut and mounted processed form of the sample precursor during a planar view sample preparation process.

4. The system of claim 2, wherein said at least one sample precursor support structure is used for re-working of the prepared sample.

5. The system of claim 2, wherein said sample precursor holding unit includes two said sample precursor support structures, and further includes a prepared sample support element, and a prepared sample support element holder.

6. The system of claim 5, wherein said prepared sample support element holder is oriented and positioned relative to, and is attached to, one of said two sample precursor support structures supporting the sample precursor.

7. The system of claim 6, wherein said prepared sample support element supports, and is fixed to, the prepared sample.

8. The system of claim 1, wherein said sample precursor holding unit includes at least one sample precursor support structure, for supporting a masking element, or a masking element and the sample precursor, during a side view or planar view sample preparation process.

9. The system of claim 1, wherein said micro-groove generating unit includes a micro-groove generating element, said micro-groove generating element is a blade or knife with a micro-groove generating tip.

10. The system of claim 9, wherein said micro-groove generating tip has a radius of less than about 100 nanometers.

11. The system of claim 9, wherein said micro-groove generating tip has a radius of less than about 20 nanometers.

12. The system of claim 9, wherein said micro-groove generating tip is composed of a diamond or diamond-like material.

13. The system of claim 9, wherein said micro-groove generating unit further includes a vertical displacement assembly, for vertically displacing and penetrating said micro-groove generating element into said surface of the sample precursor.

14. The system of claim 13, wherein said vertical displacement assembly is mountable onto said micro-groove generating unit in a manner allowing for a rotational degree of freedom of said micro-groove generating element in relation to said surface of the sample precursor.

15. The system of claim 14, wherein said rotational degree of freedom provides for a variably controllable angle of approach of said micro-groove generating element towards said surface of the sample precursor.

16. The system of claim 15, wherein said angle of approach is enabled by an aligning assembly acting upon said vertical displacement assembly.

17. The system of claim 13, wherein said vertical displacement assembly includes a bearing sub-assembly, and a micro-groove depth (penetration) control sub-assembly.

18. The system of claim 9, wherein said micro-groove generating unit further includes a force applying assembly, for applying a controllable force to said micro-groove generating element, thereby providing a controllable displacement of said micro-groove generating element into said surface of the sample precursor.

19. The system of claim 18, wherein said force applying assembly includes a force generating motor, and a force applying arm.

20. The system of claim 9, wherein said micro-groove generating unit further includes an aligning assembly, for controlling angle of approach of said micro-groove generating element towards, and penetration into, said surface of the sample precursor.

21. The system of claim 20, wherein said micro-groove generating unit further includes a vertical displacement assembly, wherein said vertical displacement assembly transmits movement to said aligning assembly such that vertical displacement of said micro-groove generating element is converted, via said aligning assembly, to a rotational displacement, thereby controlling angle of approach towards, and penetration into, said surface of the sample precursor by said micro-groove generating element.

22. The system of claim 20, wherein said micro-groove generating unit further includes a force applying assembly, for applying a controllable force to said micro-groove generating element, thereby providing a controllable displacement of said micro-groove generating element into said surface of the sample precursor.

23. The system of claim 22, wherein said force applying assembly includes a set of force applying members.

24. The system of claim 9, wherein depth (penetration) of said micro-groove generating element into said surface is in a range of from about 10 nanometers to about 10,000 nanometers.

25. The system of claim 9, wherein incremental (step) resolution of depth (penetration) of said micro-groove generating element into said surface is in a range of from about 3 nanometers to about 7 nanometers.

26. The system of claim 9, wherein said micro-groove generating element is used for measuring a vertical slant of said surface of the sample precursor.

27. The system of claim 1, wherein said micro-groove generating unit is used for detaching a pre-determined number of layers of the sample precursor adjacent to features in a target area or region of interest on the sample precursor.

28. The system of claim 1, wherein said micro-groove generating unit is used for marking, via said at least one micro-groove, a target area or region of interest on said surface of the sample precursor.

29. The system of claim 1, wherein said cryogenic sectioning unit includes a pressure control mechanism for maintaining pressure of cryogenic fluid in a cryogenic fluid reservoir at a constant value regardless of changes or variability in volume of said cryogenic fluid present in said cryogenic fluid reservoir.

30. The system of claim 29, wherein said cryogenic sectioning unit further includes a measuring pin assembly, for measuring a diameter of a cryogenic sectioning blade, for calibrating sectioning depth of said cryogenic sectioning blade.

31. The system of claim 1, further including an adhering interface assembly, for enabling interfacing of said transporting and positioning unit with said picking and placing unit, for adhering a first component to a second component within the system.

32. The system of claim 31, wherein said adhering interface assembly includes an adhesive applying sub-assembly, for adhering a masking element to said surface of the sample precursor or to said surface of a cut and mounted processed form of the sample precursor.

33. The system of claim 32, wherein said adhesive applying sub-assembly includes an adhesive applying needle, and an adhesive receptacle, wherein said adhesive receptacle contains an adhesive material which is applied by said adhesive applying needle to one or more components of the system.

34. The system of claim 33, wherein said adhesive applying needle is used for probing inside of said adhesive receptacle, for measuring a level of said adhesive material inside of said adhesive receptacle.

35. The system of claim 33, wherein said adhesive applying needle is dipped into said adhesive receptacle to a pre-determined level, so as to pick up an exact amount of said adhesive material.

36. The system of claim 1, further including a micro-mask adhering unit, for adhering a micro-mask onto said surface of the sample precursor.

37. The system of claim 36, wherein said micro-mask adhering unit includes a micro-size masking element, and a micro-size masking element holder assembly, wherein said micro-size masking element holder assembly holds said micro-size masking element, and contains electrically conductive wires which transfer electrical current to said micro-size masking element.

38. The system of claim 36, wherein said micro-mask adhering unit is used for adhering said micro-mask onto said surface of a previously cryogenically sectioned sample precursor.

39. The system of claim 38, wherein said micro-mask is adhered onto said surface at a pre-determined position and with a positioning accuracy in a range of between about 50 nanometers and about 150 nanometers.

40. The system of claim 1, further including at least one additional component selected from the group consisting of: (g) an adhering interface assembly, for enabling interfacing of said transporting and positioning unit with said picking and placing unit, for adhering a first component to a second component within the system; (h) a pneumatics control unit, for controlling pneumatics of components of the system; (i) a sample precursor micro-size (surface area dimensions) reducing unit, for reducing size (surface area dimensions) of the sample precursor to a pre-determined sample precursor size; (j) a scribing and cleaving unit, for generating a scribe line on said surface of the sample precursor, and cleaving the sample precursor along said scribe line; (k) a micro-mask adhering unit, for adhering a micro-mask onto said surface of the sample precursor; and (l) an anti-vibration unit, for preventing or minimizing occurrence of vibrations during operation of the system.

41. The system of claim 1, wherein the sample precursor includes or is composed of at least one type of material selected from the group consisting of semiconductor materials, ceramic material, pure metallic materials, metal alloy materials, polymeric materials, composite materials, and combinations thereof.

42. The system of claim 1, wherein the sample precursor includes or is composed of a semiconductor type of material.

43. The system of claim 42, wherein said material includes or is a single die of a wafer, a wafer segment, or a whole wafer.

44. A device for generating at least one micro-groove in a surface of a material, comprising:
(a) a micro-groove generating element assembly, including a micro-groove generating element and a micro-groove generating element holder assembly;
(b) a vertical displacement assembly, for vertically displacing and penetrating said micro-groove generating element into the surface of the material; and
(c) a force applying assembly, for applying a controllable force to said micro-groove generating element, via operation of said vertical displacement assembly.

45. The device of claim 44, wherein said micro-groove generating element is a blade or knife with a micro-groove generating tip.

46. The device of claim 45, wherein said micro-groove generating tip has a radius of less than about 100 nanometers.

47. The device of claim 45, wherein said micro-groove generating tip has a radius of less than about 20 nanometers.

48. The device of claim 45, wherein said micro-groove generating tip is composed of a diamond or diamond-like material.

49. The device of claim 44, wherein said vertical displacement assembly is mountable onto a housing of the micro-groove generating device in a manner allowing for a rotational degree of freedom of said micro-groove generating element in relation to the surface of the material.

50. The device of claim 49, wherein said rotational degree of freedom provides for a variably controllable angle of approach of said micro-groove generating element towards the surface of the material.

51. The device of claim 50, wherein said angle of approach is enabled by an aligning assembly acting upon said vertical displacement assembly.

52. The device of claim 44, wherein said vertical displacement assembly includes a bearing sub-assembly, and a micro-groove depth (penetration) control sub-assembly.

53. The device of claim 44, wherein said force applying assembly includes a force generating motor, and a force applying arm.

54. The device of claim 53, wherein said force generating motor is a direct current (DC) motor.

55. The device of claim 44, wherein said micro-groove generating device further includes an aligning assembly, for controlling angle of approach of said micro-groove generating element towards, and penetration into, the surface of the material.

56. The device of claim 55, wherein said vertical displacement assembly transmits movement to said aligning assembly such that vertical displacement of said micro-groove generating element is converted, via said aligning assembly, to a rotational displacement, thereby controlling angle of approach towards, and penetration into, the surface of the material by said micro-groove generating element.

57. The device of claim 44, wherein said force applying assembly includes a set of force applying members.

58. The device of claim 57, wherein said force applying members are springs.

59. The device of claim 44, wherein depth (penetration) of said micro-groove generating element into the surface is in a range of from about 10 nanometers to about 10,000 nanometers.

60. The device of claim 44, wherein incremental (step) resolution of depth (penetration) of said micro-groove generating element into the surface is in a range of from about 3 nanometers to about 7 nanometers.

61. The device of claim 44, wherein said micro-groove generating element is used for measuring a vertical slant of the surface of the material.

62. The device of claim 44, used for detaching a pre-determined number of layers of the material adjacent to features in a target area or region of interest on the material.

63. The device of claim 44, used for marking, via the at least one micro-groove, a target area or region of interest on the surface of the material.

64. A device for cryogenically sectioning a material, comprising:
(a) a fine sectioning blade, for sectioning the material at positions located along the material which are adjacent to target features of the material;
(b) a coarse sectioning blade, for reducing, via sectioning, the material at positions along the material which are not adjacent to said target features;
(c) a sectioning blade drive shaft, for driving both said fine sectioning blade and said coarse sectioning blade;
(d) a sectioning blade drive shaft motor, for rotating said blade drive shaft; and
(e) a cryogenic fluid supply and control assembly, for supplying and controlling use of a cryogenic fluid as a coolant or cooling agent for cooling at least one of said fine sectioning blade and said coarse sectioning blade, and the material during the cryogenic sectioning process, wherein said cryogenic fluid supply and control assembly includes:
(i) a cryogenic fluid;
(ii) a cryogenic fluid reservoir;
(iii) a cryogenic fluid supply valving and distributing sub-assembly, including a pressure control mechanism for maintaining pressure of said cryogenic fluid reservoir at a constant value regardless of changes or variability in volume of said cryogenic fluid present in said cryogenic fluid reservoir; and
(iv) a cryogenic fluid outlet nozzle sub-assembly.

65. The device of claim 64, further including a measuring pin assembly, for measuring a diameter of at least one of said fine sectioning blade and said coarse sectioning blade, for calibrating sectioning depth of said sectioning blade.

66. A device for adhering a micro-mask onto a surface of a material, comprising:
(a) a micro-size masking element, having a geometrical configuration, shape or form, selected from the group consisting of cylindrical, rectangular, and trapezoidal, and wherein diameter of a said cylindrical configuration is in a range of from about 6 microns to about 25 microns, and wherein section or profile of a said rectangular configuration is in a range of from about 6 microns to about 25 microns;
(b) a micro-size masking element holder assembly;
(c) an electrical contact assembly;
(d) a housing assembly;
(e) a y-axis displacement sub-assembly;
(f) a z-axis displacement sub-assembly; and
(g) a light beam interruption sensor assembly.

67. The device of claim 66, wherein said micro-size masking element holder assembly holds said micro-size masking element, and contains electrically conductive wires which transfer electrical current to said micro-size masking element.

68. The device of claim 66, used for adhering said micro-mask onto the surface of a previously cryogenically sectioned material.

69. The device of claim 66, wherein said micro-mask is adhered onto the surface at a pre-determined position and with a positioning accuracy in a range of between about 50 nanometers and about 150 nanometers.

70. A method of preparing a sample for micro-analysis, comprising:
(a) loading a sample precursor onto a sample precursor holding unit;
(b) transporting and positioning said sample precursor holding unit by a transporting and positioning unit;
(c) optically imaging, recognizing, and identifying, target features located on said sample precursor, and monitoring steps of the sample preparation, by an optical imaging unit;
(d) picking and placing said sample precursor and selected components of the system from initial positions to other functionally dependent positions, by a picking and placing unit;
(e) generating at least one micro-groove in a surface of said sample precursor, by a micro-groove generating unit, wherein depth of each said micro-groove in said surface is controlled by components included in said micro-groove generating unit; and
(f) cryogenically sectioning said sample precursor to a pre-determined configuration and size, for forming the prepared sample, by a cryogenic sectioning unit.

71. A method of generating at least one micro-groove in a surface of a material, comprising:
(a) providing a micro-groove generating element assembly including a micro-groove generating element and a micro-groove generating element holder assembly;
(b) controlling angle of approach towards, and penetration into, the surface of the material, by said micro-groove generating element, by an aligning assembly;
(c) transmitting movement to said aligning assembly, such that vertical displacement of said micro-groove generating element is converted to a rotational displacement, by a vertical displacement assembly; and
(d) applying a controllable force to said micro-groove generating element, by a force applying assembly.

72. A method of cryogenically sectioning a material, comprising:
(a) sectioning the material at positions located along the material which are adjacent to target features of the material, by a fine sectioning blade;
(b) reducing, via sectioning, the material at positions along the material which are not adjacent to said target features, by a coarse sectioning blade;
(c) driving both said fine sectioning blade and said coarse sectioning blade, by a sectioning blade drive shaft;
(d) rotating said blade drive shaft, by a sectioning blade drive shaft motor; and
(e) supplying and controlling use of a cryogenic fluid as a coolant or cooling agent for cooling at least one of said fine sectioning blade and said coarse sectioning blade, and the material during the cryogenic sectioning process, by a cryogenic fluid supply and control assembly, wherein said cryogenic fluid supply and control assembly includes:
(i) a cryogenic fluid;
(ii) a cryogenic fluid reservoir;
(iii) a cryogenic fluid supply valving and distributing sub-assembly, including a pressure control mechanism for maintaining pressure of said cryogenic fluid reservoir at a constant value regardless of changes or variability in volume of said cryogenic fluid present in said cryogenic fluid reservoir; and
(iv) a cryogenic fluid outlet nozzle sub-assembly.

73. A method of adhering a macro-mask onto a surface of a material, comprising:
(a) generating at least one micro-groove in a surface of the material, by using a micro-groove generating unit; and
(b) adhering the macro-mask at a predetermined location and according to a pre-determined configuration (orientation) onto a surface of the material, by using an adhering interface assembly, in such a way that each said generated micro-groove is extended in reference to the macro-mask, for serving as a mark, thereby being visible by an optical imaging device during subsequent subjection to a sectioning procedure.

74. A method of adhering a micro-mask onto a surface of a material, comprising:
(a) applying an adhesive onto a dedicated area on a surface of the material, by a picking and placing unit;
(b) positioning said dedicated area with said adhesive applied under a micro-size masking element, by using a transporting and positioning unit;
(c) controllably dipping of said micro-size masking element into said adhesive, by using a z-axis displacement sub-assembly of said transporting and positioning unit;
(d) focusing said micro-size masking element, by using said z-axis displacement sub-assembly;
(e) vertically moving said micro-size masking element out of focus of said optical imaging unit, by using said z-axis displacement sub-assembly;
(f) positioning a target feature of the material, to be coincident with position formerly occupied by said micro-size masking element prior to being taken out of focus, by using said transporting and positioning unit;
(g) vertically moving said micro-size masking element down until contact is made with the surface of the material, by using said z-axis displacement sub-assembly;
(h) applying an electrical current to said micro-size masking element, for heating and curing said micro-size masking element; and
(i) increasing said applied electrical current to edges of said micro-size masking element, for trimming said edges of said micro-size masking element.
